(19) United States
(12) Patent Application Publication
(10) Pub. No.: US 2006/0033678 A1
(43) Pub. Date: Feb. 16, 2006

(54) Integrated electroless deposition system

(75) Inventors: Dmitry Lubomirsky, Cupertino, CA (US); Arulkumar Shanmugasundram, Sunnyvale, CA (US); Allen D'Ambra, Burlingame, CA (US); Timothy W. Weidman, Sunnyvale, CA (US); Eugene Rabinovich, Fremont, CA (US); Svetlana Sherman, San Jose, CA (US); Manoocher Birang, Los Gatos, CA (US); Yaxin Wang, Fremont, CA (US); Michael X. Yang, Palo Alto, CA (US); Bradley Hansen, San Carlos, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/192,993

(22) Filed: Jul. 29, 2005

Related U.S. Application Data
(63) Continuation-in-part of application No. 10/996,342, filed on Nov. 22, 2004.
(63) Continuation-in-part of application No. 10/965,220, filed on Oct. 14, 2004.
(63) Continuation-in-part of application No. 11/043,442, filed on Jan. 26, 2005.
(60) Provisional application No. 60/539,491, filed on Jan. 26, 2004.
(60) Provisional application No. 60/539,491, filed on Jan. 26, 2004.
(60) Provisional application No. 60/648,004, filed on Jan. 27, 2005.

(51) Int. Cl. G09G 3/00; H05H 1/24; C23C 16/00

(52) U.S. Cl. 345/32; 427/576; 118/719

(57) ABSTRACT

Embodiments of the invention provide a cluster tool configured to deposit a material onto a substrate surface by using one or more electroless, electrochemical plating, CVD and/or ALD processing chambers. In one aspect, a ruthenium-containing catalytic layer is formed. Embodiments of the invention provide a hybrid deposition system configured to deposit a seed layer on a substrate with an electroless process and to subsequently fill interconnect features on the substrate with an ECP cell. Other aspects provide an electroless deposition system configured to deposit a seed layer on a substrate, fill interconnect features on a substrate, or sequentially deposit both a seed layer and fill interconnect features on the substrate. One embodiment provides an electroless deposition system configured to form a capping layer over substrate interconnects. The system includes a vapor dryer for pre- and post-deposition cleaning of substrates as well as a brush box chamber for post-deposition cleaning.

### CROSS-REFERENCE TO RELATED APPLICATIONS

This application claims benefit of U.S. provisional patent application Ser. No. 60/648,004, filed Jan. 27, 2005, which is herein incorporated by reference.

This application is a continuation-in-part of co-pending U.S. patent application Ser. No. 10/996,342 [APPM 9032], filed Nov. 22, 2004, which claims benefit of U.S. provisional patent application Ser. No. 60/539,491, filed Jan. 26, 2004. This application is a continuation-in-part of co-pending U.S. patent application Ser. No. 10/965,220 [APPM 8707.02], filed Oct. 14, 2004, which claims benefit of U.S. provisional patent application Ser. No. 60/539,491, filed Jan. 26, 2004. This application is a continuation-in-part of co-pending U.S. patent application Ser. No. 11/043,442 [APPM 8024.P2], filed Jan. 26, 2005. The disclosure of each of the aforementioned related patent applications is herein incorporated by reference.

### BACKGROUND OF THE INVENTION

1. Field of the Invention

Embodiments of the invention generally relate to an electroless deposition system for semiconductor processing.

2. Description of the Related Art

Metallization of sub-100 nanometer sized features is a foundational technology for present and future generations of integrated circuit manufacturing processes. More particularly, in devices such as ultra large scale integration-type devices, i.e., devices having integrated circuits with several million logic gates, the multilevel interconnects that lie at the heart of these devices are generally formed by filling sub-micron high aspect ratio, i.e., greater than about 10:1, interconnect features with a conductive material, such as copper. At these dimensions, conventional deposition techniques, such as chemical vapor deposition and physical vapor deposition, cannot reliably fill interconnect features like trenches or vias. As a result, plating techniques, i.e., electrochemical plating and electroless plating, have emerged as promising processes for void-free filling of sub-100 nanometer sized high aspect ratio interconnect features in integrated circuit manufacturing processes. Additionally, electrochemical and electroless plating processes have emerged as promising processes for depositing or repairing pre-plating seed layers and depositing post-plating layers, such as capping layers.

In order to further reduce the size of devices on integrated circuits, it has become necessary to use conductive materials having low resistivity and insulators having low k (dielectric constant<4.0) to reduce the capacitive coupling between adjacent metal lines. Currently, copper and its alloys have become the metals of choice for sub-micron interconnect technology because copper has a lower resistivity than aluminum, (1.7 μΩ-cm compared to 3.1 μΩ-cm for aluminum), and a higher current carrying capacity and significantly higher electromigration resistance. These characteristics are important for supporting the higher current densities experienced at high levels of integration and increased device speed. Further, copper has a good thermal conductivity and is available in a highly pure state.

Although copper is a popular interconnect material, copper suffers by diffusing into neighboring layers, such as dielectric layers. The resulting undesirable presence of copper causes dielectric layers to become conductive and electronic devices to fail. Therefore, barrier materials are used to control copper diffusion. The barrier layer typically includes a refractory metal nitride and/or silicide, such as titanium or tantalum. Of this group, tantalum nitride is one of the most desirable materials for use as a barrier layer. Tantalum nitride has one of the lowest electrical resistivities of the metal nitrides and is also a good barrier to prevent copper diffusion, even when relatively thin layers are formed (e.g., 20 Å or less). A tantalum nitride layer is typically deposited by conventional deposition techniques, such as physical vapor deposition (PVD), atomic layer deposition (ALD) and chemical vapor deposition (CVD). A negative characteristic of Tantalum nitride is poor adhesion to a copper layer deposited thereon. Poor adhesion of subsequent deposited copper layer(s) can lead to poor electromigration in the formed device and possibly process contamination issues in subsequent processing steps, such as chemical mechanical polishing (CMP). It is believed that exposure of the tantalum nitride layer to sources of oxygen and other contamination will cause the exposed surface of the tantalum nitride layer to oxidize, thus preventing the formation of a strong bond to the subsequently deposited copper layer. Also, dielectric deposition processes typically contain carbon, which becomes incorporated into the dielectric layer. Carbon incorporation is often detrimental to the completion of wet chemical processes since the deposited film tends to be hydrophobic, reducing or preventing fluids from wetting and depositing a film having desirable properties. Therefore, a process and apparatus is needed for depositing a barrier layer or adhesion layer that strongly bonds to carbon-containing dielectric layers and subsequently deposited copper layers.

Another problem with the use of copper and its alloys is that copper readily oxidizes when exposed to air and is also vulnerable to chemical corrosion and deterioration due to subsequent processing steps. Copper interconnects are adversely affected by oxidation and other forms of deterioration and seed layers suffer from widely different levels of oxidation when queue times vary between lots.

A method of protecting copper interconnects from subsequent processing steps is to form a capping layer over copper interconnects. One problem with previous capping layer methods is inadequate pre-treatment of the substrate prior to electroless deposition of the capping layer and inadequate post-treatment of the capping layer, which may cause contamination problems and/or selectivity problems. One example of contamination includes watermarks remaining on hydrophobic films that contain copper, cobalt, and other metals. The presence of this type of contamination can seriously affect subsequent electroless deposition as well as other processing steps. Another problem with using capping layers to protect interconnects is the potential creation of shorts between closely spaced interconnects. FIG. 1A illustrates a substrate structure 100 with parallel interconnects 101, 102 and 103. The substrate structure 100 is shown after being planarized by a chemical mechanical polishing (CMP) process. Even after rigorous cleaning, contamination in the form of copper particles 104a is generally present on the surface of substrate structure 100. FIG. 1B depicts substrate structure 100 after a metallic capping layer, such as capping layer 105, has been formed on top of parallel interconnects 101, 102, and 103 by an electroless deposition process. Because the presence of any metal can act as a site of autocatalytic (electroless) deposition, copper particles 104a will experience significant deposition as well. In regions of closely spaced interconnects, these now enlarged metallic particles 104b (FIG. 1B) can create electrical leakage between the parallel interconnects 101, 102 and 103. Also, the slightly irregular edge 106a of a parallel interconnect 101 will be exaggerated during the deposition of capping layer 105, forming more irregular edge 106b and further reducing the distance 107 required to create leakage between interconnects.

Another problem facing manufacturers of ultra-large scale integrated circuits is the filling of very high and very low aspect ratio features on the same device at the same time. FIG. 1C is a schematic side view of a substrate structure 110 with sub-micron high aspect ratio (i.e., >10:1) features, such as high aspect ratio features 111, and a low aspect ratio feature 112, both requiring copper fill. FIGS. 1C-E show low aspect ratio feature with a depth-to-width ratio of approximately 1:5, but for some device features this ratio may be as much as 1:100 or more, such as for contact pads. FIG. 1D illustrates substrate structure 110 after a typical electroless copper plating process. Electroless copper film 115 of thickness 114 has been conformally deposited on substrate structure 110 via an electroless plating process. High aspect ratio features 111 are filled since the width 113 of high aspect ratio features 111 is no more than twice the thickness 114 of the electroless copper film 115. Low aspect ratio feature 112 is only partially filled, however. Either an extended electroless fill process must be used, or another method of filling large, low aspect ratio features such as 112 must be used. Electroless deposition of films that can fill such large substrate features can require prohibitively long deposition times, e.g. one or more orders of magnitude longer than the time required to fill high aspect ratio features 111. Application of a second plating method to fill low aspect ratio features such as 112 typically requires the added expense and complexity of processing substrates on an additional processing platform. In addition, electroless copper film 115 will be subject to degradation via oxidation prior to the secondary plating process.

Another problem related to oxidation is the formation of a native oxide on exposed electrical contacts during the fabrication of electronic devices. A native oxide typically forms when a substrate surface is exposed to oxygen. Oxygen exposure occurs when the substrate is moved between processing chambers at atmospheric conditions, or when removed from a substrate processing system between processing steps, or when a small amount of oxygen remaining in a processing chamber contacts the substrate surface. Native oxides may also result if the substrate surface is contaminated during etching. Native oxides typically form an undesirable film on the substrate surface. Native oxide films are usually very thin, such as between 5 and 20 angstroms, but thick enough to cause difficulties in subsequent fabrication processes. Such difficulties usually affect the electrical properties of semiconductor devices formed on the substrate. For example, a particular problem arises when native silicon oxide films are formed on exposed contact surfaces (e.g., source or drain connection points), such as those shown in FIG. 1C. Exposed contact surfaces are present at the bottom of high aspect ratio features 111 and low aspect ratio feature 112 prior to performing interconnect metallization processes, such as electroless gap fill. Such contact surfaces are typically metallic materials subject to rapid native oxide growth. Native oxides are electrically insulating and are undesirable at interfaces with device contacts or interconnecting electrical pathways because they cause high electrical contact resistance. This results in lower substrate yields and increased failure rates due to overheating at the electrical contacts. The native oxide film can also prevent adhesion of other layers that are subsequently deposited on the substrate. It is desirable to have a method for removing native oxides and other contaminants on exposed device contacts-particularly those found in sub-micron high-aspect features. Current methods include sputter etching and wet etch processes using hydrofluoric acid. Sputter etching performs poorly in features having aspect ratios smaller than about 4:1 and can damage delicate silicon layers by physical bombardment. Wet etch processes also perform poorly in high aspect ratio features and may contaminate the feature with undesirable fluorine contamination.

Ultra-large scale integrated circuits may also suffer from high contact resistance as devices on integrated circuits are further reduced in size. High contact resistance can be the result of native oxide formation on contact surfaces, contamination, the formation of seams and voids, and barrier layer resistance. As noted above, native oxide may form on exposed contact surfaces such as those present at the bottom of high aspect ratio features 111 and low aspect ratio feature 112 shown in FIG. 1C. Contamination may be present inside high aspect ratio features 111 from previous process steps because it is difficult to remove from such features. Seams may form between conductive layers deposited in a device feature, such as a contact surface. Seam formation results in high contact resistance despite the low resistivity of the individual layers formed thereon. Similarly, unwanted voids tend to form in high aspect ratio contacts when the contacts are filled with tungsten using conventional CVD methods. Voids greatly increase electrical resistance and may also be displaced into subsequent layers formed on the device. With smaller device sizes, the barrier layer makes up increasingly more cross-sectional area of a contact or via. Because barrier layers generally posses worse-than-optimal electrical resistance, contact resistance increases exponentially with decreasing size when conventional barrier layers are used.

Yet another problem that occurs during the manufacture of ultra-large scale integrated circuits is the depletion of silicon at the source/drain contact interface through silicidation, i.e., diffusion into the contact interface by the conductive material filling the contact feature and the subsequent formation of a silicide by the conductive fill material.

Further, a functional and efficient integrated platform for electroless deposition processes capable of depositing uniform layers with minimal defects has not been developed. Therefore, there is a need for methods and apparatus that incorporate electroless deposition processes onto substrate-processing platforms capable of:
forming capping layers on interconnect features with minimal defects and minimal oxidation of the interconnect features;
removing native oxide and other contaminants on exposed contacts at the bottom of high aspect ratio features and depositing electroless Cobalt or Nickel for fill;
removing electroless cobalt or nickel overgrowth after contact fill;
cleaning oxides from highly doped silicon substrates at the source and drain connection points, and depositing thin film of cobalt or nickel or both cobalt and nickel on these substrates for further silicidation;
depositing a barrier layer or adhesion layer that strongly bonds to carbon-containing dielectric layers and subsequently deposited copper layers;
depositing and/or repairing seed layers on substrate structures prior to copper interconnect deposition;
filling interconnect features with electroless copper deposition;
sequentially depositing a seed layer on a substrate structure and then filling the interconnect features with electroless copper deposition;
sequentially depositing a seed layer on a substrate structure and then filling the interconnect features with electrochemical (ECP) copper deposition;
sequentially depositing a seed layer on a substrate structure, filling the high aspect ratio interconnect features with electroless copper deposition, and filling large, low aspect ratio features with ECP overfill deposition; and
performing the above processes at an efficient rate.

### SUMMARY OF THE INVENTION

Embodiments of the invention provide a cluster tool that is configured to deposit a material onto a surface of a substrate by using one or more electroless, electrochemical plating, CVD and/or ALD processing chambers. “Cluster tool” as used herein refers to a substrate processing system containing multiple substrate processing chambers, wherein the multiple chambers are intended either to perform various processes on substrates in sequence or to perform the same process on multiple substrates simultaneously. The system includes a processing mainframe, at least one substrate cleaning station positioned on the mainframe, and at least one electroless deposition station positioned on the mainframe. The system also includes a substrate transfer robot positioned on the mainframe and configured to transport substrates between process chambers.

Embodiments of the invention also provide a hybrid deposition system configured to deposit a seed layer on a substrate with an electroless process and to subsequently fill interconnect features on the substrate with an ECP cell. In one embodiment, conventional integrated bevel clean and spin-rinse-dry chambers are used for post-deposition cleaning of the substrate.

Embodiments of the invention further provide an electroless deposition system configured to deposit a seed layer on a substrate, repair an extant seed layer, fill interconnect features on a substrate, or sequentially deposit both a seed layer and fill interconnect features on the substrate. In one embodiment, a standard SRD chamber is used for post-deposition cleaning of the substrate. In another embodiment, conventional IBC and SRD chambers are used for post-process cleaning of the substrate. In another embodiment, a hybrid IBC/SRD chamber is used for post-deposition processing. In another embodiment, a brush box chamber and SRD are used.

Embodiments of the invention provide an electroless deposition system configured to form a capping layer over substrate interconnects. The system includes a vapor dryer for pre- and post-deposition cleaning of substrates as well as a brush box chamber for post-deposition cleaning.

Embodiments of the invention further provide an electroless deposition system that is configured to form a barrier layer and a ruthenium-containing catalytic layer on a substrate prior to electroless to deposition on the substrate.

Embodiments of the invention further provide an elelctroless deoposition system that is configured to remove native oxide and other contaminants on exposed contacts at the bottom of high aspect ratio features using a plasma-enhanced dry etch chamber or a supercritical clean chamber and depositing electroless Cobalt or Nickel for fill.

Embodiments of the invention also provide a substrate processing chamber that integrates the functions of an electroless deposition chamber with the post-deposition bevel cleaning function of an IBC chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A (Prior Art) is a schematic perspective diagram of a substrate structure that has been cross-sectioned for clarity.

FIG. 1B (Prior Art) is a schematic perspective diagram of the structure of FIG. 1A after the deposition of a capping layer on the substrate structure.

FIG. 1C is a schematic side view of a substrate structure prior to copper film deposition.

FIG. 1D is a schematic side view of the substrate structure in FIG. 1C after the deposition of a copper film via a typical electroless plating process.

FIG. 1E is a schematic side view of the substrate structure in FIG. 1D after the deposition of a second copper film via an ECP overfill process.

FIGS. 1F-1K illustrate schematic cross-sectional views of an integrated circuit fabrication sequence formed by a process described herein.

FIG. 2 is a schematic plan view of an exemplary deposition system.

FIG. 2A is a schematic plan view of an exemplary deposition system.

FIG. 3 is a perspective diagram of an exemplary substrate bevel cleaning chamber.

FIG. 4 is a partial perspective view of an exemplary substrate spin rinse dry cell.

FIG. 5A illustrates a selective electroless deposition process sequence.

FIG. 5B illustrates a non-selective electroless deposition process sequence.

FIG. 5C illustrate a selective electroless deposition process sequence for high aspect ratio contact fill.

FIG. 6 is a perspective view of an exemplary electroless plating twin cell.

FIG. 7 is a perspective view of an exemplary twin electroless plating twin cell with processing enclosure removed for clarity.

FIG. 8 is a sectional view of an exemplary pair of electroless processing stations.

FIG. 9A is a perspective view of a running beam and a flipper robot for substrate transfer into a brush box chamber and a vapor dryer chamber.

FIG. 9B is a flow chart summarizing the different methods of vertical wafer handling required for embodiments of the invention.

FIG. 10 is a flow chart of a substrate process sequence for one embodiment of the invention.

FIG. 11 is a schematic plan view of an exemplary deposition system.

FIG. 11A is a schematic plan view of an exemplary deposition system.

FIGS. 12A, 12B, 12C, 12D, and 12E are a flow charts of substrate process sequences for one embodiment of the invention.

FIG. 13 is a flow chart of a substrate process sequence for one embodiment of the invention.

FIG. 14 illustrates a cross-sectional view of a capacitively coupled plasma processing chamber that may be incorporated into embodiments of the invention.

FIG. 14A illustrates a cross-sectional view of a plasma processing chamber adapted to deposit a ruthenium-containing layer on a substrate.

FIG. 15 is a flow chart of a substrate process sequence for one embodiment of the invention.

FIG. 16 is a flow chart of a substrate process sequence for one embodiment of the invention.

FIG. 17 is a flow chart of a substrate process sequence for one embodiment of the invention.

FIGS. 18A and 18B illustrate a cross-sectional view of a process chamber that may be adapted to deposit reducing and catalytic layers on a substrate.

FIGS. 18C and 18D illustrate a cross-sectional view of a process chamber that may be adapted to deposit reducing, catalytic, and ECP layers on a substrate.

FIG. 19 illustrates a partial cross sectional view of an illustrative processing chamber for heating, cooling, and etching.

FIG. 20 is a schematic cross-sectional view of an exemplary supercritical clean chamber that may be used in embodiments of the invention.

For clarity, identical reference numerals have been used, where applicable, to designate identical elements that are common between figures.

### DETAILED DESCRIPTION

Embodiments of the invention generally provide a cluster tool that is configured to deposit a material onto semiconductor substrates by using one or more electroless, ECP, CVD and/or ALD processing chambers. More particularly, embodiments of the invention allow formation of capping layers with low defects and low oxidation of interconnect features, deposition of a barrier layer on substrates, deposition and/or repair of seed layers on substrates, electroless fill of interconnect features, and sequential filling of high and low aspect ratio interconnect features on a substrate, using electroless and ECP processes. Other embodiments of the invention allow the removal of native oxides and other contaminants on exposed contacts at the bottom of high aspect ratio features and the subsequent deposition of cobalt and/or nickel to fill such contacts. In one aspect, nickel silicide is formed after the cleaning step and before the cobalt fill step to prevent further silicidation of diffused cobalt. A typical sequence for forming an interconnect includes depositing one or more non-conductive layers, etching at least one of the layer(s) to form one or more features therein, depositing a barrier layer in the feature(s) and depositing one or more conductive layers, such as copper, to fill the feature.

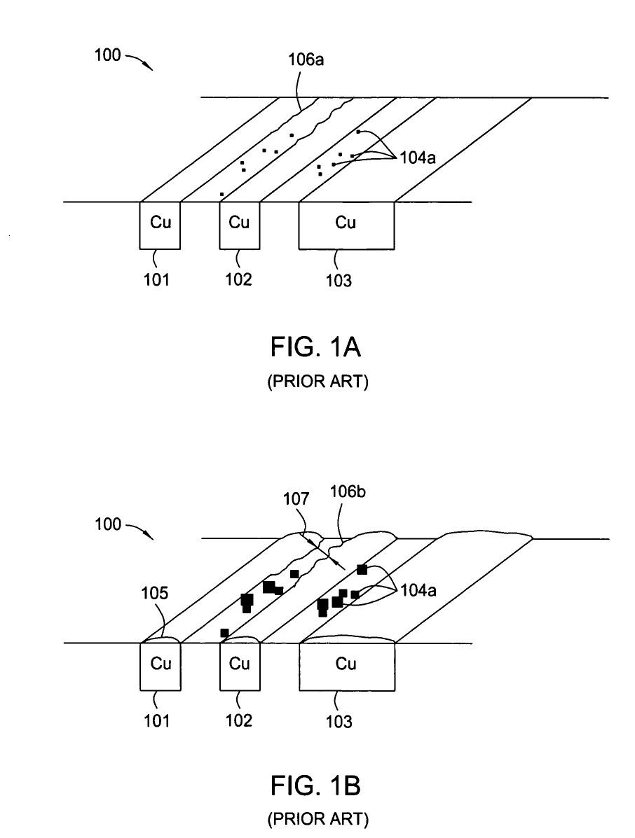

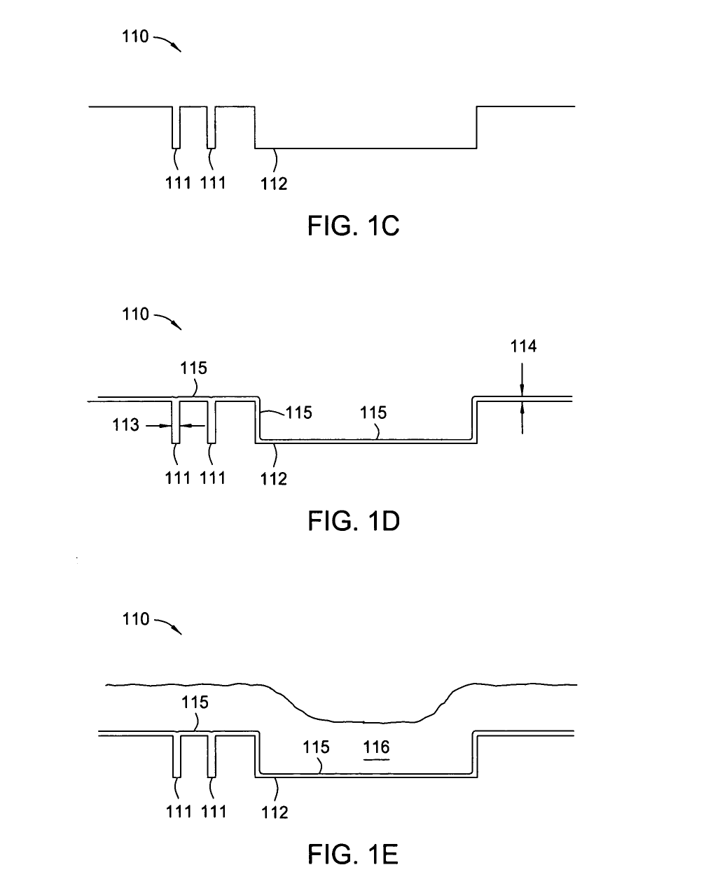

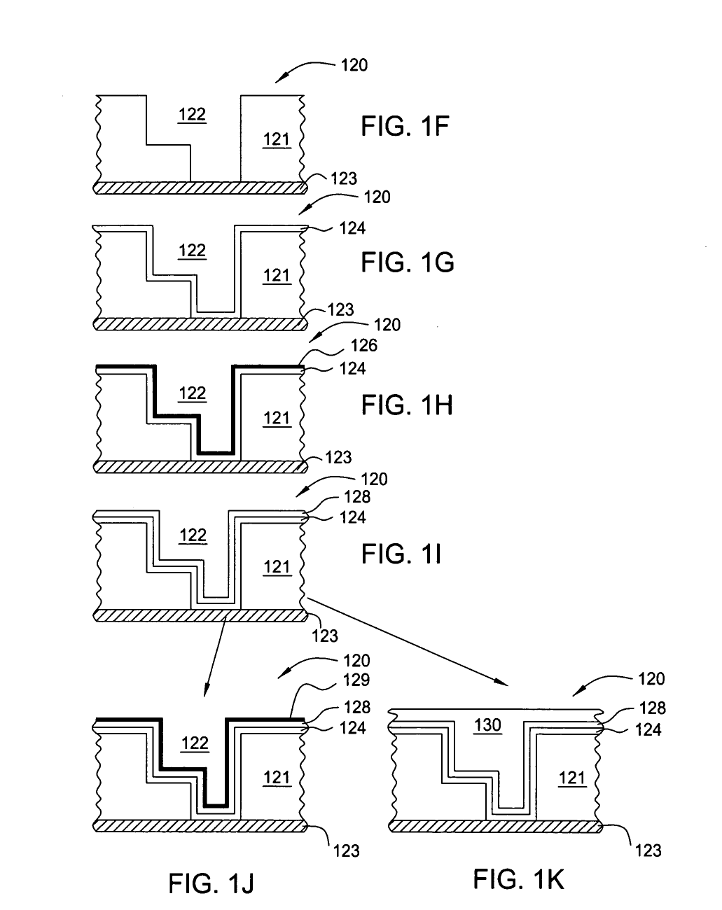

FIG. 1F illustrates a cross-sectional view of substrate 120 having an interconnect feature, or aperture, 122 formed into a dielectric layer 121 on the surface of the substrate 120. Substrate 120 may comprise a semiconductor material such as, for example, silicon, germanium, or silicon germanium, for example. The dielectric layer 121 may be an insulating material, such as silicon dioxide, silicon nitride, SOI, silicon oxynitride and/or carbon-doped silicon oxides, such as SiOₓC_{y}, for example, BLACK DIAMOND™ low-k dielectric, available from Applied Materials, Inc., located in Santa Clara, Calif. Aperture 122 may be formed in substrate 120 using conventional lithography and etching techniques to expose contact layer 123. Contact layer 123 may include copper, tungsten, aluminum or alloys thereof.

To prevent copper diffusion into dielectric layer 121, barrier layer 124 may be formed on the dielectric layer 121 and in aperture 122, as depicted in FIG. 1G. Barrier layer 124 may be formed using a suitable deposition process including ALD, chemical vapor deposition (CVD), physical vapor deposition (PVD) or combinations thereof. In one embodiment, barrier layer 124 may be formed by a chamber of the cluster tool.

Rather than directly depositing a bulk conductive material, such as copper, onto barrier layer 124 to fill aperture 122, a reducing layer 126 which promotes adhesion, may first be formed on barrier layer 124, as depicted in FIG. 1H. To form a reducing layer 126 on barrier layer 124, the surface of barrier layer 124 is modified by use of a plasma deposition process. In one embodiment, this plasma deposition process may be conducted in the same deposition chamber as the barrier layer deposition process, described above.

To prepare substrate 120 for subsequent deposition of conductive layers via electroless and/or electrochemical plating, a catalytic layer 128 is deposited on barrier layer 124 as depicted in FIG. 1I. Catalytic layer 128 is formed by exposing reducing layer 126 to a catalytic metal-containing precursor. Reducing layer 126 chemically reduces the catalytic metal-containing precursor to form catalytic layer 128 on barrier layer 124. Catalytic layer 128 contains the respective metal from the precursor, allowing formation of subsequent conductive layers on the substrate via electroless and/or electrochemical deposition.

Conductive layers such as seed layer 129 and/or bulk layer 130 may then be deposited on substrate 120 as shown in FIGS. 1J and 1K, respectively. Alternately, seed layer 129 may be deposited on substrate 120 followed by a bulk conductive layer, such as bulk layer 130 (not shown). Embodiments of the invention may deposit seed layer 129 and/or bulk layer 130 by an electroless plating process. In one aspect, bulk layer 130 may be deposited via an electrochemical plating process.

General Cluster Tool Description

The cluster tool generally contains a wet processing platform in communication with a substrate loading area and together with the loading area, comprises a substrate plating system. The loading area, or “dry side”, is generally configured to receive substrate-containing cassettes and transfer substrates received from the cassettes to the wet processing platform for wet processing. The loading area typically includes “dry side” processing chambers for treatment of substrates before and/or after wet processing, such as barrier layer deposition chambers and anneal chambers. The dry side may also contain a robot configured to transfer substrates between the cassettes, the wet processing platform, and the dry side processing chambers. The wet processing platform generally includes at least one substrate transfer robot and a plurality of substrate processing chambers, for example, ECP cells, IBC chambers, SRD chambers, electroless plating cells, etc. The various embodiments may include different combinations of wet and dry substrate-processing chambers. In one aspect, the cluster tool will allow for pre-treatment of a dry substrate, such as barrier layer deposition, wet processing of the substrate, such as seed layer deposition, electrochemical and/or electroless gap fill, and surface and/or bevel cleaning and drying, and any necessary post-deposition processing, such as anneal. Applications of the above processes suitable for substrate structure deposition include barrier layer deposition, electroless seed deposition, electroless seed repair, electroless seed and electroless interconnect fill (e.g. bulk fill), electroless seed and ECP interconnect fill, electroless capping deposition, and electroless high aspect ratio interconnect fill followed by ECP low aspect ratio interconnect fill.

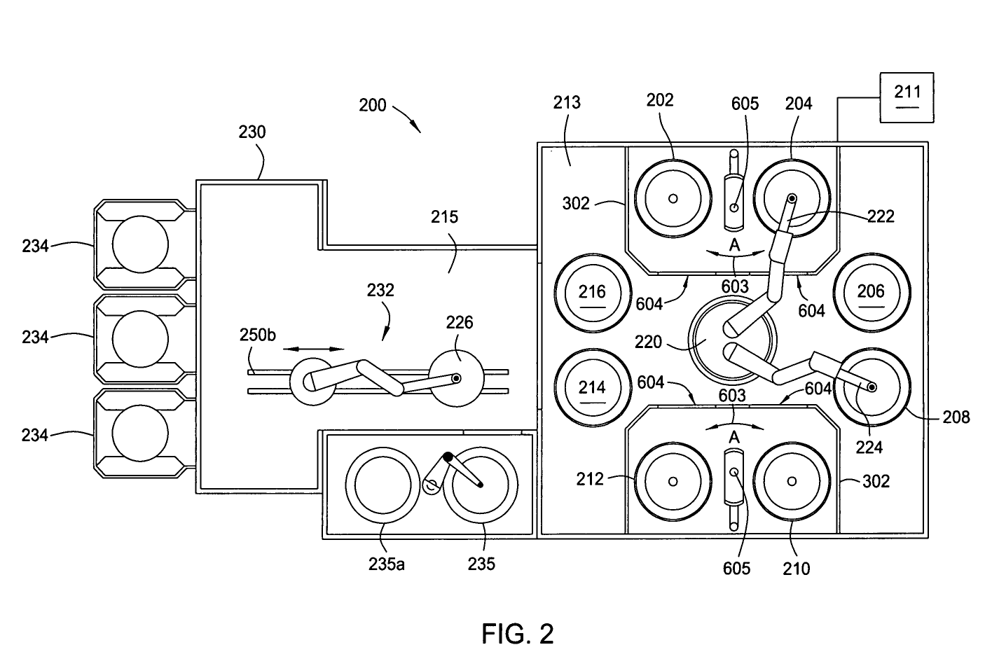

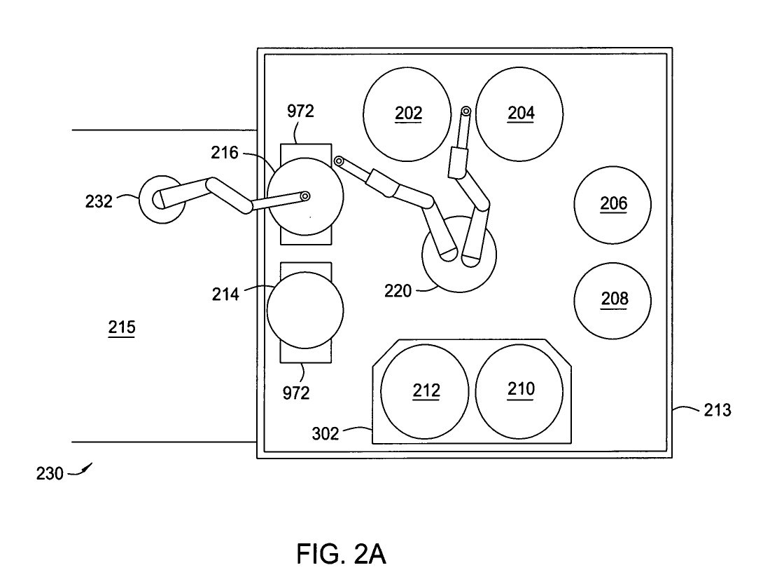

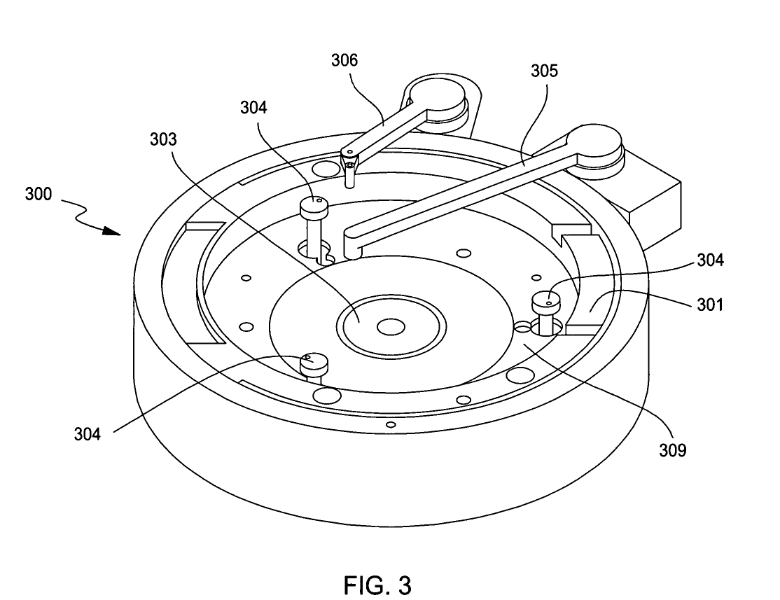

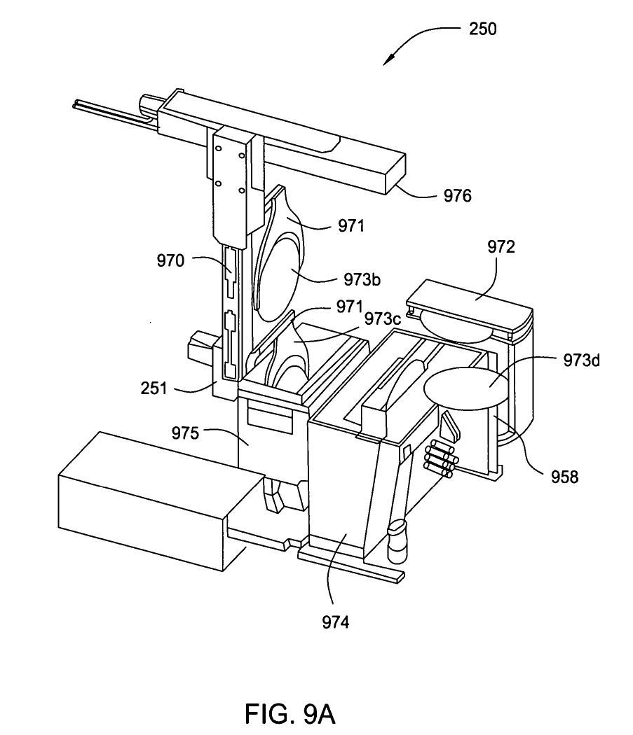

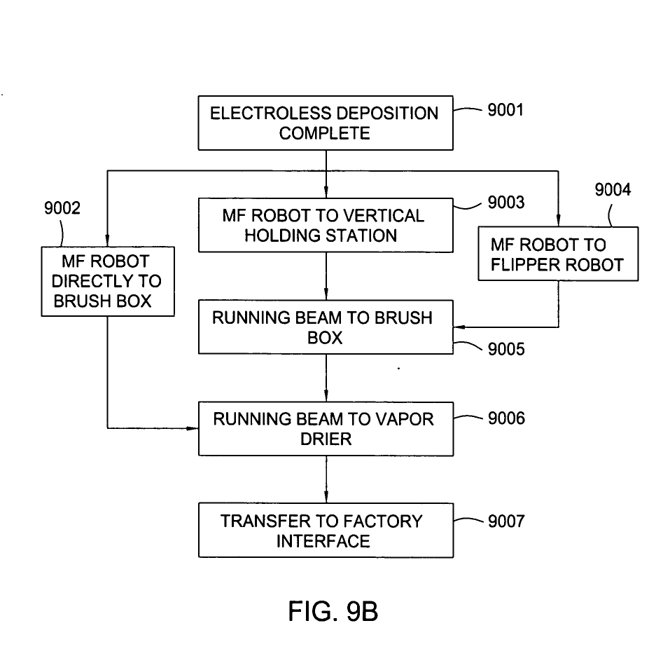

FIG. 2 illustrates one example of a cluster tool 200 that may perform electroless deposition. Cluster tool 200 includes a factory interface 230 that includes a plurality of substrate loading stations 234 configured to interface with and retain substrate containing cassettes (hereafter referred to as cassettes). A factory interface robot 232 is positioned in the factory interface 230 and is configured to access and transfer a substrate 226 into and out of the cassettes positioned on the substrate loading stations 234. The factory interface robot 232 also extends into a link tunnel 215 that connects the factory interface 230 to a wet processing platform 213. The position of factory interface robot 232 allows for access to substrate loading stations 234 to retrieve substrates therefrom, and to then deliver the substrate 226 to an in-station 972 (see FIG. 2A for position of in-station 972) disposed on the wet processing platform 213 and typically located above or adjacent processing station 214 (In-station 972 is depicted in FIGS. 2A and 9A). Similarly, factory interface robot 232 may be used to transfer a substrate 226 into or out of processing stations 214 and 216 or processing stations 235 and 235a. Processing stations 235 and 235a may include one or more stacked dry process chambers, such as anneal, barrier layer deposition, catalytic layer deposition, supercritical clean or dry etch chambers. Barrier layer and catalytic layer deposition take place prior to wet processing of a substrate and the annealing process typically takes place after wet processing. An anneal chamber that may be adapted to perform various aspects of the invention described herein is further described in U.S. patent application Ser. No. 10/996,342, filed Nov. 22, 2004, which is incorporated by reference in its entirety to the extent not inconsistent with the claimed aspects of the invention. When removing substrate 226 from processing stations 214, 216, 235 or 235a, factory interface robot 232 may then deliver substrate 226, which is clean and dry, back to one of the cassettes positioned on the substrate loading stations 234 for removal from cluster tool 200.

Wet processing platform 213, also referred to as the mainframe, includes a centrally positioned mainframe substrate transfer, such as mainframe robot 220. Mainframe robot 220 generally includes one or more blades 222 and 224 configured to support and transfer substrates. Additionally, mainframe robot 220 and the blades 222 and 224 are generally configured to independently extend, rotate, pivot, and vertically move so that the mainframe robot 220 may simultaneously insert and remove substrates to/from the plurality of processing stations 202, 204, 206, 208, 210, 212, 214 or 216 positioned on wet processing platform 213. Similarly, factory interface robot 232 also includes the ability to rotate, extend, pivot, and vertically move its substrate support blade, while also allowing for linear travel along the robot track 250b that extends from the factory interface 230 to the wet processing platform 213.

Generally, the processing stations 202, 204, 206, 208, 210, 212, 214, or 216 may be any of a number of processing chambers utilized in a substrate processing system. More particularly, the processing chambers on the integrated wet processing platform may be configured as ECP cells, rinsing chambers, IBC chambers, SRD chambers, substrate surface cleaning chambers (which collectively includes cleaning, rinsing, and etching chambers), electroless plating chambers (which includes pre- and post-clean chambers, activation chambers, deposition chambers, etc.), brush box chambers and vapor dryer chambers. Each of the various configurations of the wet processing platform and the factory interface will be discussed below.

Each of the respective processing stations 202, 204, 206, 208, 210, 212, 214 and 216 and factory interface robot 232 and mainframe robot 220 are generally in communication with a system controller 211, which may be a microprocessor-based control system configured to receive inputs from both a user and/or various sensors positioned on the cluster tool 200 and appropriately control the operation of cluster tool 200 in accordance with the inputs and/or a predetermined processing recipe. Additionally, the processing stations 202, 204, 206, 208, 210, 212, 214 and 216 are also in communication with a fluid delivery system (not shown) configured to supply the necessary processing fluids to the respective processing cell stations during processing, which is also generally under the control of system controller 211. An exemplary processing fluid delivery system may be found in commonly assigned U.S. patent application Ser. No. 10/438,624, entitled “Multi-Chemistry Electrochemical Processing System,” filed on May 14, 2003, which is hereby incorporated by reference in its entirety to the extent not inconsistent with the present invention.

Cluster Tool Configurations

In an effort to provide a cluster tool that can deposit a seed layer on substrate structures, fill high and low aspect ratio interconnect features with metal and/or selectively form a capping layer over interconnect features, various embodiments of cluster tools may be created. These embodiments are capable of performing one or more of the above processes with high throughput, low defects, minimal oxidation of copper interconnect features and superior adhesion between deposited layers.
A. Hybrid Electroless/Electrochemical Plating System

1. Applications of Cluster Tool Configuration

One embodiment, as illustrated in FIG. 2, of a cluster tool 200 generally includes an electroless plating, electrochemical plating, wafer bevel clean, and spin-rinse drying type processing chambers. Optionally, it may include an ALD barrier processing chamber and/or catalytic layer deposition processing chamber located at processing station 235 prior to performing wet processing. Optionally, it may also include a plasma-enhanced dry etch chamber positioned at processing station 235a for removal of native oxide prior to barrier or catalytic layer deposition. This configuration of plating cluster tool 200 allows the sequential deposition of multiple films on a substrate within a single cluster tool, for example, an ALD or CVD barrier layer formed on substrate structures, such as tantalum nitride (TaN), an electroless copper seed layer formed on the substrate structures or a barrier layer, and lastly ECP copper fill of interconnect features on the substrate. In one embodiment, the catalytic layer is a Ruthenium-containing layer deposited without the use of carbon-containing precursors. Ruthenium-containing catalytic layers offer superior adhesion to subsequent metal layers over the prior art.

This configuration of the cluster tool 200 has advantages over conventional barrier layer, seed layer and gap fill deposition sequences that are performed in separate substrate processing systems, since it reduces the total substrate processing time and hardware costs are greatly reduced. Also, this configuration of plating cluster tool 200 deposits metal layers with improved electrical properties, better defect performance and greater adhesion than metal layers formed on a substrate via multiple substrate processing systems. The sequential formation of a reducing and/or catalytic layer on the barrier layer in the same chamber (i.e., without breaking vacuum) greatly reduces exposure of the barrier layer to oxidation and moisture prior to seed layer deposition, thus improving adhesion of subsequent metal layers. Oxidation of the seed layer surface prior to gap fill deposition is controlled and minimized because gap fill is performed immediately after seed layer formation. Processing substrates in a single cluster tool results in fewer defects compared to processing substrates in multiple processing systems. Hence, this configuration provides better device performance, at a lower cost per substrate processed, and the process is less complicated than the prior art.

In one aspect, this configuration allows the sequential deposition of four layers on a substrate: a barrier layer and/or an electroless seed layer formed on substrate structures, followed by electroless fill of sub-micron high aspect ratio features on the substrate, such as high aspect ratio features 111 in FIG. 1C, followed by ECP fill of low aspect ratio interconnect features on the substrate, such as low aspect ratio feature 112 in FIG. 1C. This configuration allows an ECP overfill process to fill low aspect ratio features on a substrate immediately after high aspect ratio features on the substrate are filled via an electroless process. The results of an ECP overfill process are illustrated in FIG. 1E. Referring to FIG. 1E, substrate structure 110 is shown after the deposition of an electroless seed layer (not shown), an electroless copper film 115, and an ECP film 116. Both high and low aspect ratio features (111 and 112, respectively) are filled with copper with minimal oxidation formed between electroless copper film 115 and the ECP film 116. Hence, with this embodiment, four deposition steps can be performed sequentially in the same cluster tool, thus reducing the number of processing platforms required, minimizing the amount and variation of oxidation that occurs between each deposition step, improving defect performance, improving adhesion of metal films to the barrier layer, and improving electrical properties of deposited metal layers.

2. Description of Cluster Tool Configuration

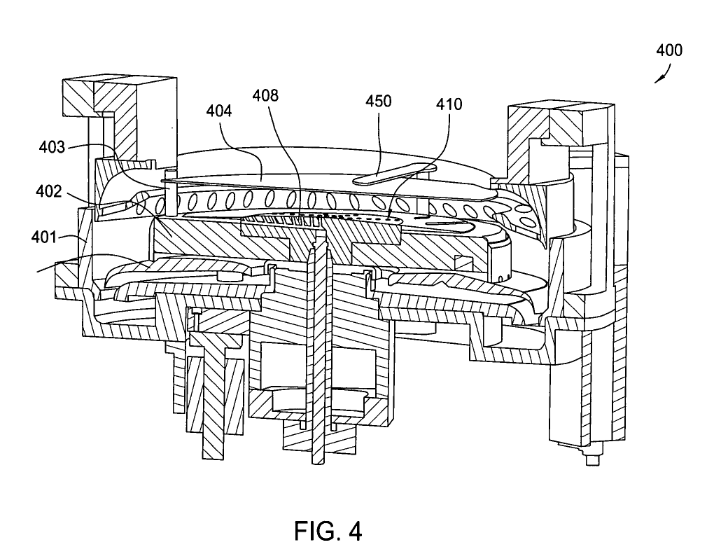

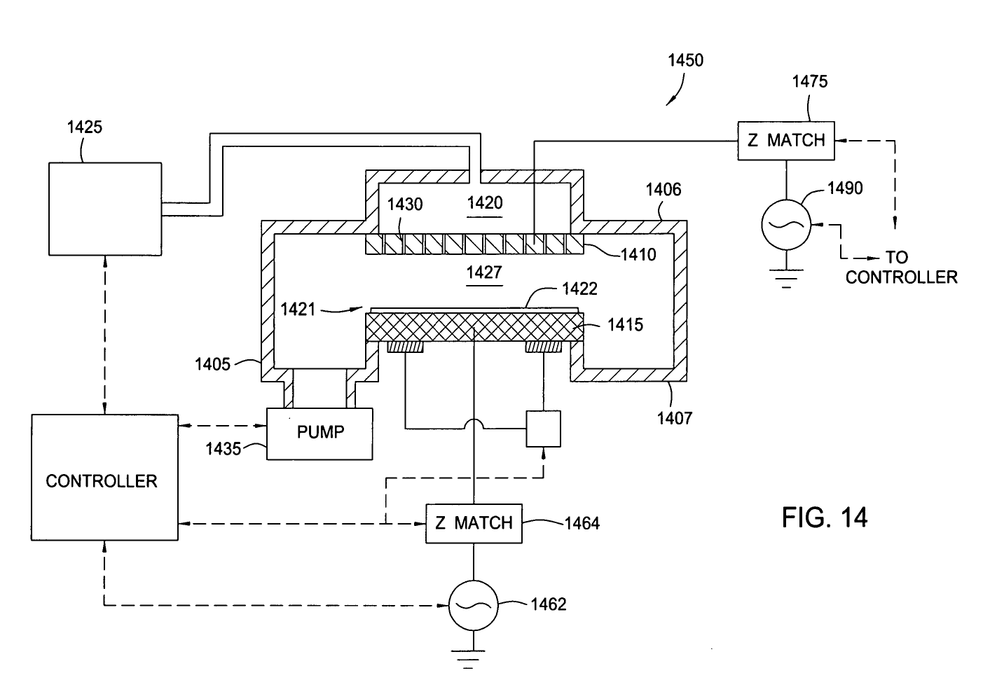

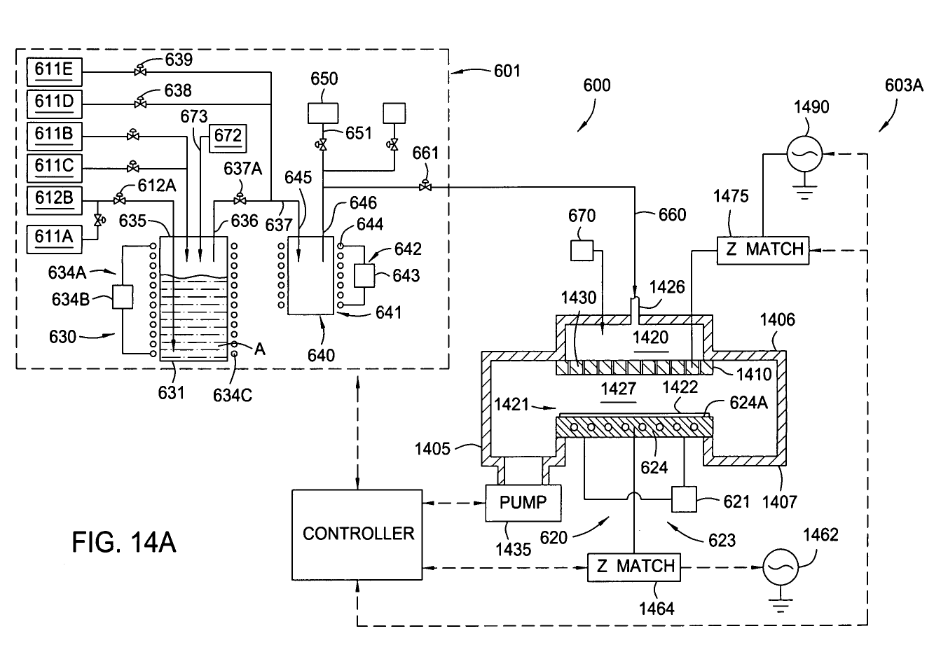

FIG. 2 illustrates one embodiment of a cluster tool 200. In this embodiment, processing station 235 may be configured as an ALD or CVD chamber for the deposition of a barrier layer and/or catalytic layer prior to wet processing. An exemplary ALD chamber is described in greater detail below in conjunction with FIGS. 14 and 14A. In one aspect, processing station 235a may contain a plasma-enhanced dry etch chamber for removal of native oxide prior to barrier layer deposition. An exemplary dry etch chamber is described in greater detail below in conjunction with FIG. 19. Referring to FIG. 2, processing stations 214 and 216 may be configured as an interface between wet processing platform 213 and the generally dry processing stations positioned in factory interface 230 of the plating cluster tool 200. As such, substrates are introduced into wet processing platform 213 by being placed in a holding location, know as an in-station 972 (shown in FIG. 9A) which holds substrates for future wet processing. The in-station 972 is typically located above or below processing stations 214 and 216. In this configuration, the processing stations 214 and 216 may include an SRD chamber that is adapted to perform the final wet processing steps on a substrate before the substrate leaves wet processing platform 213. An exemplary SRD chamber is described in greater detail below in conjunction with FIG. 4.

In one embodiment, processing stations 202 and 204 are an electroless plating twin cell, processing stations 206 and 208 are standard IBC chambers, and processing stations 210 and 212 are two ECP cells. This configuration is also shown in FIG. 2A. An exemplary electroless plating twin cell, IBC chamber and ECP cell are described in greater detail below. These configurations for processing stations 202/204, 206/208, and 210/212 may be rearranged without affecting the functionality of the invention and are defined above only for purposes of description. For example, in order to optimize substrate throughput, the pair of processing stations 202/204 and 206/208 may both be configured as electroless twin plating cells, the processing stations 210/212 may consist of two ECP cells, and processing stations 214 and 216 may be configured as a single SRD and IBC chamber, respectively. The electroless twin cell located at processing stations 202 and 204 is contained by a processing enclosure 302 (described below) and also may include an internal substrate transfer shuttle 605 (described below) for substrate transfers between the first and second processing stations inside each enclosure 302. ECP cells located at processing stations 210 and 212 are typically not in a processing enclosure 302 and generally do not require an internal substrate transfer shuttle 605 between them.

3. Process Sequences

a) Electroless Seed and ECP Gap Fill

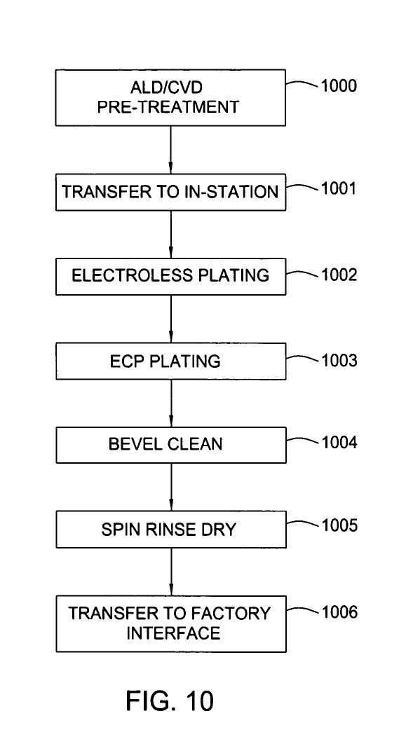

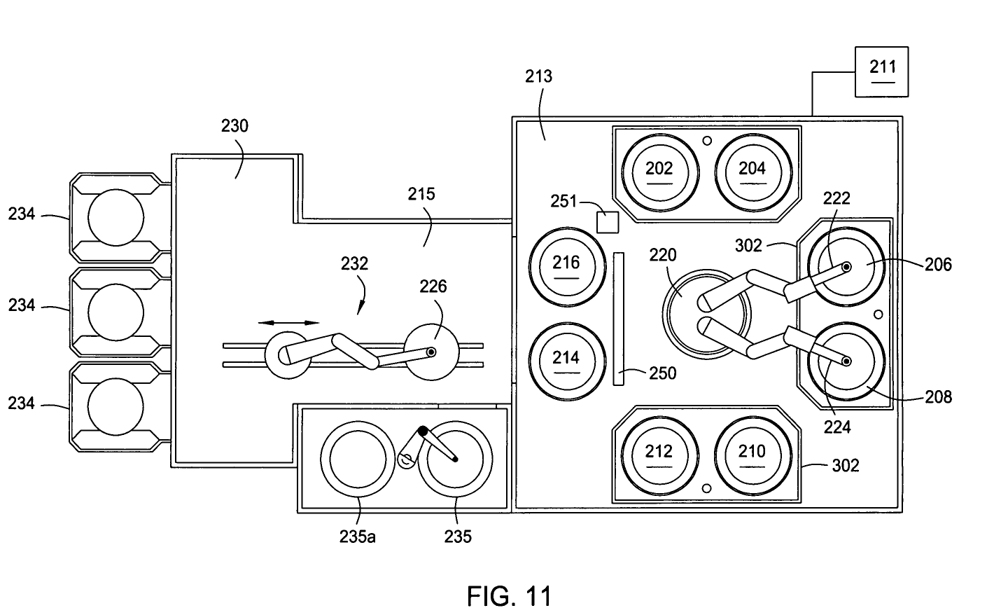

An example of a typical substrate processing sequence for a hybrid electroless/electrochemical plating platform is detailed in the flow chart illustrated in FIG. 10 and results in the deposition of an electroless seed layer and an ECP gap fill layer on a substrate. As noted above, the exemplary hybrid electroless/electrochemical plating platform is configured with processing stations 202 and 204 as an electroless plating twin cell, processing stations 206 and 208 as IBC chambers, processing stations 210 and 212 as ECP cells, and processing stations 214 and 216 as combination SRD chambers/in-stations (shown in FIGS. 2 and 2A). Optionally, processing station 235 is configured as an ALD/CVD pre-treatment chamber and processing station 235a is configured as a dry etch or supercritical clean chamber.

In Step 1000, if desired, native oxide and other contaminants are removed from the substrate in a dry etch chamber or supercritical clean chamber positioned at processing station 235a and the substrate is then pre-treated with a barrier layer, a reducing layer, and/or a catalytic layer in a chamber positioned at processing station 235 prior to wet processing. The processes for deposition of barrier, reducing and catalytic layers on substrates are described below in conjunction with FIGS. 1F-1K. The dry etch chamber and process is described below in conjunction with FIG. 19. The supercritical clean chamber is described below.

In step 1001, factory interface robot 232, also known as the “dry” robot, places a substrate at the in-station associated with processing stations 214 or 216. In step 1002, mainframe robot 220, also known as the “wet” robot, transfers the substrate to processing station 202 in the electroless plating twin cell. All electroless deposition processes take place in an electroless processing station, such as processing stations 202 and 204, with the substrate being transferred between processing stations 202 and 204 via internal substrate transfer shuttle 605 as necessary. In process sequences where activation type processes, e.g., preparatory cleaning, activation and post-activation clean steps, are performed, the activation type processes may be performed in the first processing station of the twin plating cell, processing station 202, and the electroless plating step may be performed in the second processing station, processing station 204.

In some process sequences, the reducing layer and catalytic layer formation steps may be performed in the first processing station, i.e. processing station 202, and the electroless plating step may be performed in the second processing station, i.e. processing station 204.

In cases where no chemical compatibility issues are present between the various cleaning, activation and plating solutions being used, all electroless deposition can take place in a single processing station. Processing stations 202 and 204 then act as two independent electroless plating cells. In this case, step 1002 includes transferring the substrate from one of the in-stations by mainframe robot 220 to either processing station 202 or 204. Further, if the substrate has been pre-treated with a catalytic layer in processing station 235 prior to wet processing, processing stations 202 and 204 may also act as two independent electroless plating cells.

In step 1003, mainframe robot 220 transfers the substrate to either of the ECP cells located at processing stations 210 or 212 so that an ECP gap fill process can be performed to fill the interconnect features such as parallel interconnects 101, 102, and 103, illustrated in FIGS. 1A and 1B.

In step 1004, upon completion of ECP deposition, the substrate is transferred to IBC chamber positioned at station 206 or 208 for removal of the unwanted deposs on the wafer edge and bevel. An exemplary IBC chamber and process are described below in conjunction with FIG. 3. An exemplary IBC chamber and process are described more fully in commonly assigned U.S. patent application Ser. No. 10/826,492, entitled “Integrated Bevel Clean Chamber,” filed on Apr. 16, 2004, which is hereby incorporated by reference in its entirety to the extent not inconsistent with the present invention.

In step 1005, mainframe robot 220 transfers the substrate to SRD chamber positioned at processing stations 214 or 216 for final rinsing and drying. An exemplary SRD chamber and process are described below in conjunction with FIG. 4. A description of an exemplary SRD chamber that may be used in embodiments of the invention may be found in commonly assigned U.S. application Ser. No. 10/616,284 entitled “Multi-Chemistry Plating System,” filed on Jul. 8, 2004, which is hereby incorporated by reference in its entirety to the extent not inconsistent with the present invention.

In step 1006, after the SRD process is complete, factory interface robot 232 removes the substrate from the SRD and the wet processing platform 213.

Hence, this embodiment of plating cluster tool 200 allows the sequential deposition of an electroless seed layer on a substrate followed by ECP fill of interconnect features on the substrate. Optionally, a barrier and or catalytic layer may be deposited on the substrate immediately prior to wet processing, improving adhesion of the subsequent metal layers. This configuration thus allows the amount and variation of oxidation of the seed layer prior to gap fill deposition to be minimized and also reduces the number of processing platforms required to complete three deposition steps on a substrate structure.

In one embodiment, in an effort to maximize substrate processing throughput, the cluster tool 200 may be configured to include two electroless twin plating cells instead of one electroless twin plating cell. In the configuration, the cluster tool may contain, for example, two electroless twin plating cells located at processing stations 202/204 and 206/208, two ECP cells located at processing stations 210/212, a single IBC chamber at processing station 216 and a single SRD chamber at processing station 214. The same substrate processing sequence in FIG. 10 is followed.

b) Electroless Gap Fill and ECP Overfill

Alternately, the hybrid electroless/electrochemical plating configuration may be used for electroless gap fill of high aspect ratio features and then ECP overfill of low aspect ratio features, as illustrated in FIG. 1E. The substrate processing sequence is similar to the sequence shown in FIG. 10, except step 1002. In addition to ALD deposition of a barrier layer and electroless deposition of a seed layer, step 1002 may also include an electroless gap fill of high aspect ratio features step on a substrate. Hence, this configuration of the cluster tool 200 allows the sequential deposition of an ALD barrier layer, an electroless seed layer, and an ECP gap fill layer or the sequential deposition of an ALD barrier layer, an electroless seed layer and electroless gap fill of high aspect ratio features, followed by ECP gap fill of large, low aspect ratio features. In each case, both the amount and variation of oxidation of the first copper layer prior to ECP gap fill are minimized and only a single processing platform is required to complete three or four deposition steps on a substrate structure. Adhesion of metal layers to the TaN barrier is also improved.

In one aspect, the electroless gap fill of high aspect ratio contacts to a source or drain connection point, may include the selective deposition of cobalt- or nickel-based alloys. Such a high aspect ratio contact is similar to aperture 122 and contact layer 123 in FIG. 1F, except that in this instance contact layer 123 consists of a doped-silicon source or drain connection. Preferably, an initial thin layer of nickel or cobalt is deposited at the bottom of the source or drain contact to form a nickel or cobalt silicide covering contact layer 123. This may obviate the need for a barrier layer between the source or drain connection point and the bulk conductive layer, i.e., bulk layer 130, in FIG. 1K, since the nickel silicide may prevent further silicidation of the source or drain, i.e., contact layer 123, by stopping diffusion of the bulk layer 130 into the contact layer 123 and the formation of a silicide during subsequent process steps. Preferably, the bulk layer 130 is deposited in the same process chamber immediately after the initial thin layer of cobalt or nickel is formed at the bottom of the high aspect ratio contact to minimize oxidation. Both of these deposition steps take place in step 1002 as shown in FIG. 10.

In another aspect, the electroless gap fill of high aspect ratio features 111 shown in FIG. 1C may be completed by a selective electroless deposition process. The substrate processing sequence is similar to the sequence shown in FIG. 10, except that step 1002 consists of a bottom-up electroless fill process rather than a conformal fill process. A description of an exemplary bottom-up deposition process that may be used in embodiments of the invention may be found in commonly assigned U.S. Application Ser. No. 60/663,493 [9916L] entitled “Deposition Processes Within a High Aspect Ratio Contact,” filed on Mar. 18, 2005, which is hereby incorporated by reference in its entirety to the extent not inconsistent with the present invention.

4. Description of Process Chambers

Embodiments of the invention include the incorporation of multiple substrate processing chambers onto a single cluster tool, including ECP, IBC, SRD, electroless, plasma-enhanced dry etch, and ALD or CVD chambers. Examples of these chambers and the processes performed on substrates therein are provided below.

a) ECP Cell

In one aspect of the invention, process step 1003 is performed in ECP cells that are used to fill interconnect structures on substrates with a conductive material, such as copper. ECP plating processes are generally two stage processes. A seed layer is first formed over the surface features of the substrate via PVD, CVD, or ALD processes. Then the surface features of the substrate are exposed to an electrolyte solution while an electrical bias is applied between the seed layer and a copper anode positioned within the electrolyte solution. The electrolyte solution contains ions to be plated onto the surface of the substrate and the application of a cathodic type electrical bias causes these ions in the electrolyte solution to be plated onto the seed layer. Conventional electro chemical plating cells generally utilize an overflow weir-type plater containing a plating solution, generally termed a catholyte. The substrate is positioned facedown in the catholyte during plating and an electrical plating bias is applied between the substrate and an anode positioned in a lower portion of the plating cell. This bias causes metal ions in the catholyte to go through a reduction that causes the ions to be plated on the substrate. Transferring substrates to and from such a facedown plating cell configuration generally requires a mainframe robot 220 that is capable of rotating substrates from faceup to face down and vice versa. An exemplary ECP cell is described in commonly assigned U.S. patent application Ser. No. 10/627,336 entitled “Electrochemical Processing Cell,” filed on Jul. 24, 2003, which is hereby incorporated by reference in its entirety to the extent not inconsistent with the present invention.

In an exemplary ECP process, a substrate may be transferred into the plating cell and positioned face-down on a rotatable contact ring. The contact ring may be adapted to make electrical contact around the periphery of the substrate so that the necessary electrical plating bias may be applied to the substrate. The substrate is immersed in the catholyte solution, typically while being rotated by the contact ring between about 5 rpm and about 60 rpm. The catholyte solution may have between about 5 g/l and 50 g/l of sulfuric acid, a copper concentration between about 25 g/l and 70 g/l, and a chlorine concentration between about 30 ppm and about 60 ppm. The catholyte solution may also include additional additives, such as levelers, suppressors, or accelerators. During plating, a plating bias, typically between about 1 V and about 10 V, is applied to the substrate. The substrate may be rotated between about 10 rpm and about 100 rpm during the plating process step. Plating takes place for between 30 sec and 5 minutes, depending on the thickness of plated film desired. The plating bias is then removed and the substrate is positioned above the catholyte solution for removal from the plating cell. Prior to removal from the plating cell, the substrate may be rotated between about 100 and 1000 rpm for between about 1 second and about 10 seconds in order to remove catholyte solution from the substrate.

b) IBC Chamber

In one aspect of the invention, IBC chambers are used for removing deposition at the edge, or bevel, of a substrate and unwanted contamination from the backside of a substrate without damaging structures formed on one or more surfaces of the substrate. This process is generally performed on a substrate after a conductive material has been deposited on the substrate, such as ECP processes or electroless deposition processes. IBC chambers typically include a container, a rotatable substrate support disposed in the container and capable of rotating a substrate at a relatively high rotational velocity, i.e., 500 rpm or higher, and a fluid delivery assembly configured to precisely deliver a liquid etchant to a peripheral portion of the substrate and to deliver a rinsing agent, such as de-ionized (Dl) water, to the entire wafer.

In operation, the IBC chamber can be used to rinse and clean substrates. The cleaning operation may be conducted on both the production surface and the non-production surface of the substrate, or on either surface individually. The cleaning chamber may also be used to clean excess material from the bevel portion of the substrates, i.e., the portion of the conductive layer deposited near the perimeter on the production surface, or topside, and partially onto the backside of the substrate. This process is often termed bevel clean or edge bead removal in the semiconductor art. In another embodiment, the IBC chamber may be used as a combination IBC/SRD chamber, wherein the final rinse and dry function of an SRD chamber, described below and in conjunction with FIG. 4, is incorporated into an exemplary IBC chamber 300 described below in conjunction with FIG. 3. No additional features are required to perform the final rinse and dry function of an SRD chamber in the exemplary IBC chamber 300 as described below.

FIG. 3 illustrates an isometric view of an exemplary IBC chamber 300. The upper components of the exemplary IBC chamber 300 generally include a chamber bowl or chamber having a drain basin 309 in communication with the lower portion of wall 301. The chamber bowl is generally manufactured from a plastic material, a nylon-type material, or metal material coated with a non-metal. The material is generally selected to be non-reactive with the etchant solutions that are used to remove a desired material from the substrate surface. Drain basin 309 is generally configured to receive a processing fluid thereon, and channel the processing fluid to a fluid drain (not shown). A central portion of drain basin 309 includes a substrate chuck 303, which is configured to rotate substrates being processed in the chamber and/or actuate them vertically. Drain basin 309 also includes a plurality of substrate centering pins 304 extending upward therefrom. Substrate centering pins 304 are generally positioned radially around the perimeter of drain basin 309 in an equal spacing arrangement, for example and are designed to precisely locate the substrate in the chamber for optimum cleaning of the bevel. Exemplary IBC chamber 300 further includes at least one rinsing solution dispensing arm 305, along with at least one etching solution dispensing arm 306. Generally, both rinsing solution dispensing arm 305 and etching solution dispensing arm 306 are pivotally mounted to a perimeter portion of exemplary IBC chamber 300, and include a longitudinally extending arm having at least one fluid dispensing nozzle positioned on a distal terminating in thereof. The nozzles are positioned to dispense the respective processing fluids onto a first or upper side of a substrate positioned on the substrate chuck 303. The operation of rinsing solution dispensing arm 305 and etching solution dispensing arm 306 is generally controlled by a system controller, which is configured to precisely position (via pivotal actuation and/or vertical actuation of the respective arms) the distal end of the respective arms over a specified radial position of a substrate being processed, which allows for fluid dispensed from the nozzles positioned at the respective ends of arms 306 and 306 to be dispensed onto precise radial locations of a substrate being processed in exemplary IBC chamber 300. The fluids dispensed on the substrate may be a rinsing solution, e.g., DI water, or acid solution, e.g., an H₂SO₄-containing solution. Further, rinsing solution dispensing arm 305 and etching solution dispensing arm 306 may include a mechanism configured to prevent fluid leakage from the nozzles when the nozzles are not activated. For example, the nozzles may include a vacuum port or suck back valve (not shown) that is configured to receive unwanted fluid drips during off times. Alternatively, nozzles may include a gas aperture that is configured to blow unwanted droplets of fluid away from the substrate surface.

In a typical bevel clean, or IBC process, a substrate is positioned face-up in an IBC chamber, such as IBC 300. The process of positioning a substrate in IBC 300 generally includes insertion, centering, and chucking. The insertion process is conducted by a substrate transfer robot, such as mainframe robot 220. Centering is performed by substrate centering pins 304. A vacuum chuck then holds substrate in place throughout processing. The pre-rinse process includes rotating the substrate between about 150 rpm and about 250 rpm between about 8 seconds and 20 seconds while DI water is dispensed onto the topside of the substrate via rinsing solution dispensing arm 305 at a flow rate of between about 1 l/min and 2 l/min. The substrate is then rotated between about 2000 rpm and about 3500 rpm for about 5 seconds to remove residual DI water. An etchant solution is then applied to the bevel of the substrate via etching solution dispensing arm 306 for between about 10 seconds and about 25 seconds at a flow rate of between about 20 cc/min and about 40 cc/min. The flow of etchant solution may be through a relatively fine nozzle having an aperture with an inner diameter between about 0.25 and 0.5 inches. The nozzle is positioned between about 1 mm and 3 mm from the substrate surface for precise dispensing of etchant solution onto the substrate bevel. A typical etchant solution consists of between about 15 and 25 parts H₂SO₄, between about 350 and 450 parts H₂O₂ and about 1400 parts H₂O. After etchant dispense is complete, rinsing solution is dispensed onto the topside of the substrate at a flow rate of between about 1 l/min and about 2.5 l/min for between about 3 seconds and about 10 seconds while the substrate is rotated between about 100 rpm and 300 rpm. After this rinse step, all liquid dispense is terminated and the substrate is rotated between about 400 rpm and about 4000 rpm to partially or completely dry the substrate.

An exemplary IBC chamber and bevel cleaning method is described in more detail in commonly assigned U.S. patent application Ser. No. 10/826,492, entitled “Integrated Bevel Clean Chamber,” filed on Apr. 16, 2004, which is hereby incorporated by reference in its entirety to the extent not inconsistent with the present invention.

c) SRD Chamber

In one embodiment of the invention, i.e., a hybrid electroless/electrochemical plating platform, SRD chambers are used for the final rinse and spin dry of substrates after wet processing. In operation, SRD chambers generally operate to receive a substrate therein, rinse the substrate with a rinsing fluid, and dry the substrate via spinning the substrate to centrifugally urge fluid off of the substrate surface, while optionally dispensing a drying gas into the cell containing the substrate to further facilitate the drying process. This process is typically performed after completing all wet processing steps on a substrate and immediately prior to transferring the substrate from a wet processing region of a cluster tool.

FIG. 4 illustrates a partial perspective and sectional view of SRD 400, an exemplary substrate spin rinse dry chamber 400. SRD 400 includes a fluid bowl 401. SRD 400 further includes a rotatable hub 402 centrally positioned in the fluid bowl 401. Rotatable hub 402 includes a generally planar upper surface that has a plurality of backside fluid dispensing nozzles 408 formed thereon and at least one gas dispensing nozzle 410 formed thereon. A plurality of upstanding substrate support fingers 403 are positioned radially around the perimeter of rotatable hub 402. Fingers 403 are configured to rotatably support a substrate 404 at the bevel edge thereof for processing in SRD 400. A fluid dispensing arm 550 may be pivotally mounted to the side wall such that a distal end of the arm having a fluid dispensing nozzle positioned thereon may be pivoted to a position over a substrate being processed in the chamber. The fluid dispensing arm 550 is configured to pivot outward over the substrate surface and dispense a processing fluid, typically Dl water, onto the substrate surface proximate the center of the substrate. As noted above, in some embodiments of substrate plating cluster tool, the SRD function as described in exemplary SRD chamber 400 can instead be integrated into an IBC chamber without modifying the exemplary IBC chamber 300. A more detailed description of an exemplary SRD chamber that may be used in embodiments of the invention may be found in previously referenced U.S. application Ser. No. 10/616,284 entitled “Multi-Chemistry Plating System,” filed on Jul. 8, 2003.

In a typical SRD process, a substrate is positioned face-up in an SRD chamber, such as SRD 400, on support fingers 403. In the pre-rinse step, rotatable hub 402 spins the substrate between about 900 rpm and 1700 rpm for between about 2 seconds and about 6 seconds while between about 600 ml and about 1500 ml is dispensed onto the topside and the backside of the substrate via fluid dispensing arm 550 and backside fluid dispensing nozzles 408. In the backside clean step, rotatable hub 402 rotates the substrate between about 40 rpm and 90 rpm for between about 10 seconds and about 20 seconds while between about 200 ml and 500 ml of a cleaning solution, such as ElectraClean™ solution, is applied to the substrate backside and between about 1000 ml and about 1500 ml of rinsing solution is dispensed onto the topside of the substrate. In the post rinse step, between about 1000 ml and 1500 ml of rinsing solution is dispensed on the substrate topside and between about 600 ml and about 1000 ml of rinsing solution is dispensed on the substrate backside while the substrate is rotated at between about 40 rpm and about 90 rpm for about 10 seconds to 16 seconds. In the dry step, all liquid flow is terminated and the substrate is rotated at between 2000 rpm and about 3000 rpm for between about 10 seconds and about 20 seconds. Optionally, between about 2 cfm and about 4 cfm of a dry purge gas may be introduced into the chamber during this step for about 4 seconds to enhance the substrate drying process.

d) Electroless Plating Chambers

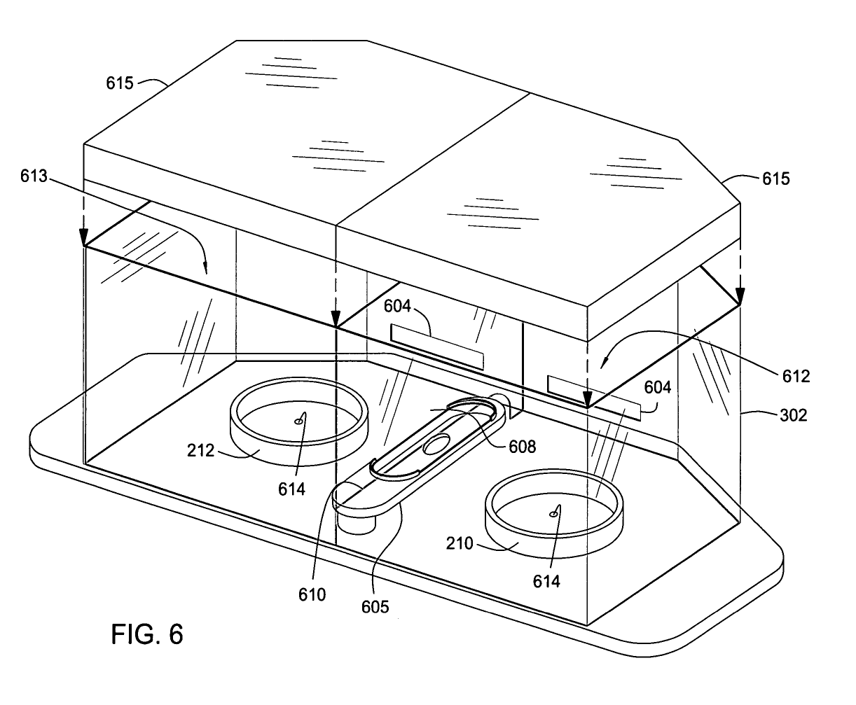

Generally, embodiments of the cluster tool include at least one electroless plating cell. In one aspect, a pair of electroless plating cells are grouped together to advantageously perform an electroless deposition process on a substrate. The pair of electroless plating cells, or electroless plating twin cell, comprise two substrate processing cells positioned on the wet processing platform 213 (see FIG. 2) inside one of the processing enclosures 302. Processing enclosure 302 is described more fully below in conjunction with FIG. 6. Each pair of cells may include electroless plating or plating support cells, e.g., electroless plating cells, electroless activation cells, and/or substrate rinse or clean cells.

In one embodiment, in each processing enclosure 302 there may be two independent electroless plating cells in which the necessary pre-deposition, deposition, and post-deposition processes are all carried out on a substrate in each cell. In this configuration, substrates are transferred into, processed, and transferred out of each processing cell independently.

Alternately, the two cells inside a processing enclosure 302 may comprise a sequential electroless twin cell, wherein one cell is an activation cell, the other is an electroless deposition cell, and the substrate is transferred from the activation cell to the deposition cell via a robot internal to processing enclosure 302. Hence, the entire series of processes required to perform electroless deposition on a substrate, i.e., activation, pre-cleaning, electroless deposition, and post cleaning, is carried out inside a single processing enclosure 302, but the individual processes are divided between the two processing cells that comprise the twin electroless plating cell.

FIG. 6 is a perspective view of an exemplary electroless twin cell with the substrate processing hardware of the electroless plating cells omitted for clarity. In this embodiment, processing stations 210 and 212 (as defined in FIG. 2) are shown in an processing enclosure 302, however other processing chamber station pairs on wet processing platform 213 may be also operate as electroless twin cells, depending on the embodiment of the invention. An processing enclosure 302 defines a controlled processing environment around the pair of processing stations 210 and 212. The processing enclosure 302 may include a central interior wall 608 that generally bisects the processing volume into two equally sized processing volumes, processing volume 612 and processing volume 613. Although the central interior wall 608 is optional, when it is implemented, the central interior wall 608 generally creates a processing volume 612 above processing station 210 and a processing volume 613 above processing station 212. The processing volumes 612 and 613 are substantially isolated from each other by the central interior wall 608, however, a lower portion of the central interior wall 608 includes a slot 610 formed therein. The slot 610 is sized to accommodate an internal substrate transfer shuttle 605 that is positioned between processing stations 210 and 212. The internal substrate transfer shuttle 605 is generally configured to transfer substrates between the respective processing stations (210⇄212) without requiring the use of the mainframe robot 220. Internal substrate transfer shuttle 605 may be a vacuum chuck-type substrate support member that is configured to pivot about a point such that a distal substrate supporting end of internal substrate transfer shuttle 605 moves in the direction of arrow 603 (shown in FIG. 2) to transfer substrates between the respective processing stations 210 and 212. The processing volumes 612 and 613 also include a valved port 604 that is configured to allow a robot, such as mainframe robot 220 to access the respective processing volumes 612 or 613 to insert and remove substrates therefrom.

Each processing enclosure 302 also includes an environmental control assembly 615 (shown in FIG. 6 removed from contact with the processing enclosure 302 for clarity) positioned on an upper portion of the processing volumes 612 and 613. The environmental control assembly 615 includes a processing gas source configured to provide a processing gas to the processing volumes 612 and 613. The processing gas source is generally configured to provide a controlled volume of an inert gas, such as nitrogen, helium, hydrogen, argon, and/or mixtures of these or other gases commonly used in semiconductor processing, to the processing volumes 612 and 613. Thus, environmental control assembly 615 purges the interior of processing volumes 612 and 613 of gases that may degrade the electroless plating process, such as oxygen. The environmental control assembly 615 further includes a particle filtration system, such as a HEPA-type filtration system. The particle filtration system is used to remove particulate contaminants from the process gas entering the processing volumes 612 and 613. The particle filtration system is also used to generate a generally linear and equal flow of the processing gas toward processing stations below. The environmental control assembly 615 may further include devices configured to control humidity, temperature, pressure, etc. in the respective processing volumes 612 and 613. The system controller 211 may be used to regulate the operation of the environmental control assembly and exhaust port 614, along with other components of the cluster tool 200 (shown in FIG. 2), to control the oxygen content within the processing volumes 612 and 613 in accordance with either a processing recipe or inputs received from sensors or detectors (not shown) positioned in the processing volumes 612 and 613. Each processing station (processing stations 210 and 212 in FIG. 2) inside a processing enclosure 302 also includes at least one exhaust port 614, which is positioned to facilitate uniform flow of the processing gas from the gas supply in environmental control assembly 615 toward the processing stations 210 and 212 respectively. Optionally, multiple radially positioned ports (not shown) may be instead be positioned around the processing stations 210 and 212.

The combination of the environmental control assembly 615, the exhaust port 614, and the system controller 211 also allows cluster tool 200 to control the oxygen content of the processing volumes 612 and 613 during specific processing steps, wherein one processing step may require a first oxygen content for optimal results and a second processing step may require a second oxygen content for optimal results, where the first and second oxygen contents are different from each other. In addition to the oxygen content, system controller 211 may be configured to control other environmental parameters of the processing enclosure, such as temperature, humidity, pressure, etc. as desired for a particular processing sequence. These specific parameters may be modified by heaters, chillers, humidifiers, dehumidifiers, vacuum pumps, gas sources, air filters, fans, etc., all of which may be included in the environmental control assembly 615 and positioned in fluid communication with the processing volumes 612 and 613 and controlled by the system controller 211. Hence, processing enclosure 302 provides an environmentally controlled enclosure for each electroless deposition cell therein.

i) Selective Electroless Plating Process

A selective electroless deposition process sequence, e.g., the capping layer process or bottom-up contact fill, generally includes preparatory cleaning, electroless deposition, post-deposition clean, and optionally cleaning the bevel edge of the substrate. In one aspect, the selective deposition process may include activation and post-activation clean steps. The selective electroless deposition process may be performed in exemplary electroless twin cells located at processing stations 210 and 212 as described above. In addition, vapor drying of the substrate may also be performed as part of the process sequence before or between preparatory cleaning steps, immediately prior to the electroless deposition step, or subsequent to substrate bevel clean. An exemplary vapor dryer method and apparatus is described below.

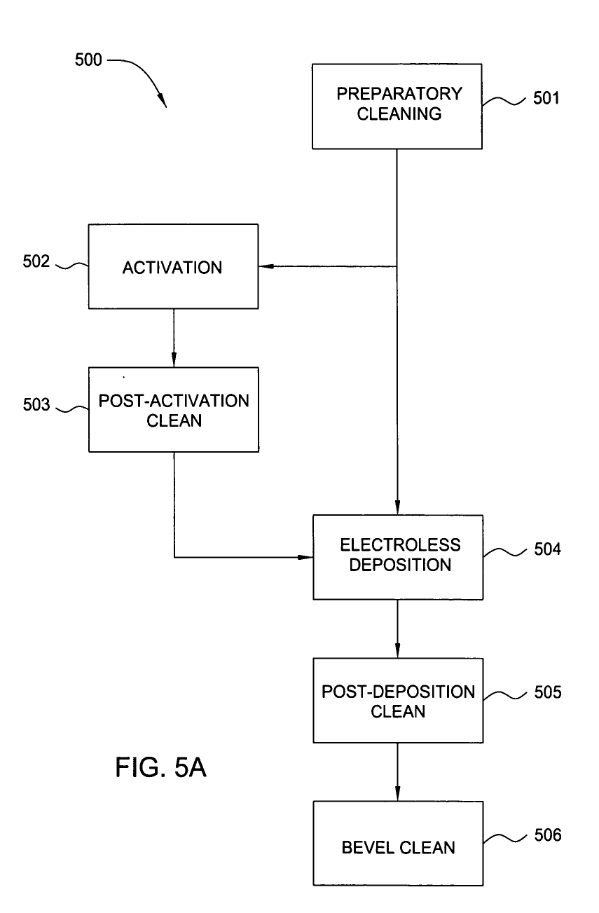

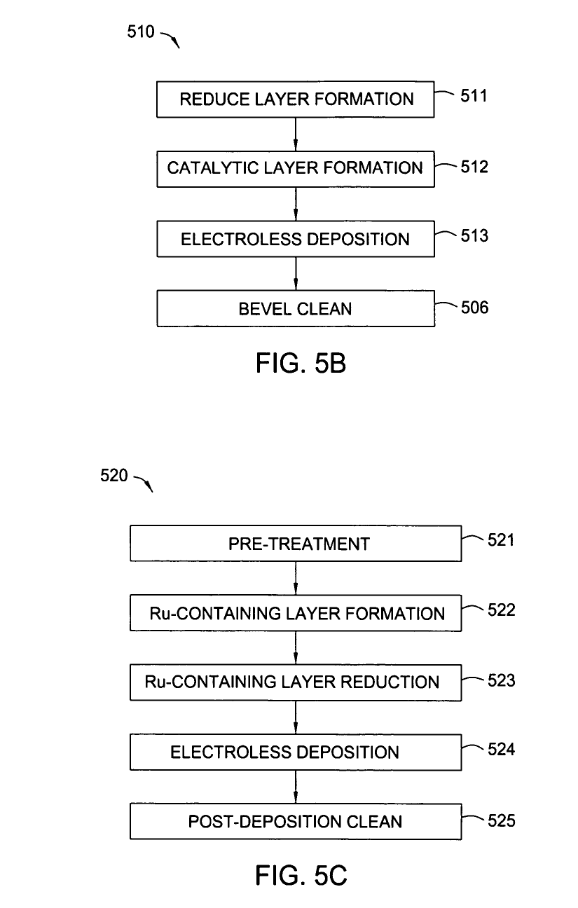

A selective electroless deposition process sequence 500 for forming a capping layer on a copper-filled interconnect is illustrated in FIG. 5A and described below.

Step 501, Preparatory Cleaning: When selectively depositing a layer on interconnect features, preparatory cleaning is necessary to ensure that no metallic residues are present on exposed dielectric surfaces of the substrate structure prior to electroless deposition. As illustrated in FIGS. 1A and 1B, if metallic residues are not removed, electroless deposition of the capping material may occur on these metallic residues and possibly cause an electrical short between the devices formed on or above the substrate structure 100. Preparatory cleaning also removes surface oxides and residues from previous process steps from the metallic surfaces of the substrate structure that may inhibit the electroless deposition process. Preparatory cleaning steps may include application of a dielectric clean solution to the substrate structure, brush cleaning of the substrate surface either in situ or in an external brush box chamber, application of megasonic or ultrasonic energy to the substrate structure, and application of a metal cleaning solution to the substrate structure. Rinsing and vapor drying may generally be performed after any of these steps.

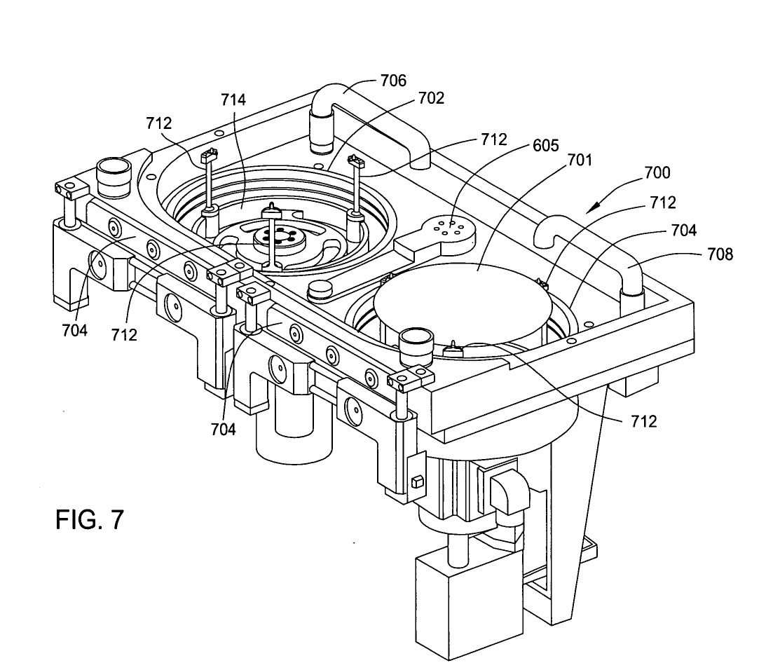

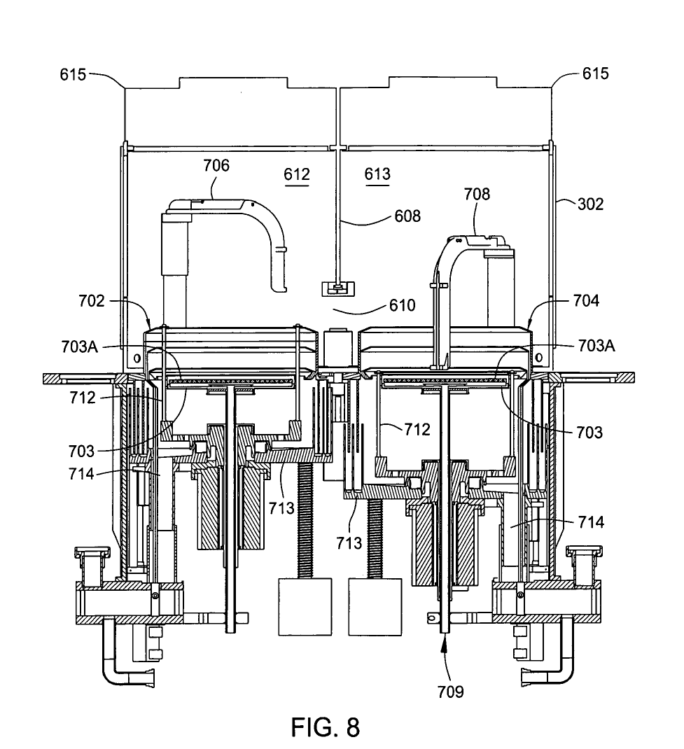

In a typical preparatory cleaning process, a substrate is transferred into an electroless deposition chamber or activation chamber—as described below in conjunction with FIGS. 7 and 8—and a dielectric clean solution is applied to the surface of the substrate and subsequently rinsed off with a rinsing solution. The dielectric clean solution may include one or more acids, such as citric acid, HF, and/or HCl, as well as corrosion inhibitors to prevent corrosion of exposed conductive surfaces on the substrate. The rinsing solution is typically DI water. The substrate is rotated in the chamber via a rotatable substrate support between about 50 and 500 rpm during the application of the dielectric clean solution and rinsing solution and is rotated between about 500 and 2000 rpm to substantially remove the rinsing solution. The dielectric clean solution and the rinsing solution are applied using one or more fluid dispensing arms, described below in conjunction with FIG. 8. Specific cleaning solution application times and concentrations vary depending on the material make-up of substrate structure 100 and parallel interconnects 101, 102, and 103 (see FIG. 1A). Generally, a thickness of less than about 50 Å from the parallel interconnects 101, 102 and 103 and the substrate structure 100 is etched by the dielectric clean solution.

A description of dielectric solution chemistries and processes of cleaning the substrate structure as described herein may be found in commonly assigned U.S. patent application Ser. No. 10/970,839, entitled, “Electroless Cobalt Alloy Deposition Process,” filed on Oct. 21, 2004, and commonly assigned U.S. patent application Ser. No. 10/967,644, entitled, “Selective Self-Initiating Electroless Capping of Copper With Cobalt-Containing Alloys,” filed Oct. 15, 2004, both of which are incorporated by reference herein to the extent not inconsistent with the claimed aspects and description herein. An exemplary apparatus and method for in situ brush cleaning of substrates and suitable metal cleaning solutions are disclosed in commonly assigned U.S. patent application Ser. No. 11/004,014, entitled “Method And Apparatus For Electroless Capping With Vapor Drying,” filed on Dec. 2, 2004, which is hereby incorporated by reference in its entirety to the extent not inconsistent with the present invention. For situations when in situ brush cleaning is not performed in the electroless twin cell, an exemplary brush box chamber for brush cleaning of substrates is described below.

Step 502, Activation: When an activation step is used, the electroless deposition process generally involves the application of an activation solution to the surface of the substrate structure, which deposits an activation metal seed layer on all the exposed metal portions of a substrate structure, for example the top surfaces of parallel interconnects 101, 102, and 103 in FIG. 1A. Any oxidation of the exposed metal portions of a substrate structure after the above cleaning processes may be detrimental to proper deposition of the activation seed layer. Therefore, a short waiting time, i.e., less than about 15 seconds, is desired between the preparatory cleaning of the substrate and the application of the activation seed layer and these two process steps are preferably performed sequentially in the same chamber. The presence of a substantially inert gas environment also minimizes oxidation of exposed metal surfaces after preparatory cleaning and prior to activation seed layer deposition. Due to incompatibilities of the chemistries typically used in the metal cleaning step and the activation step, in some cases these processes may be carried out in two or more different processing stations, for example 210 and 212 in environmentally controlled processing enclosure 302 (FIG. 2). Hence, an electroless plating twin cell allows preparatory cleaning and activation steps to be performed on a substrate in different processing stations with very little oxidation. The waiting time between processes in processing stations 210 and 212 is short; only a few seconds are required for the substrate to be transferred between the processing stations 210 and 212. The low oxygen environment inside processing enclosure 302 further minimizes unwanted oxidation of the substrate structure after preparatory cleaning in processing station 210 and prior to activation seed layer deposition in processing stations 212. It is important to note that when there are no chemical incompatibilities between the chemistries used in the various steps of the electroless plating process, i.e., the dielectric clean, metal clean, activation, post-activation clean, deposition, and post-deposition clean, then the entire electroless plating process may be carried out in the same processing station. Hence, processing stations 210 and 212 can instead be used as two independent electroless processing stations and no substrate transfer between the two is required.

In a typical activation process, the substrate has just been transferred into an electroless deposition chamber as described above. The substrate is rotated between about 50 and 500 rpm and an activation solution is applied to the surface via one or more fluid dispensing arms, described below in conjunction with FIG. 8. The application time necessary to form a suitable activation metal seed layer varies depending on activation solution concentration and composition, but is generally less than about 2 minutes. A description of chemistries and methods for performing an activation process may be found in previously referenced U.S. patent application Ser. No. 10/970,839, entitled, “Electroless Cobalt Alloy Deposition Process” and in U.S. patent application Ser. No. 10/967,644, entitled, “Selective Self-Initiating Electroless Capping of Copper With Cobalt-Containing Alloys.”

Step 503, Post Activation Clean: Post-activation clean may be performed by applying a post-activation clean solution to the substrate structure as well as optionally brushing the substrate structure and/or applying ultrasonic or megasonic energy to the substrate structure. Post activation solutions typically include one or more acids, requiring this step to be performed in a processing station 210 or 212 that only uses other compatible chemistries. As noted above, the entire electroless deposition process may be performed on a substrate in either processing station 210 or 212 if there are no chemical compatibility issues between any of the processing solutions.

For a post activation clean process that does not involve brushing of the substrate structure or the application of ultrasonic or megasonic energy, the substrate is typically rotated via a rotatable substrate support between about 50 and 500 rpm while a post-activation clean solution is applied to the substrate surface and subsequently rinsed off using one or more fluid application arms. Application time of the post-activation clean solution varies depending on the concentrations and composition of the activation solution and post-activation clean solution, but is typically less than 2 minutes. Substrate brush cleaning and/or ultrasonic or megasonic cleaning may take place in a dedicated cleaning chamber, such as a brush box chamber, described below. The post-activation clean removes any excess activation solution so that when depositing a capping layer, the activation metal seed layer remains primarily on the exposed portions of interconnect features. Remaining activation solution on the dielectric portions of the substrate structure may cause undesirable electroless deposition. A short waiting time between the end of the activation process and the post-activation clean is also beneficial for the electroless plating process and generally both steps are performed sequentially in the same processing station.

Step 504, Electroless Deposition: A conductive layer may be deposited by application of an electroless deposition solution to the substrate structure. When an activation step is used, the deposition takes place on the activation metal seed layer. This step may be conducted in one or both of the processing stations 210 or 212 located in processing enclosure 302. Metals that may be deposited include copper, cobalt and nickel, among others. Since the electroless deposition process is highly temperature dependent, temperature control of the substrate and deposition solution is critical to the process and methods and apparatus for temperature control in an exemplary electroless deposition processing station are detailed below in conjunction with FIGS. 7 and 8. A more detailed description of chemistries, processes, and methods for depositing an activation metal seed layer, completing a post-activation clean step, and depositing an electroless layer may be found in previously referenced U.S. patent application Ser. No. 10/970,839, entitled, “Electroless Cobalt Alloy Deposition Process” and in U.S. patent application Ser. No. 10/967,644, entitled, “Selective Self-Initiating Electroless Capping of Copper With Cobalt-Containing Alloys,” filed Oct. 21, 2004.

Step 505, Post-Deposition Clean: As stated above, it is critical to remove conductive material that has accumulated on dielectric surfaces of a substrate structure during the electroless deposition process when forming a capping layer. A post-deposition clean process may be performed by applying a post-deposition clean solution to the substrate structure subsequent to electroless deposition. The post-deposition clean solution may be applied to the surface of the substrate via one or more fluid delivery arms for 1 to 60 seconds while the substrate is rotated between about 50 and 500 rpm. Post-deposition clean solutions may be slightly acidic clean solutions, such as ElectraClean™ solution, available from Applied Materials Inc. of Santa Clara, Calif. or a CX-100 solution available from Wako Chemicals USA, Inc. of Richmond, Va. Alternately, the post-deposition clean solution may be slightly basic, i.e., with a pH value between about 7.5 and 9.5. Additionally, scrubbing the surface of the substrate with a brush-like material and/or applying sonic energy to the substrate structure may also be part of the post-deposition clean process. Both wafer scrubbing and sonic cleaning may be performed in-situ but are typically performed in a dedicated post-deposition clean chamber, such as a brush box.

In a typical post-deposition clean process, the substrate is rotated between about 50 and 500 rpm in the deposition chamber via a rotatable substrate support and an electroless deposition solution is applied to the surface via one or more fluid dispensing arms for about 1 to 60 seconds. The substrate is then rinsed in-situ, i.e., rotated between about 50 and 500 rpm while rinse solution is applied to the substrate surface. The substrate is then spun dry, i.e., rotated between about 500 and about 2000 rpm for between about 5 seconds and 60 seconds. The substrate is then removed from the electroless deposition chamber and transferred to a brush box chamber integrated on the wet processing platform of the invention and external to the electroless plating twin cell. In the brush box chamber, the surface of the substrate is brush cleaned using roller-type brushing devices. An exemplary brush box chamber is described below. A detailed description of solutions that may be used for this process as well as an exemplary apparatus and method for in situ brush cleaning of substrates and suitable metal cleaning solutions may be found in previously referenced U.S. patent application Ser. No. 11/004,014, entitled “Method And Apparatus For Electroless Capping With Vapor Drying.”

Step 506, Bevel Clean: The portion of the conductive layer deposited near the perimeter on the topside, on the substrate bevel, and partially onto the backside of the substrate may be removed by means of an IBC chamber, described above in conjunction with FIG. 3, or in-situ. Unwanted process residues and deposition may also be removed from the backside of the substrate during this step. An exemplary method and apparatus for performing a bevel clean process in an IBC chamber is described above in conjunction with FIG. 3.

Alternatively, process sequence 520 in FIG. 5C illustrates a selective electroless deposition process sequence for bottom-up contact fill with nickel or cobalt-tungsten alloy, such as for high aspect ratio features 111 shown in FIG. 1C. The process steps are illustrated in FIG. 5C and described below.

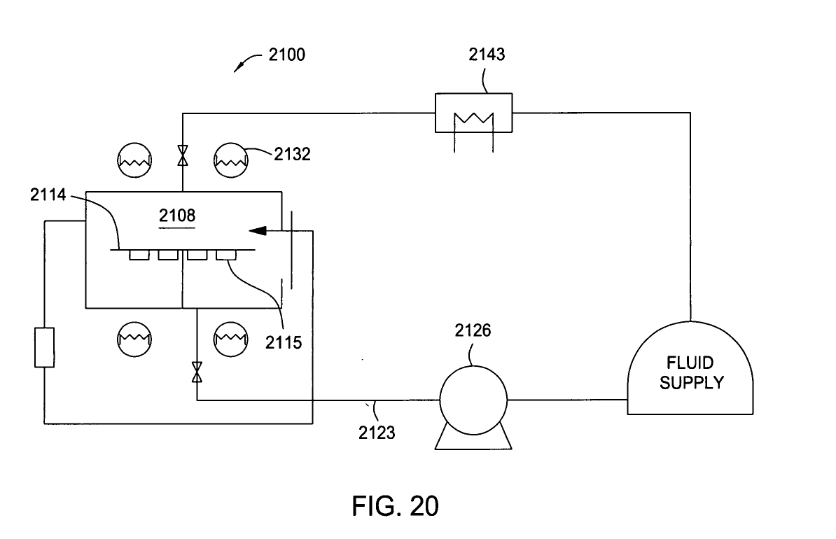

Step 521, Pre-treatment: Removal of native oxides on contact surfaces is necessary prior to electroless deposition for acceptable contact resistance for high aspect ratio features. Aspects of the invention may use a plasma-enhanced dry etch chamber, described below in conjunction with FIG. 19, or a super-critical clean chamber, described below in conjunction with FIG. 20, positioned in processing station 235 or 235a for native oxide removal. Alternately, a plasma pre-treatment process, such as a plasma-soak process, may be conducted in a process chamber capable of plasma vapor deposition, wherein the contact surface is exposed to a reducing plasma or reducing vapor in an ALD or CVD chamber positioned in processing station 235 or 235a. An exemplary plasma pre-treatment process and an exemplary vapor pre-treatment process that may be used in embodiments of the invention are described below in conjunction with FIGS. 14 and 14A, and in previously referenced U.S. Patent Application Ser. No. 60/663,493 [9916L]. In another aspect, the substrate surface is exposed to a wet clean process to remove native oxides formed thereon. The wet clean process may be an in situ process performed in the same processing cell as a subsequent electroless deposition process.

Step 522, Ruthenium-Containing Layer Formation: A ruthenium-containing layer, preferably ruthenium oxide, is selectively deposited on the contact surface by exposing the substrate to a ruthenium tetroxide vapor. The ruthenium-containing layer may be deposited on the substrate by use of a vapor deposition process, such as an in situ generated process, or in a liquid deposition process, such as an aqueous solution or suspension. The former method may be performed in an ALD or CVD deposition chamber positioned at processing station 235 or 235a, preferably in the same chamber wherein step 521 is performed on the substrate. The latter method, i.e., the liquid deposition process, may be performed in the same processing cell as the aqueous cleaning method described in step 521. Ruthenium tetroxide is a strong oxidant and therefore readily reacts with any exposed metal oxide layers (e.g., tungsten oxide and other contact layer materials) to form a consistent and catalytic active layer of ruthenium oxide selectively on the bottom of the contact. Formation of a ruthenium-containing layer on a substrate is described in greater detail below in conjunction with FIG. 14A and in previously referenced U.S. Patent Application Ser. No. 60/663,493 [9916L].

Step 523, Ruthenium-Containing Layer Reduction: The ruthenium-containing layer, preferably ruthenium oxide, is exposed to a reductant, forming a catalytic ruthenium metal layer on the bottom surface of the contact. The ruthenium oxide layer may be exposed to a reducing plasma, such as a hydrogen-containing plasma, to form metallic ruthenium layer from the ruthenium-containing layer on the bottom surface of the contact. This process may be performed in an ALD or CVD deposition chamber positioned at processing station 235 or 235a, preferably in the same chamber wherein step 522 is performed on the substrate. Alternately, the ruthenium oxide layer may be exposed to a vapor deposition process to remove oxygen and form a ruthenium metal layer on the bottom surface of the contact, preferably in the same vapor deposition chamber that performed step 522 on the substrate. An exemplary plasma pre-treatment process and an exemplary vapor pre-treatment process that may be used in embodiments of the invention are described below in conjunction with FIG. 14 and in previously referenced U.S. Patent Application Ser. No. 60/663,493 [9916L].

Step 524, Electroless Deposition: This step is similar to electroless deposition step 504 described above, except that nickel or cobalt-tungsten alloys are the preferred materials for bottom-up fill of high aspect ratio contacts. A more detailed description of chemistries, processes, and methods for depositing a bottom-up contact fill may be found in previously referenced U.S. Patent Application Ser. No. 60/663,493 [9916L].

Step 525, Post Deposition Clean: This step is similar to step 505, described above. Optionally, for embodiments of the invention that contain a brush box chamber, a post deposition clean may be performed on the substrate in which electroless cobalt and nickel overgrowth is removed via an optimized brush box process. This final clean step eliminates the need for an additional CMP process to be performed on the substrate when electroless cobalt and/or nickel deposition is used for contact fill.

ii) Non-Selective Electroless Plating Process

The non-selective electroless deposition of a metal layer on a substrate generally includes the formation of a catalytic layer on a substrate and electroless deposition of the metal layer onto the catalytic layer. A non-selective electroless deposition process sequence 510 is illustrated in FIG. 5B and described below.

Step 511, Reducing Layer Formation: In some embodiments, a reducing layer may be formed on the substrate prior to non-selective electroless deposition. The reducing layer is formed on a substrate by modifying the surface of the substrate by a plasma deposition process. Reducing layer formation may take place in an ALD or CVD chamber prior to wet processing of the substrate. One method and apparatus that may be used to form a reducing layer is described below in conjunction with FIGS. 1F-1K and 14 and in the commonly assigned U.S. Patent Application Ser. No. 60/648,004 [9906L], entitled “Deposition of an Intermediate Catalytic Layer on a Barrier Layer for Copper Metallization,” by Timothy W. Weidman, filed Jan. 27, 2005, which is incorporated by reference herein in its entirety to the extent not inconsistent with the claimed aspects and description herein.

Step 512, Catalytic Layer Formation: The catalytic layer may be formed by different methods. In one embodiment, the catalytic layer is formed from the reducing layer of step 511 either in an ALD or CVD chamber. An exemplary plasma-enhanced ALD chamber and process is described below in conjunction with FIGS. 1H and 14. In another embodiment, the catalytic layer is formed from the reducing layer of step 511 by a liquid deposition process. In this case, the catalytic layer may be formed on the substrate in an electroless plating cell, for example one processing station of an electroless plating twin cell, such as processing station 210. In another embodiment, the catalytic layer may be formed directly on a substrate via a liquid deposition process in a processing station of an electroless plating twin cell, for example processing station 210. The metal ion source for this process may be nickel, cobalt, palladium, ruthenium, rhenium and/or copper. The metal source used for this process may be a sulfate, chloride, or nitrate. The electroless deposition may then be completed in the second processing station of the twin cell, for example processing station 212. In another embodiment, described below in conjunction with FIG. 14A, a ruthenium-containing catalytic layer may be formed directly onto the substrate without a reducing layer being present.

Step 513, Electroless Deposition: This step is similar to electroless deposition step 504 described above. A conductive layer may be deposited by application of an electroless deposition solution to the substrate structure. The deposition takes place on the catalytic seed layer. This step may be conducted in one or both of the exemplary processing stations 210 or 212 located in processing enclosure 302. A description of chemistries, processes, and methods for depositing an electroless layer may be found in previously referenced U.S. patent application Ser. No. 10/970,839, entitled, “Electroless Cobalt Alloy Deposition Process” and in U.S. patent application Ser. No. 10/967,644, entitled, “Selective Self-Initiating Electroless Capping of Copper With Cobalt-Containing Alloys.”

Step 506, Bevel Clean: This is identical to step 506 described above and shown in FIG. 5A. In addition, vapor drying of the substrate may also be performed as part of the process sequence after the substrate bevel clean step.

iii) Electroless Plating Chamber

FIG. 7 is a perspective view of an exemplary electroless plating twin cell with processing enclosure 302 removed for clarity. In operation, embodiments of the deposition station 700 may be used to perform a dielectric clean process, a metal clean process, an electroless activation process, a catalytic layer deposition process, an electroless plating process, a post clean process, a post-deposition bevel clean process and/or other processing steps that may be used in an electroless process. The deposition station 700 generally represents an embodiment of the processing cells illustrated in FIGS. 2 and 6. Electroless processing stations 702 and 704 correspond to electroless processing stations 210 and 212, respectively. The processing stations 702 and 704 illustrated in deposition station 700 may be an electroless activation station and an electroless deposition station, respectively. Alternatively, each processing station 702 and 704 may each be configured to perform all steps of the electroless deposition process. Internal substrate transfer shuttle 605 is positioned between processing stations 702 and 704 and is configured to transfer substrates between the respective processing stations 702 and 704. Each of processing stations 702 and 704 includes a rotatable substrate support assembly 714 that is configured to support a substrate 701 for processing in the respective station in a face up orientation, i.e., the processing surface of the substrate 701 is facing away from the support assembly 714. In other embodiments, the process chamber may be utilized in a face down configuration without varying from the basic scope of the invention. In FIG. 7, processing station 702 does not have a substrate 701 illustrated on the substrate support assembly 714, while processing station 704 has a substrate 701 supported on the support assembly 714 to show the respective stations in both a loaded and empty states. Generally, the hardware configuration of the respective processing stations 702 and 704 will be the same, however, embodiments of the invention are not limited to configurations where the processing stations 702 and 704 have identical hardware therein. For example, the inventors contemplate that the deposition station, i.e., processing station 704 may incorporate the functionality of an IBC chamber, which is further described herein, while the activation station, i.e., processing station 702 may be configured with no post-plating bevel clean capability.

Processing stations 702 and 704 are typically configured with a substrate support assembly 714, which comprises substrate support fingers 712 and lift assembly 713 (shown in FIG. 8), for transferring and precisely centering substrates in the processing station. Processing stations 702 and 704 each include a fluid dispensing arm 706 and 708, respectively, that is configured to pivot over the substrate 701 during processing to dispense a processing fluid onto the front side or production surface of the substrate 701. The fluid dispensing arms 706 and 708 may also be configured to be positioned precisely with respect to the substrate vertically. The vertical and/or angular position of the fluid dispensing portion of the arms 706 and 708 may be adjusted during processing of a substrate if desired. The dispensing arms 706 and 708 may include more than one fluid conduit therein, and as such, the dispensing arms 706 and 708 may be configured to dispense multiple fluid solutions therefrom onto the substrate 701. In one embodiment, one or both dispensing arms 706 and 708 include a fluid conduit and fluid application nozzle configured to perform an in situ bevel clean process and/or final rinse on substrates subsequent to electroless deposition.

FIG. 8 is a sectional view of an exemplary pair of processing stations 702 and 704. The sectional view of FIG. 8 also illustrates the processing enclosure 302 that defines the processing volumes 612, 613 that are divided by the central interior wall 608, as described above with respect to FIG. 6. Because substrate temperature is critical to the electroless process, each of the processing stations 702 and 704 includes a substrate processing platen assembly 703 that forms a substantially horizontal upper surface configured to be positioned immediately below a substrate during processing (FIG. 8). The upper surface of platen assembly 703 consists of a diffusion member 703A that evenly distributes fluids dispensed to the backside of a substrate.

In a typical electroless deposition process, a substrate 701 (shown in FIG. 7) is transferred into processing station 704 and is secured by fingers 712. Fingers 712 vertically position the substrate 701 just above platen assembly 703. Because of the sensitivity to temperature of this process, the substrate, as well as fluids applied to the substrate surface, may be temperature-controlled. The substrate temperature may be controlled by filling the space between the fluid diffusion member and the substrate 701 with a temperature-controlled fluid dispensed by conduit 709 to platen assembly 703. The fluid contacts the backside of the substrate 701 and transfers heat thereto to heat the substrate during the electroless plating process. Fingers 712 then rotate substrate 701 at a suitable rpm for evenly distributing process fluids dispensed thereon, i.e., 50-500 rpm, and fluid dispensing arm 708 pivots over substrate 701 and dispenses an electroless deposition solution onto the front side or production surface of the substrate 701. Dispense time of the electroless deposition solution onto the substrate is strongly dependent on substrate and electroless deposition solution temperature as well as concentration and composition of the electroless deposition solution, but is generally between about 5 seconds and about 480 seconds. In the case of a capping layer, the typical deposition rate is between about 100 Å/min and about 200 Å/min.

A more detailed description of an exemplary electroless twin cell that may be used in embodiments of the invention may be found in commonly assigned U.S. patent application Ser. No. 10/996,342, entitled “Method And Apparatus For Electroless Deposition of Metals Onto Semiconductor Substrates,” filed on Nov. 22, 2004, which is hereby incorporated by reference in its entirety to the extent not inconsistent with the present invention.

e) Chamber for Barrier, Reducing and Catalytic Layer Deposition

i) General Description of Chamber

To reduce electromigration and improve adhesion of subsequent metal layers, embodiments of the invention include treatment of substrates prior to wet processing in wet processing platform 213, such as the deposition of a barrier layer, a reducing layer and/or a catalytic layer. In one embodiment, all of these substrate pre-treatments may be performed in a single ALD, CVD or vapor deposition chamber, preferred examples of which are described below. In other embodiments, barrier layer and/or reducing layers may be formed on a substrate via an ALD, CVD or vapor deposition process while the catalytic layer may be formed in a fluid processing chamber as described above.

In one embodiment, a standard capacitively-coupled or inductively-coupled plasma deposition chamber may be used for barrier layer, reducing layer and catalytic layer deposition on substrates. Such a chamber typically includes a sub-atmospheric process region located above a temperature-controlled substrate support and beneath a conductive showerhead, which acts as a plasma-controlling device. A process gas supply provides process gas to the process region through the showerhead. In other embodiments, a remote plasma source may be used. In another embodiment, a deposition chamber contains a ruthenium tetroxide generating apparatus (described below in conjunction with FIG. 14A) that is adapted to deposit a ruthenium-containing layer on a substrate surface without the use of carbon-containing precursors.

ii) Barrier, Reducing and Catalytic Layer Deposition Process

Referring to FIGS. 1F-1K, pre-treatment of a substrate 120 may generally include depositing a barrier layer 124 on a substrate surface, exposing the barrier layer 124 to a soak process to form a reducing layer 126, depositing a catalytic layer 128 on barrier layer 124 by exposing reducing layer 126 to a catalytic metal-containing precursor and depositing conductive layers such as seed layer 129 and/or bulk layer 130 on catalytic layer 128. In one embodiment, barrier layer 124 (e.g., TaN) is deposited by an ALD or CVD process. Barrier layer 124 is exposed to a reductant during a soak process that may include phosphine, diborane or silane. A reducing layer is then formed on the barrier layer. Reducing layer 126 is exposed to a catalytic metal-containing precursor to deposit catalytic layer 128 on barrier layer 124. In one example, the catalytic metal-containing precursor is introduced to the substrate by a liquid deposition process, performed in an electroless plating twin cell, described above. In another example, the catalytic metal-containing precursor is introduced to the substrate by a vapor phase deposition process, preferably in the same chamber in which barrier layer 124 and reducing layer 126 were deposited on substrate 120. This embodiment has the added advantage of minimizing exposure of barrier layer 124 to oxygen or moisture, which improves adhesion of subsequent metal layers. In another embodiment, a catalytic layer 128 containing ruthenium may be deposited directly onto barrier layer 124 or dielectric layer 121 with no reducing layer 126 present. This embodiment requires no carbon-containing precursors for formation of catalytic layer 128, improving adhesion of subsequent conductive layers. Catalytic layer 128 contains a catalytic metal that may include ruthenium, cobalt, rhodium, iridium, nickel, palladium, platinum, alloys thereof or combinations thereof. Thereafter, a conductive layer, such as seed layer 129 and/or bulk layer 130 is deposited on catalytic layer 128. For example, seed layer 129 may be a copper or ruthenium seed layer or a secondary barrier layer, such as a cobalt tungsten phosphide layer. Bulk layer 130 may be a copper-containing conductive layer deposited by electroless deposition or electrochemical deposition. This process sequence is described below and illustrated in FIGS. 1F-1K with cross-sectional views of a substrate structure at different stages of the sequence. Alternately, reducing, catalytic and conductive layers may be deposited as described above on substrate structures without a barrier layer.

Barrier layer 124 may be formed on the dielectric layer 121 and in aperture 122, as depicted in FIG. 1G. Barrier layer 124 may include one or more barrier materials such as, tantalum, tantalum nitride, tantalum silicon nitride, titanium, titanium nitride, titanium silicon nitride, tungsten nitride, silicon nitride, ruthenium nitride, derivatives thereof, alloys thereof and combinations thereof. Barrier layer 124 may be formed using a suitable deposition process including ALD, CVD, PVD or combinations thereof. For example, tantalum and/or tantalum nitride is deposited as barrier layer 124 by an ALD process as described in commonly assigned U.S. patent Ser. No. 10/281,079, filed Oct. 25, 2002, and is herein incorporated by reference. In one example, a Ta/TaN bilayer may be deposited as barrier layer 124, wherein the tantalum layer and the tantalum nitride layer are independently deposited by ALD, CVD and/or PVD processes. The above ALD process may be performed in a dry side pre-treatment chamber of cluster tool 200, such as an ALD chamber located at processing station 235.

Embodiments of ALD have been described above as the deposition of a binary compound of tantalum nitride utilizing pulses of two reactants, wherein a “pulse” is a quantity of a particular compound that is intermittently or non-continuously introduced into a reaction zone of a processing chamber. In the deposition of other elements or compounds, pulses of two or more reactants may also be used. For example, an ALD process for the tertiary compound tantalum silicon nitride utilizes pulses of tantalum, silicon and nitrogen precursors.

A typical process of depositing a TaN barrier layer by an ALD process includes providing pulses of a tantalum-containing compounds, such as PDMAT (Ta[NMe₂]₅) with a flow rate in a range from about 20 sccm to about 1,000 sccm and with a pulse time of about 2 seconds or less. Pulses of ammonia may be provided with a flow rate in a range from about 20 sccm and about 1,000 sccm and with a pulse time of about 1 second or less. An argon purge gas may have a flow rate in a range from about 100 sccm to about 1,000 sccm and may be continuously provided or pulsed into the process chamber. The time between pulses of the tantalum-containing compound and the nitrogen-containing compound may be about 5 seconds or less, preferably in a range from about 0.5 seconds to about 2 seconds. The substrate is preferably maintained with a temperature in a range from about 50° C. to about 350° C. at a chamber pressure in a range from about 1.0 Torr to about 50.0 Torr. A more detailed description of ALD formation of a barrier layer on a substrate and precursors useful for this process are disclosed in commonly assigned U.S. Patent Application Ser. No. 60/648,004[9906L], entitled “Deposition of an Intermediate Catalytic Layer on a Barrier Layer For Copper Metallization,” filed on Jan. 27, 2005, which is hereby incorporated by reference in its entirety to the extent not inconsistent with the present invention.

To form a reducing layer 126 on barrier layer 124, as depicted in FIG. 1H, barrier layer 124 is exposed to a volatile reducing precursor (VRP), preferably diborane, phosphine, silane, hydrazine, hydrogen, or combinations thereof. This is referred to as a soak process. The soak process for forming reducing layer 126 may be performed by exposing barrier layer 124 to the VRP directly or diluted in a carrier gas, for example in a vapor deposition chamber. The soak process may be conducted in the same deposition chamber as the barrier layer deposition process, described above. Alternately, reducing layer 126 is formed on barrier layer 124 by a plasma soak process. The plasma soak process includes exposing barrier layer 124 to a reducing plasma (i.e., a reductant or derivative thereof in the plasma state of matter) to form reducing layer 126. Preferably, the reductant is silane, diborane, phosphine or combinations thereof. In this case a chamber capable of plasma vapor deposition is necessary, for example the substrate may be placed into a plasma enhanced ALD (PE-ALD) a plasma enhanced CVD (PE-CVD) or HDP-CVD chamber. An exemplary plasma vapor deposition chamber is described below.

In a typical process of forming a reducing layer 126 on a barrier layer 124, barrier layer 124 is exposed to a plasma-soak process for a pre-determined time. The soak process may occur for about 5 minutes or less. During the soak process, the substrate is maintained at a temperature in a range from about 20° C. to about 350° C. and the process chamber is maintained at a pressure in a range from about 0.1 Torr to about 750 Torr. The VRP may be diluted in a carrier gas, such as helium, argon or nitrogen. The carrier gas may be provided at a flow rate in a range between about 100 sccm and about 5,000 sccm. The VRP may be provided at a flow rate in a range from about 5 sccm to about 500 sccm. The plasma may be formed using RF power delivered to the plasma generating devices utilized in the plasma chamber, e.g., a showerhead in a capacitively coupled chamber, where the RF power ranges from 100 W to 10,000 W at an RF frequency between about 0.4 kHz and about 10 GHz. A more detailed description of forming a reducing layer on a substrate and precursors useful for this process are disclosed previously referenced U.S. Patent Application Ser. No. 60/648,004 [9906L], entitled “Deposition of an Intermediate Catalytic Layer on a Barrier Layer For Copper Metallization.”

A catalytic layer 128 is deposited on barrier layer 124 as depicted in FIG. 1I. Catalytic layer 128 is formed by exposing reducing layer 126 to a catalytic metal-containing precursor. Reducing layer 126 chemically reduces the catalytic metal-containing precursor to form catalytic layer 128 on barrier layer 124 containing the respective metal from the precursor. In one example, the catalytic metal-containing precursor is delivered to reducing layer 126 by a vapor deposition process, such as an ALD process or a CVD process. The process chamber may be a typical vapor deposition chamber as used during ALD, CVD or PVD processes. Preferably, the catalytic layer forming chamber is the same chamber in which the barrier and reducing layers were also deposited on the substrate. Alternatively, the catalytic metal-containing precursor is delivered to reducing layer 126 by a liquid deposition process, such as an aqueous solution containing the precursor dissolved therein. In embodiments of the invention using a liquid deposition process to form catalytic layer 128, the process is conducted in an electroless plating cell, described above.

Catalytic layer 128 includes at least one catalytic metal and usually contains the oxidized remnants of the reducing layer 126. The catalytic metal may include ruthenium, cobalt, rhodium, iridium, nickel, palladium, platinum, osmium, alloys thereof or combinations thereof. Generally, the chemical reaction between reducing layer 126 and the catalytic metal-containing precursor forms the metallic form of the catalytic metal (e.g., Ru⁰ or Co⁰) and/or the respective boride, phosphide, silicide, nitride and combinations thereof. The catalytic layer adheres to the barrier layer as well as to the subsequently deposited conductive layer, such as a seed layer 129 or a bulk layer 130, illustrated in FIGS. 1J and 1K, respectively.

A typical process of forming a catalytic layer 128 on barrier layer 124 involves exposing reducing layer 126 to a vaporized catalytic metal-containing precursor. The vapor deposition process is conducted at a temperature high enough to vaporize the catalytic metal-containing precursor and drive the reduction reaction to completion. The temperature range varies according to the particular catalytic metal-containing precursor used during the deposition. Generally, the substrate is maintained in a range from about 25° C. to about 350° C., preferably from about 50° C. to about 250° C. The process chamber may be a typical vapor deposition chamber as used during ALD, CVD or PVD processes. The process chamber is maintained at a pressure relative to the temperature, precursor and particular process. Generally, the pressure is maintained in a range from about 0.1 Torr to about 750 Torr. The catalytic metal-containing precursor is exposed to reducing layer 126 from about 1 second to about 120 seconds. The catalytic metal-containing precursor may be delivered purely or diluted in a carrier gas that includes nitrogen, hydrogen, argon, helium or combinations thereof. In one example, a reducing plasma is exposed to the substrate for 10 seconds at a flow rate of about 500 sccm, consisting of 450 sccm helium carrier gas and 50 sccm silane.

Seed layer 129 is deposited as the conductive layer on catalytic layer 128 and may be deposited using conventional deposition techniques, such as ALD, CVD, PVD, electroless, or electroplating. Preferably, seed layer 129 is deposited immediately after deposition of catalytic layer 128, minimizing oxidation of catalytic layer 128 and improving overall adhesion of subsequently deposited conductive layers. Hence, in the preferred embodiment of the invention, seed layer 129 is deposited on a substrate in the same cluster tool in which catalytic layer 128 is deposited on the substrate, ideally in the same processing chamber. In one aspect, wherein the catalytic metal-containing precursor is delivered to reducing layer 126 by a liquid deposition process, seed layer 129 is a copper seed layer deposited on a substrate by an electroless deposition process in the same electroless plating twin cell that deposited catalytic layer 128 on the substrate. Seed layer 129 may have a thickness range from about a single molecular layer to about 100 Å. Generally, seed layer 129 contains copper, ruthenium, cobalt, tantalum or other metal or alloy known to exhibit good adhesion to a subsequent bulk layer 130. A typical method and apparatus for depositing a seed layer 129 via an electroless deposition process is described above in conjunction with FIGS. 7 and 8.

Ruthenium oxides may be used for the formation of catalytic and/or bulk conductive layers, ruthenium tetroxide (RuO₄) being the preferred ruthenium compound used for this process. Ruthenium tetroxide may be prepared with an in situ generation process, described below in conjunction with FIG. 14A, by exposing a metallic ruthenium source to an oxidizing gas, such as ozone. The in situ generated ruthenium tetroxide is immediately introduced into the process chamber. Ruthenium tetroxide is a strong oxidant and therefore readily reacts with the reducing layer to form a ruthenium-containing catalytic layer on the barrier layer or dielectric layer.

iii) Ruthenium Layer Deposition Process

A ruthenium-containing layer may be selectively or non-selectively deposited on device features formed on the surface of a substrate by use of a ruthenium tetroxide-containing gas. It is believed that the selective or non-selective deposition of a ruthenium-containing layer on the surface of the substrate is strongly dependent on the temperature and type of surfaces that are exposed to the ruthenium tetroxide containing gas. It is also believed that by controlling the temperature of a substrate at a desired temperature below, for example about 180° C., a ruthenium layer will selectively deposit on certain types of surfaces. At higher temperatures, for example greater than 180° C., the ruthenium deposition process from a ruthenium tetroxide containing gas becomes much less selective and thus will allow a blanket film to deposit on all types of surfaces. In one aspect, the deposition of a ruthenium containing layer is used to promote the adhesion and filling of subsequent layers on the surface of the substrate. In another aspect, the properties of the ruthenium containing layer deposited on the surface of the substrate is specially tailored to fit the needs of the devices formed on the surface of the substrate. Typical desirable properties include the formation of crystalline or amorphous metallic ruthenium layers on the surface of the substrate so that the formed layer(s) can act as a barrier layer, a catalytic layer for subsequent electroless or electroplating processes, or even fill a desired device feature. Another desirable property of a ruthenium-containing layer is the formation of a ruthenium dioxide layer (RuO₂) on the surface of the substrate to, for example, promote selective bottom up growth of an electroless and/or electroplated layer, or form an electrode that is compatible ferroelectric oxides (e.g., BST, etc.), piezoelectric materials (e.g., PZT, etc.) used to form various Micro-Electro-Mechanical Systems (MEMS) devices.

In general, a ruthenium-containing catalytic layer with desirable properties is formed on a barrier layer or a dielectric layer by generating a ruthenium tetroxide containing gas and exposing a temperature controlled surface of a substrate to the gas. This involves forming a ruthenium tetroxide gas, collecting the gas in a source vessel, purging the source vessel of excess oxygen, heating the source vessel and delivering the ruthenium tetroxide-containing gas to the process chamber to form the catalytic layer. As noted above, in various aspects of the invention it may be desirable to selectively or non-selectively form a metallic ruthenium layer or a ruthenium dioxide layer on the surface of the substrate to form a ruthenium containing layer. An exemplary apparatus and method of forming a ruthenium tetroxide containing gas to form a ruthenium containing layer on a surface of a substrate is described herein.

In an exemplary vapor deposition process, the deposition gas, containing ruthenium tetroxide, is delivered to the surface of the substrate having a reducing layer containing P-H functional groups formed thereon. The reducing layer containing P-H functional groups may be formed by use of a phosphine soak process or phosphine plasma soak process. During the process the substrate is maintained at a temperature of about 200° C. After exposing the reducing layer to the ruthenium tetroxide containing gas for about 60 seconds, a ruthenium phosphide layer is formed on the barrier layer. Alternately, a ruthenium-containing catalytic layer may be formed directly onto a barrier layer or dielectric layer with no reducing layer.

iv) Exemplary Barrier, Reducing and Catalytic Layer Deposition Chamber

The barrier, reducing and catalytic layer deposition described above may be performed in a plasma processing chamber. FIG. 14 illustrates an exemplary capacitively coupled plasma chamber, chamber 1450. A sidewall 1405, a ceiling 1406 and a base 1407 enclose chamber 1450 and form a process area 1421. A temperature-controlled substrate pedestal 1415, which supports a substrate 1422, mounts to the base 1407 of chamber 1450. A vacuum pump 1435 controls the pressure within chamber 1450, typically holding the pressure below 5 milliTorr (mT). A gas distribution showerhead 1410 consists of a gas distribution plenum 1420 connected to the gas supply 1425 and communicating with the processing region 1427 over the substrate 1422 through plural gas nozzle openings 1430. The gas distribution showerhead 1410, made from a conductive material (e.g., anodized aluminum, etc.), acts as a plasma controlling device by use of the attached impedance match element 1475 and RF power source 1490. A bias RF generator 1462 applies RF bias power to the temperature-controlled substrate pedestal 1415 and substrate 1422 through an impedance match element 1464. With the appropriate gases provided by gas supply 1425, the barrier layer, reducing layer and/or catalytic layer deposition described above may all be performed in chamber 1450.

v) Exemplary Ruthenium Layer Deposition Chamber

In general, the method and apparatus described herein is adapted to selectively or non-selectively deposit a ruthenium containing layer on device features formed on the surface of a substrate by use of a ruthenium tetroxide containing gas. In a preferred embodiment of the invention, a deposition chamber 600, illustrated in FIG. 14A, is used to generate and deposit a ruthenium-containing catalytic layer on a substrate. Deposition chamber 600 is similar to chamber 1450 described above and identical reference numerals have been used to designate elements common to each chamber. In one embodiment, the ruthenium containing layer is formed on a surface of a substrate by creating ruthenium tetroxide in an external vessel and then delivering the generated ruthenium tetroxide gas to a surface of a temperature controlled substrate positioned in a processing chamber.

The deposition chamber 600 generally contains a process gas delivery system 601 and a sealed processing chamber 603A. The sealed processing chamber 603A generally contains all of the components described above in conjunction with FIG. 14 and also a temperature controlled substrate support 623, a remote plasma source 670 and the process gas delivery system 601 connected to the inlet line 1426. The temperature controlled substrate support 623 generally contains a conductive block 624, a heat exchanging device 620 and a temperature controller 621. The conductive block has a substrate supporting surface 624A and is attached and sealed to the base 1407 to form a sealed processing chamber 603A.

In one embodiment of the deposition chamber 600, a process gas delivery system 601 is adapted to deliver a fluid to the processing region 1427 so that a catalytic or adhesion layer can be formed on the substrate surface. The process gas delivery system 601 generally contains one or more gas sources 611A-E, an ozone generating device 612B, a processing vessel 630, a source vessel assembly 640, and an outlet line 660 attached to the inlet line 1426 of the sealed processing chamber 603A. The one or more gas sources 611A-E are generally sources of various carrier and/or purge gases that may be used during processing in the sealed processing chamber 603A. The one or more gases delivered from the gas sources 611A-E may include, for example, nitrogen, argon, helium, hydrogen, or other similar gases.

In one embodiment of the process gas delivery system 601, the processing vessel 630 contains a vessel 631, a temperature controlling device 634A, an input port 635 and an output port 636. The vessel 631 is generally an enclosed region made of or coated with glass, ceramic or other inert material that will not react with the processing gas formed in the vessel 631. The vessel 631 contains a volume of a ruthenium metal (item “A”), preferably in a porous-solid or pellet form, to promote the formation of ruthenium tetroxide when the ozone gas is delivered to the vessel 631. The temperature controlling device 634A generally contains a temperature controller 634B and a heat exchanging device 634C, which are adapted to control the temperature of the vessel 631 at a desired processing temperature during the ruthenium tetroxide generation process. Typically, the ruthenium metal “A” contained in vessel 631 is maintained at a temperature between about 20° C. and 60° C. to enhance ruthenium tetroxide formation in vessel 631. In one aspect, the heat exchanging device 634C is a temperature controlled fluid heat exchanging device, a resistive heating device and/or a thermoelectric device that is adapted to heat and/or cool the vessel 631 during different phases of the process.

In one embodiment, a remote plasma source 672 is connected to the processing vessel 630 via the RPS inlet line 673 so that in different phases of the ruthenium tetroxide formation process the ruthenium metal can be regenerated by injecting H radicals into the vessel 631 to reduce any formed oxides on the surface of the ruthenium metal. Regeneration is necessary when an undesirable layer of ruthenium dioxide (RuO₂) is formed on a significant portion of the exposed ruthenium metal contained in the vessel 631.

Referring to FIG. 14A, the source vessel assembly 640 generally contains a source vessel 641, a temperature controller 642, an inlet port 645 and an outlet port 646. The source vessel 641 is adapted to collect and retain the ruthenium tetroxide generated in the processing vessel 630. The source vessel 641 is generally lined, coated or made from a glass, ceramic, plastic (e.g., Teflon, polyethylene, etc.), or other material that will not react with the ruthenium tetroxide and has desirable thermal shock and mechanical properties. When in use the temperature controller 642 cools the source vessel 641 to a temperature less than 20° C. to condense the ruthenium tetroxide gas on to the walls of the source vessel. The temperature controller 642 generally contains a temperature controller device 643 and a heat exchanging device 644, which are adapted to control the temperature of the source vessel 641 at a desired processing temperature.

In operation, deposition chamber 600 forms a ruthenium-containing layer on a substrate. Initially, ruthenium tetroxide gas is formed and collected in the source vessel 641. Ozone generated in ozone generating device 612B is then delivered to the ruthenium metal contained in vessel 631 to form a flow of ruthenium tetroxide gas, which is collected in the source vessel 641. Therefore, an ozone containing gas, typically containing between about 10 wt. % and 20 wt. % of ozone, flows across the ruthenium metal which causes ruthenium tetroxide to be formed and swept away by the flowing gas. During this process the gas flow path is from the ozone generating device 612B, in the input port 635, across the ruthenium metal (item “A”), through the output port 636 in the vessel 631 through the process line 637 and into the source vessel 641. Cooling the ruthenium tetroxide and causing it to condense or solidify on the walls of the source vessel 641, the unwanted oxygen- and ozone-containing components in the ruthenium tetroxide-containing gas can be separated and removed.

Oxygen- and ozone-containing components in the ruthenium tetroxide-containing gas are separated and removed while the walls of the source vessel are maintained at a temperature of 20° C. or below. This is performed by closing the ozone isolation valve 612A and flowing one or more purge gasses from the one or more of the gas sources 611 B-C through the processing vessel 630, into the process line 637, through the source vessel 641 and then through the exhaust line 651 to the exhaust system 650. Removal of these unwanted oxygen and unreacted ozone components is especially important where copper interconnects are exposed on the surface of the substrate, since copper has a high affinity for oxygen and is corroded easily in the presence of an oxidizing species.

In one embodiment, ruthenium tetroxide is delivered to sealed processing chamber 603A after the source vessel 641 has been purged and valve 637A is closed to isolate the source vessel 641 from the processing vessel 630. Prior to delivery of ruthenium tetroxide to sealed processing chamber 603A, the source vessel 641 is heated to a temperature to cause the condensed or solidified ruthenium tetroxide to form ruthenium tetroxide gas at which time the one or more of the gas sources 611 (e.g., items 611 D-E), the isolation valve 638, the isolation valve 639 and process chamber isolation valve 661 are opened, causing a ruthenium tetroxide containing gas to flow into the inlet line 1426, through the gas distribution showerhead 1410, into a processing region 1427 and across the substrate 1422 so that a ruthenium-containing layer can be formed on a substrate surface. Alternately, a ruthenium tetroxide-containing gas is formed when a nitrogen containing gas is delivered from the gas source 611D and a hydrogen-containing gas is delivered from the gas source 611E through the source vessel and to the sealed processing chamber 603A. In another embodiment, the remote plasma source 670 is utilized to enhance the process of forming a metallic ruthenium layer via the injection of H radicals, generated by the remote plasma source, into the processing region 1427 to reduce any formed oxides on the surface of the ruthenium metal. In another embodiment, process gas delivery system 601 includes multiple source vessel assemblies 640, which alternately collect and dispense the generated ruthenium tetroxide. This avoids interruption of substrate processing in chamber 1450 when one source vessel must collect ruthenium tetroxide.

In a typical process for depositing a ruthenium-containing layer, a plasma is generated during the deposition process to improve the deposited ruthenium-containing layer's properties. A typical process using a remote plasma source (RPS) may include using 1000 sccm of H₂, 1000 sccm of argon, an RF power of 350 W and a frequency of about 13.56 MHz.

A more detailed description of a ruthenium tetroxide deposition apparatus and method that may be used in embodiments of the invention may be found in commonly assigned U.S. Patent Application Ser. No. 60/648,004 [9906L], entitled “Deposition of an Intermediate Catalytic Layer on a Barrier Layer For Copper Metallization,” filed Jan. 27, 2005.

vi) Combined Vapor/Liquid Deposition Chambers

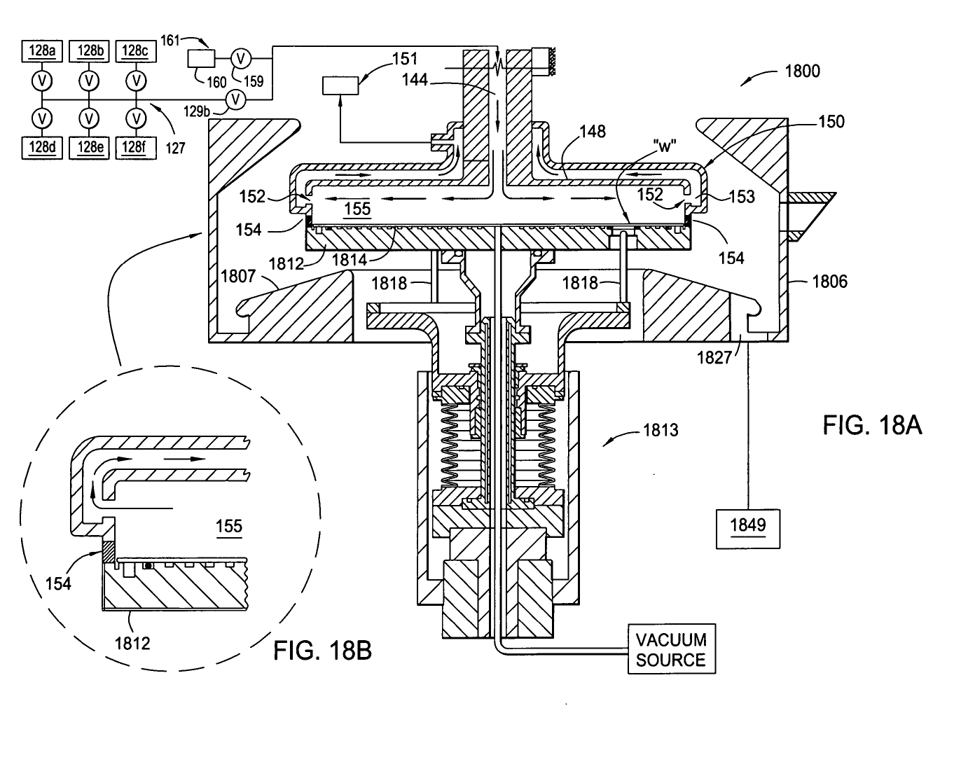

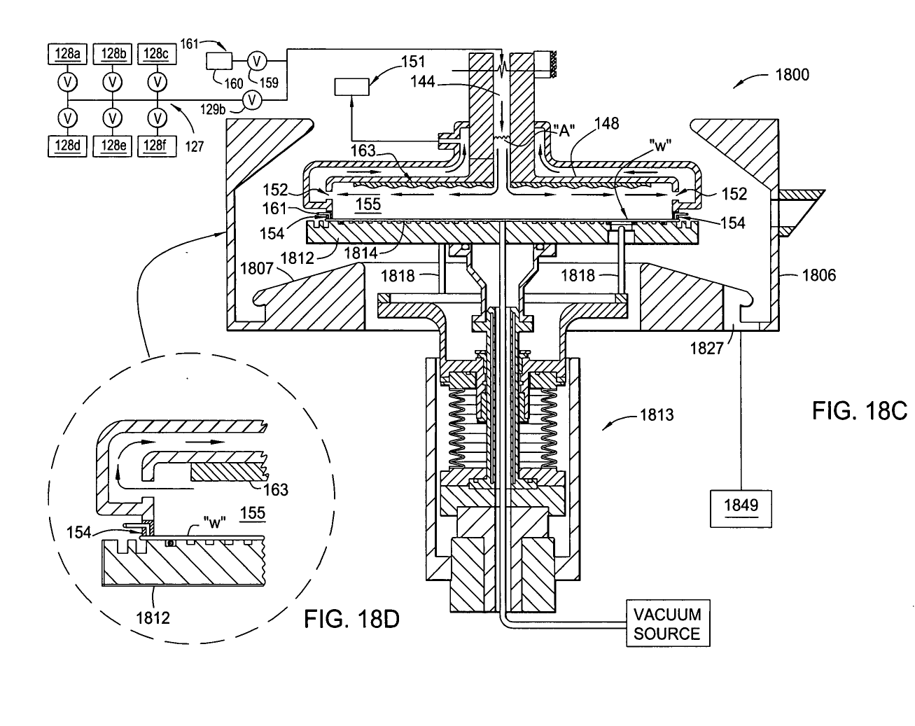

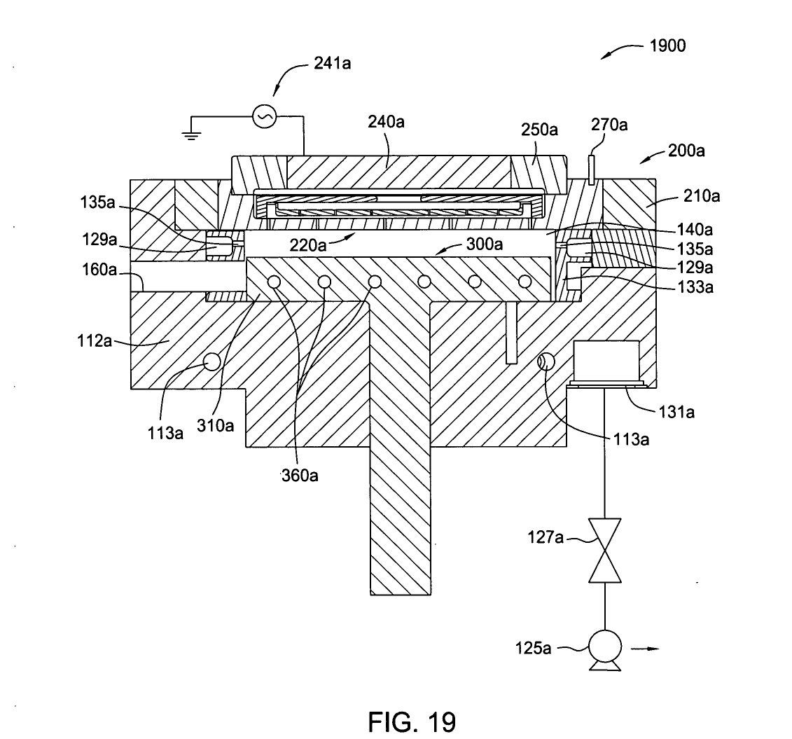

In another embodiment, the reducing and catalytic layers described above may be deposited on a substrate in a fluid deposition chamber 1800, described below and shown in FIGS. 18A and 18B. Because both vapor and liquid deposition may take place in fluid deposition chamber 1800, the reducing and catalytic layers may be deposited via vapor deposition processes and subsequent conductive layers may be deposited via electroless and/or electrochemical deposition. Hence, formation of a reducing layer, a catalytic layer and a seed layer may all be performed in a single chamber.

FIGS. 18A and 18B illustrate a schematic cross-sectional view of fluid deposition chamber 1800, which is one embodiment of a combined vapor/liquid deposition chamber that may be useful to deposit conductive layers using vapor deposition and electroless or electroplating processes as described previously. The fluid deposition chamber 1800 processes substrates in a processing region 155 that is formed by the temperature-controlled substrate support 1812, the substrate “W”, a seal 154 and the lower wall 148 of moveable processing shield 150.

In one embodiment, a process gas source 161 containing a gas reservoir 160 and valve 159 and/or a liquid source 127 containing liquid reservoirs 128a-128f and valve 129b are adapted to deliver one or more processing fluids to the injection port 144, into the processing region 155, across the substrate surface, through the holes 152 and into the evacuation region 153 where the process gas is directed to the waste collection system 151. In one example, a plating solution may be collected and recirculated across the surface of the substrate by use of a collection tank system 1849, which is adapted to recirculate collected plating solution. The fluid deposition chamber 1800 further includes a drain 1827 in order to collect and expel fluids used in the fluid deposition chamber 1800. The bottom 1807 of the processing compartment 1806 may comprise a sloped surface to aid the flow of fluids used in the fluid deposition chamber 1800 towards an annular channel in communication with the drain 1827 and to protect the substrate support assembly 1813 from contact with fluids.

In one embodiment, forming a reducing layer and a catalytic layer are performed sequentially in fluid deposition chamber 1800, described herein. A substrate is transferred into fluid deposition chamber 1800 and placed on the substrate receiving surface 1814 by use of a robot (not shown) and the lift pins 1818. Next the moveable processing shield 150 is then moved into position where it contacts the substrate receiving surface 1814, or the substrate surface, to form the processing region 155. The pressure in the evacuation region 153, and processing region 155, is then lowered by use of the pump (not shown) in waste collection system 151. A processing fluid is then delivered to the processing region 155 from a process gas source 161 that is connected to the injection port 144. In one example, the processing gas contains ruthenium tetroxide to form a ruthenium-containing layer on the surface of the substrate. This corresponds to reducing layer 126 in FIG. 1H.

After forming reducing layer 126, the processing region 155 may then be purged with a carrier gas (e.g., argon, nitrogen, etc.) to remove any of the remnants of the processing gas. Next an electroless or electroplating solution may be delivered to the processing region 155 from the liquid source 127 so that a catalytic layer 128 can be formed from reducing layer 126 on the substrate surface.

Referring to FIGS. 18C and 18D, in one embodiment of the fluid deposition chamber 1800, one or more electrical contacts (not shown) are embedded in the seal 154 of the moveable processing shield 150 and an anode 163 is placed in contact with the processing fluid (see item “A”) so that a plating current can be delivered to the reducing layer so that the catalytic layer can be deposited using an electroplating process. The metal ions in the processing fluid will be plated on the reducing layer by applying a negative bias to the reducing layer surface relative to the anode 163 by use of a power supply (not shown). Further, a bulk conductive layer, corresponding to metal bulk layer 130 in FIG. 1K, may subsequently be deposited.

A more detailed description of a combined liquid/vapor deposition chamber may be found in the commonly assigned U.S. patent application Ser. No. 10/059,572, entitled “Electroless Deposition Apparatus” by Stevens et al., filed Jan. 28, 2002, and previously referenced U.S. Patent Application Ser. No. 60/648,004 [9906L], entitled “Deposition of an Intermediate Catalytic Layer on a Barrier Layer For Copper Metallization,” which are incorporated by reference herein in their entirety to the extent not inconsistent with the claimed aspects and description herein.

f) Plasma-Assisted Dry Etch Chamber for Contact Clean

i) General Description of Chamber

To remove native oxide and other contaminants formed on exposed contact surfaces prior to the electroless deposition process and to improve adhesion of subsequent metal layers, embodiments of the invention include a treatment of substrates prior to wet processing in wet processing platform 213, namely a plasma-assisted dry etch treatment as described below and in conjunction with FIG. 19. The substrate dry clean treatment is performed in a chamber adapted to perform a chemical etch clean and in-situ anneal on substrates and is preferably located on the dry side of cluster tool 200 (as shown in FIG. 2), such as processing station 235.

The dry etch chamber may perform a plasma-enhanced chemical etch process with both substrate heating and cooling all within a single processing environment, including an anneal or heat treating process. FIG. 19 illustrates a partial cross sectional view of a processing chamber 1900. The dry etch chamber is a vacuum chamber containing a lid assembly 200a, a substrate support member 310a which is temperature-controlled, a chamber body 112a which is temperature-controlled, and a processing zone 140a. The processing zone 140a is the region between the lid assembly 200a and the substrate support member 310a. The substrate support member 310a is generally adapted to support and control the temperature of the substrate during processing. The lid assembly 200a contains a process gas supply panel (not shown) as well as a first and second electrode (elements 240a and 220a) that define a plasma cavity for generating plasma external to the processing zone 140a. The process gas supply panel (not shown) provides reactive gas to the plasma cavity, through the second electrode 220a and into the processing zone 140a. The second electrode 220a is positioned over the substrate and adapted to heat the substrate after the plasma-assisted dry etch process is complete.

ii) Plasma-Assisted Dry Etch Process

An exemplary dry etch process for removing native oxides on a surface of the substrate using an ammonia (NH₃) and nitrogen trifluoride (NF₃) gas mixture performed within a dry etch processing chamber will now be described.

The dry etch process begins by placing a substrate, such as a semiconductor substrate, into a dry etch processing chamber. Preferably, the substrate is held to the support assembly 300a of the substrate support member 310a during processing via a vacuum or electrostatic chuck. The chamber body 112a is preferably maintained at a temperature of between 50° C. and 80° C., more preferably at about 65° C. This temperature of the chamber body 112a is maintained by passing a heat transfer medium through fluid channels 113a located in the chamber body. During processing, the substrate is cooled below 65° C., such as between 15° C. and 50° C., by passing a heat transfer medium or coolant through fluid channels 113a formed within the substrate support. In another embodiment, the substrate is maintained at a temperature of between 22° C. and 40° C. Typically, the substrate support is maintained below about 22° C. to reach the desired substrate temperatures specified above.

The ammonia and nitrogen trifluoride gases are then introduced into the dry etching chamber to form a cleaning gas mixture. The amount of each gas introduced into the chamber is variable and may be adjusted to accommodate, for example, the thickness of the oxide layer to be removed, the geometry of the substrate being cleaned, the volume capacity of the plasma and the volume capacity of the chamber body 112a. In one aspect, the gases are added to provide a gas mixture having at least a 1:1 molar ratio of ammonia to nitrogen trifluoride. In another aspect, the molar ratio of the gas mixture is at least about 3 to 1 (ammonia to nitrogen trifluoride). Preferably, the gases are introduced in the dry etching chamber at a molar ratio of from 5:1 (ammonia to nitrogen trifluoride) to 30:1. More preferably, the molar ratio of the gas mixture is of from about 5 to 1 (ammonia to nitrogen trifluoride) to about 10 to 1. The molar ratio of the gas mixture may also fall between about 10:1 (ammonia to nitrogen trifluoride) and about 20:1.

A purge gas or carrier gas may also be added to the gas mixture. Any suitable purge/carrier gas may be used, such as argon, helium, hydrogen, nitrogen, or mixtures thereof, for example. Typically, the overall gas mixture is from about 0.05% to about 20% by volume of ammonia and nitrogen trifluoride. The remainder being the carrier gas. In one embodiment, the purge or carrier gas is first introduced into the chamber body 112a before the reactive gases to stabilize the pressure within the chamber body.

The operating pressure within the chamber body can be variable. Typically, the pressure is maintained between about 500 mTorr and about 30 Torr. Preferably, the pressure is maintained between about 1 Torr and about 10 Torr. More preferably, the operating pressure within the chamber body is maintained between about 3 Torr and about 6 Torr.

An RF power of from about 5 and about 600 Watts is applied to the first electrode to ignite a plasma of the gas mixture within the plasma cavity. Preferably, the RF power is less than 100 Watts. More preferable is that the frequency at which the power is applied is very low, such as less than 100 kHz. Preferably, the frequency ranges from about 50 kHz to about 90 kHz.

The plasma energy dissociates the ammonia and nitrogen trifluoride gases into reactive species that combine to form a highly reactive ammonia fluoride (NH₄F) compound and/or ammonium hydrogen fluoride (NH₄F.HF) in the gas phase. These molecules then flow through the second electrode 220a to react with the substrate surface to be cleaned. In one embodiment, the carrier gas is first introduced into the dry etch chamber, a plasma of the carrier gas is generated, and then the reactive gases, ammonia and nitrogen trifluoride, are added to the plasma.

Not wishing to be bound by theory, it is believed that the etchant gas, NH₄F and/or NH₄F.HF, reacts with the native oxide surface to form ammonium hexafluorosilicate (NH₄)₂SiF₆, NH₃, and H₂O products. The NH₃, and H₂O are vapors at processing conditions and removed from the chamber by a vacuum pump attached to the chamber. A thin film of (NH₄)₂SiF₆ is left behind on the substrate surface.

After performing the plasma processing step a thin film of (NH₄)₂SiF₆ is formed on the substrate surface, the substrate support is elevated to an anneal position in close proximity to the heated second electrode. The heat radiated from the second electrode 220a should be sufficient to dissociate or sublimate the thin film of (NH₄)₂SiF₆ into volatile SiF₄, NH₃, and HF products. These volatile products are then removed from the chamber by the vacuum pump 125a attached to the system. Typically, a temperature of 75° C. or more is used to effectively sublimate and remove the thin film from the substrate. Preferably, a temperature of 100° C. or more is used, such as between about 115° C. and about 200° C.

The thermal energy to dissociate the thin film of (NH₄)₂SiF₆ into its volatile components is convected or radiated by the second electrode. A heating element 270a is directly coupled to the second electrode 220a, and is activated to heat the second electrode and the components in thermal contact therewith to a temperature between about 75° C. and 250° C. In one aspect, the second electrode is heated to a temperature of between 100° C. and 150° C., such as about 120° C.

The distance between the upper surface of the substrate having the thin film thereon and the second electrode 220a is not critical and is a matter of routine experimentation. A person of ordinary skill in the art can easily determine the spacing required to efficiently and effectively vaporize the thin film without damaging the underlying substrate. It is believed, however, that a spacing of between about 0.254 mm (10 mils) and 5.08 mm (200 mils) is effective.

Once the film has been removed from the substrate, the chamber is purged and evacuated. The cleaned substrate is then removed from the chamber by lowering the substrate to the transfer position, de-chucking the substrate, and transferring the substrate through a slit valve opening.

iii) Exemplary Plasma-Assisted Dry Etch Chamber

FIG. 19 is a partial cross sectional view showing an illustrative processing chamber 1900. In one embodiment, the processing chamber 1900 includes a chamber body 112a, a lid assembly 200a, and a support assembly 300a. The lid assembly 200a is disposed at an upper end of the chamber body 112a, and the support assembly 300a is at least partially disposed within the chamber body 112a. The processing chamber 1900 and the associated hardware are preferably formed from one or more process-compatible materials, such as aluminum, anodized aluminum, nickel plated aluminum, nickel plated aluminum 6061-T6, stainless steel, as well as combinations and alloys thereof.

The chamber body 112a includes a slit valve opening 160a formed in a sidewall thereof to provide access to the interior of the processing chamber 1900. The slit valve opening 160a is selectively opened and closed to allow access to the interior of the chamber body 112a by a substrate handling robot (not shown).

In one or more embodiments, the chamber body 112a includes a fluid channel 113a formed therein for flowing a heat transfer fluid therethrough. The heat transfer fluid can be a heating fluid or a coolant and is used to control the temperature of the chamber body 112a during processing and substrate transfer. The temperature of the chamber body 112a is important to prevent unwanted condensation of the gas or byproducts on the chamber walls. Exemplary heat transfer fluids include water, ethylene glycol, or a mixture thereof. An exemplary heat transfer fluid may also include nitrogen gas.

The chamber body 112a can further include a liner 133a that surrounds the support assembly 300a. The liner 133a is preferably removable for servicing and cleaning. The liner 133a can be made of a metal such as aluminum, or a ceramic material. However, the liner 133a can be any process compatible material. The liner 133a can be bead blasted to increase the adhesion of any material deposited thereon, thereby preventing flaking of material which results in contamination of the processing chamber 1900. In one or more embodiments, the liner 133a includes one or more apertures 135a and a pumping channel 129a formed therein that are in fluid communication with a vacuum system. The apertures 135a provide a flow path for gases into the pumping channel 129a, which provides an egress for the gases within the processing chamber 1900.

The vacuum system may include a vacuum pump 125a and a throttle valve 127a to regulate flow of gases through the processing chamber 1900. The vacuum pump 125a is coupled to a vacuum port 131a disposed on the chamber body 112a and therefore, in fluid communication with the pumping channel 129a formed within the liner 133a. The apertures 135a allow the pumping channel 129a to be in fluid communication with a processing zone 140a within the chamber body 112a. The processing zone 140a is defined by a lower surface of the lid assembly 200a and an upper surface of the support assembly 300a, and is surrounded by the liner 133a. The apertures 135a may be uniformly sized and evenly spaced about the liner 133a.

In operation, one or more gases exiting the processing chamber 1900 flow through the apertures 135a formed through liner 133a into the pumping channel 129a. The gas then flows within the pumping channel 129a and through the vacuum port 131a into the vacuum pump 125a.

Referring to FIG. 19, the lid assembly 200a includes a number of components stacked on top of one another. In one or more embodiments, the lid assembly 200a includes a lid rim 210a, gas delivery assembly which acts as the second electrode 220a, and a top plate 250a. The second electrode 220a is coupled to an upper surface of the lid rim 210a and is arranged to make minimum thermal contact therewith. The components of the lid assembly 200a are preferably constructed of a material having a high thermal conductivity and low thermal resistance, such as an aluminum alloy with a highly finished surface. Preferably, the thermal resistance of the components is less than about 5×10⁻⁴ m² K/W.

The second electrode 220a may include a distribution plate or showerhead (not shown). Typically, the distribution plate is substantially disc-shaped and includes a plurality of apertures or passageways thereby providing an even distribution of the gas across the surface of the substrate as the flow of gas exits lid assembly 200a. The second electrode 220a may further include a blocker assembly (not shown) disposed adjacent the distribution plate. The blocker assembly provides an even distribution of gas to the backside of the distribution plate.

A gas supply panel (not shown) is typically used to provide the one or more gases to the processing chamber 1900. The particular gas or gases that are used depend upon the process or processes to be performed within the processing chamber 1900. Illustrative gases can include, but are not limited to one or more precursors, reductants, catalysts, carriers, purge, cleaning, or any mixture or combination thereof. Typically, the one or more gases introduced to the processing chamber 1900 flow into the lid assembly 200a and then into the chamber body 112a through the second electrode 220a. Depending on the process, any number of gases can be delivered to the processing chamber 1900, and can be mixed either in the processing chamber 1900 or before the gases are delivered to the processing chamber 1900.

In use, one or more process gases are introduced into the second electrode 220a from the gas supply panel (not shown), flow around and through the blocker assembly (not shown), then enter the processing zone 140a of processing chamber 1900 and meet the exposed surface of the substrate disposed on the support assembly 300a.

Still referring to FIG. 19, the lid assembly 200a can further include a first electrode 240a to generate a plasma of reactive species within the lid assembly 200a. In one embodiment, the first electrode 240a is supported on the top plate 250a and is electrically isolated therefrom. In one or more embodiments, the first electrode 240a is coupled to a power source 241a while the second electrode 220a is connected to ground (i.e. the second electrode 220a serves as an electrode). Accordingly, a plasma of one or more process gases can be generated in the volumes between the first electrode 240a and the second electrode 220a (the gas delivery assembly in this example). The plasma is well confined or contained within the lid assembly 200a. Accordingly, the plasma is a “remote plasma” since no active plasma is in direct contact with the substrate disposed within the chamber body 112a. As a result, plasma damage to the substrate is avoided because the plasma is sufficiently separated from the substrate surface.

Any power source capable of activating the gases into reactive species and maintaining the plasma of reactive species may be used for power source 241a. For example, radio frequency (RF), direct current (DC), or microwave (MW) based power discharge techniques may be used. Alternatively, a remote activation source may be used, such as a remote plasma generator, to generate a plasma of reactive species which are then delivered into processing chamber 1900.

Second electrode 220a may be heated depending on the process gases and operations to be performed within the processing chamber 1900. In one embodiment, a heating element 270a, such as a resistive heater for example, can be coupled to the second electrode 220a or the distribution plate. Regulation of the temperature may be facilitated by a thermocouple coupled to the second electrode 220a or the distribution plate.

The support assembly 300a may be at least partially disposed within the chamber body 112a. The support assembly 300a can include a substrate support member 310a to support a substrate (not shown in this view) for processing within the chamber body 112a. The substrate support member 310a can be coupled to a lift mechanism (not shown) which extends through a bottom surface of the chamber body 112a. The lift mechanism (not shown) can be flexibly sealed to the chamber body 112a by a bellows (not shown) that prevents vacuum leakage from around the lift mechanism. The lift mechanism allows the substrate support member 310a to be moved vertically within the chamber body 112a between a process position and a lower, transfer position. The transfer position is slightly below slit valve opening 160a formed in a sidewall of the chamber body 112a. In one or more embodiments, the substrate support member 310a has a flat, circular surface or a substantially flat, circular surface for supporting a substrate to be processed thereon. The substrate support member 310a is preferably constructed of aluminum. The substrate support member 310a can be moved vertically within the chamber body 112a so that a distance between substrate support member 310a and the lid assembly 200a can be controlled.

In one or more embodiments, the substrate (not shown) may be secured to the substrate support member 310a using an electrostatic or vacuum chuck. In one or more embodiments, the substrate may be held in place on the substrate support member 310a by a mechanical clamp (not shown), such as a conventional clamp ring. Preferably, the substrate is secured using an electrostatic chuck

Substrate support member 310a may include one or more bores (not shown) formed therethrough to accommodate a lift pin (not shown). Each lift pin is typically constructed of ceramic or ceramic-containing materials, and are used for substrate-handling and transport.

The temperature of the support assembly 300a is controlled by a fluid circulated through one or more fluid channels 360a embedded in the body of the substrate support member 310a. Preferably, the fluid channel 360a is positioned about the substrate support member 310a to provide a uniform heat transfer to the substrate receiving surface of the support member 310a. The fluid channel 360a and can flow heat transfer fluids to either heat or cool the substrate support member 310a. Any suitable heat transfer fluid may be used, such as water, nitrogen, ethylene glycol, or mixtures thereof. The support assembly 300a can further include an embedded thermocouple (not shown) for monitoring the temperature of the support surface of the substrate support member 310a.

In operation, the substrate support member 310a can be elevated to close proximity of the lid assembly 200a to control the temperature of the substrate being processed. As such, the substrate can be heated via radiation emitted from the lid assembly 200a or the distribution plate, which are heated by heating element 270a. Alternatively, the substrate can be lifted off the substrate support member 310a to close proximity of the heated lid assembly 200a using the lift pins.

A more detailed description of a plasma-assisted dry etch chamber and process that may be contained in some configurations of the invention may be found in commonly assigned U.S. Patent Application Ser. No. 60/547,839 entitled “In-Situ Dry Clean Chamber For Front End Of Line Fabrication,” filed on Feb. 22, 2005, which is hereby incorporated by reference in its entirety to the extent not inconsistent with the claimed invention.

g) Supercritical Clean Chamber

In some aspects of the invention, immediately prior to deposition process steps, native oxides and other contaminants are removed from substrate surfaces in a dry side chamber via a supercritical clean process. Various gases, such as carbon dioxide, in their supercritical fluid state have been shown to replace organic solvents in cleaning applications. For substances that exhibit supercritical fluid properties, when the substance is above its critical point, i.e., above the critical temperature and critical pressure, the phase boundary between the gas phase and liquid phase disappears, and the substance exists in a single supercritical fluid phase. In the supercritical fluid phase, a substance assumes some of the properties of a gas and some of the properties of a liquid. For example, supercritical fluids have diffusivity properties similar to gases but solvating properties similar to liquids. Therefore, supercritical fluids have good cleaning properties and may be used to clean substrate structures that have geometries difficult to clean with standard wet-clean methods, such as high aspect ratio contacts.

The term “supercritical fluid” as used herein refers to a substance above its critical point. The term “dense fluid” as used herein refers to a substance at or below its critical point. Dense fluid preferably comprises a substance at or near its critical point. In certain embodiments, a dense fluid comprises a substance that is at a state in which its density is at least ⅕ the density of the substance at its critical point.

In one aspect, a substrate may be processed by applying a supercritical fluid thereto. In another aspect, a substrate may be processed by applying a dense fluid thereto without the substance reaching a supercritical state. In still another apsect, a substrate may be processed by applying a substance thereto in which the substance is phase modulated between a supercritical fluid state and a dense fluid state. A dense fluid may have a high solvating and diffusivities properties similar to a supercritical fluid.

One method of cleaning substrate structures consists of applying a supercritical fluid thereto, such as a carbon dioxide fluid at a pressure greater than about 1,000 psi and at a temperature of at least about 31° C. The carbon dioxide fluid may further include a co-solvent, such as methanol, surfactants, chelating agents, and combinations thereof. Cleaning of the substrate structure via this method may be accomplished without the need for a wet clean.

FIG. 20 is a schematic cross-sectional view of an exemplary chamber, supercritical clean chamber 2100, that may be used in embodiments of the invention. Supercritical clean chamber 2100 is adapted to apply a supercritical fluid and/or a dense fluid to a substrate. Supercritical clean chamber 2100 contains a sealed process enclosure 2108, a substrate support 2114 disposed in the sealed process enclosure 2108 and optionally one or more sonic transducers 2115 attached to the substrate support 2114. The sonic transducers 2115 create acoustic or sonic waves directed towards the surface of a substrate to help agitate the fluid during processing. Heating elements 2132 are disposed proximate or inside the walls of supercritical clean chamber 2100 to heat the fluid to the desired temperature during processing. The supercritical and/or dense fluid is transferred to the sealed process enclosure 2108 through a fluid line 2123 by a pump/compressor 2126 at a desired pressure, typically between about 1,000 psi and 5,000 psi and temperature, typically at least about 31° C., and is applied to the substrate via a showerhead or diffuser plate (not shown) located in the sealed process enclosure 2108. Optimum exposure time of the substrate to the supercritical fluid varies depending on the geometry of the substrate structure, such as aspect ratio, and type of contamination to be removed therefrom. Optionally, heating elements 2143 may heat the carbon dioxide fluid to a desired temperature as the fluid is being transferred though the fluid line 2123.

A detailed description of an exemplary supercritical clean chamber that may be used in embodiments of the invention may be found in commonly assigned U.S. patent application Ser. No. 11/038,456 entitled “Using Supercritical and/or Dense Fluids in Semiconductor Applications,” filed on Jan. 18, 2005, which is hereby incorporated by reference in its entirety.

B. Electroless Deposition System with SRD and In Situ IBC

1. Applications of Cluster Tool Configuration

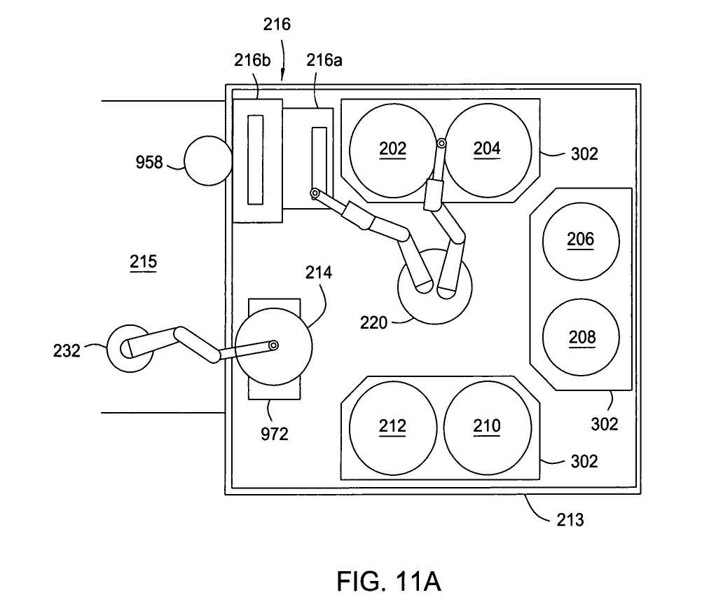

FIG. 11 illustrates one embodiment of a cluster tool 200 that generally includes electroless plating chambers and spin-rinse drying chambers. Optionally, it may include ALD barrier layer, reducing layer, and/or catalytic layer deposition prior to wet processing. Optionally, it may also include a plasma-enhanced dry etch chamber or supercritical clean chamber for removal of native oxide prior to barrier or catalytic layer deposition. This configuration of cluster tool 200 may be used to process substrate structures with ALD or CVD tantalum nitride (TaN), an electroless copper electroless seed layer deposition and/or seed layer repair, fill interconnect features with electroless gap fill deposition, deposit both seed layer and gap fill sequentially, or deposit a capping layer, such as cobalt, on extant interconnect features. In instances when this embodiment is used either for interconnect gap fill or for forming a seed layer that will be followed by electroless gap fill, the cluster tool may also be configured with IBC capability incorporated into the electroless plating twin cells, allowing the necessary post-deposition cleaning of substrates prior to removal from the wet processing platform.

2. Description of Cluster Tool Configuration

FIG. 11 illustrates cluster tool 200, which generally includes electroless plating and spin-rinse drying. In this embodiment, processing stations 214 and 216 may be configured as an interface between the wet processing platform 213 and the generally dry processing stations or factory interface 230 of the plating cluster tool 200. As such, substrates are introduced into wet processing platform 213 by being placed in an in-station 972 while waiting for wet processing. The in-station 972 is typically located above or below processing stations 214 and 216 (not shown in FIG. 11 for clarity, see FIG. 11A). In addition to the in-stations, processing stations 214 and 216 each include an SRD chamber which performs the final wet processing steps on a substrate before the substrate leaves wet processing platform 213. Alternatively, processing stations 214 and 216 may instead consist of a combination IBC/SRD chamber, wherein the bevel clean process is performed on a substrate followed immediately by the final rinse and dry process. In this embodiment, processing stations 202 and 204 may comprise an electroless plating twin cell, processing stations 206 and 208 a second electroless plating twin cell, and processing stations 210 and 212 a third electroless plating twin cell. Each electroless twin cell is contained by a processing enclosure 302. Each twin cell also includes a substrate transfer shuttle (not shown in FIG. 11 for clarity, see FIG. 6) for substrate transfers between the first and second processing stations inside each processing enclosure 302. Alternately, each electroless plating twin cell may also include the functionality of an IBC chamber, i.e. the post-deposition cleaning of unwanted material and contamination from the bevel portion and backside of a substrate.

Processing stations 235 and 235a, which are located on the dry side of the cluster tool, may be configured as an ALD or CVD chamber for the deposition of a barrier layer and/or catalytic layer prior to wet processing. In some embodiments, the catalytic layer so formed is a ruthenium-containing layer deposited without the use of carbon-containing precursors. In another embodiment, a dry etch chamber or supercritical clean chamber is positioned at processing station 235 or 235a.

3. Process Sequences

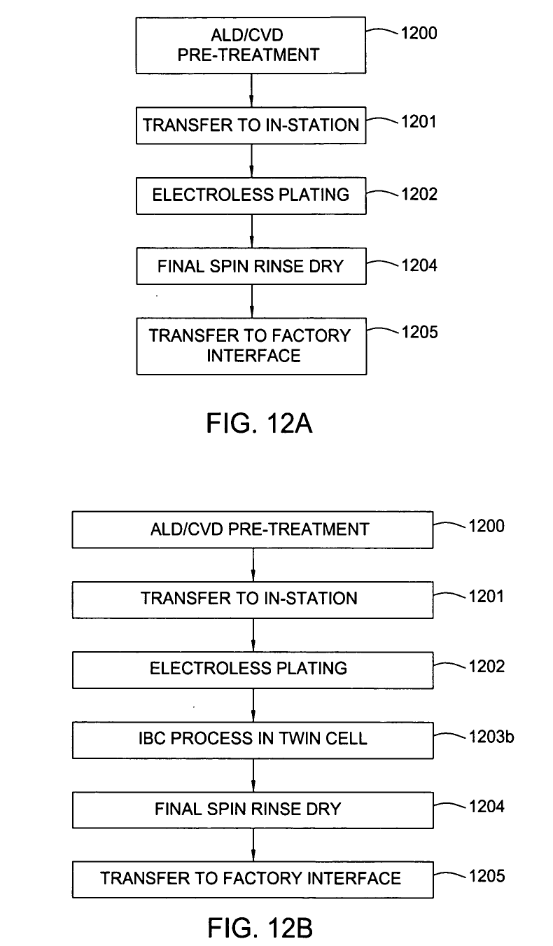

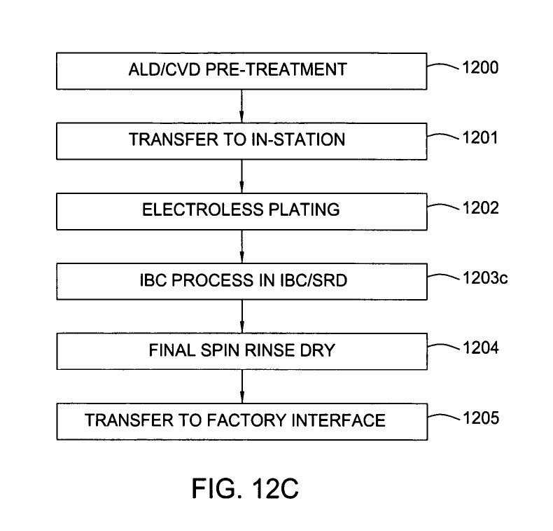

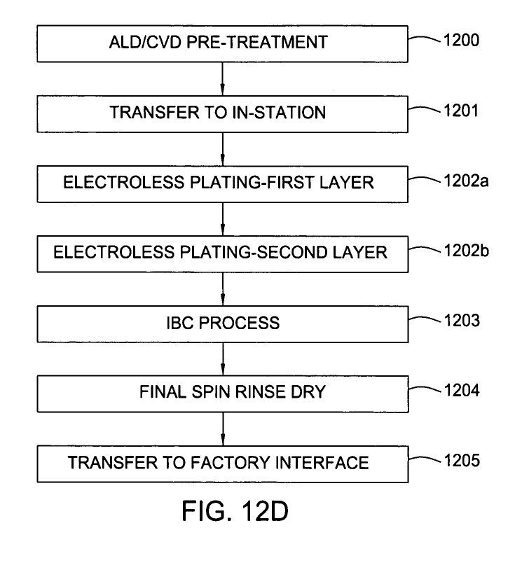

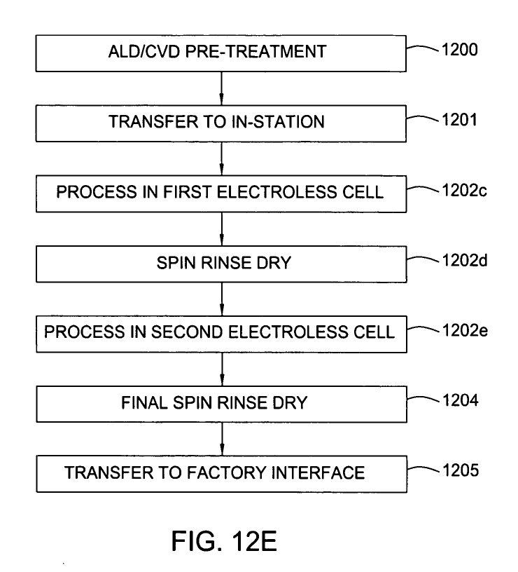

Typical substrate processing sequences for this embodiment of the invention are detailed in the flow charts illustrated in FIGS. 12A, 12B, 12C, 12D, and 12E.

a) Single Layer Metal Deposition

When the cluster tool 200 is used for depositing a single layer of metal on substrates, i.e., either a seed layer, gap fill, or an interconnect capping layer, then it may be advantageous to have all of the electroless deposition processes performed on a substrate take place in a single electroless plating twin cell. In one aspect, the second and third electroless twin cells may also operate in parallel with the first twin cell and perform the same deposition process on other substrates going through a desired process sequence. The substrate processing sequences for this scenario are shown in FIGS. 12A, 12B, and 12C.

In Step 1200, a substrate is pre-treated with a barrier layer, a reducing layer, and/or a catalytic layer in chamber positioned at processing station 235 prior to wet processing. In one aspect, the chamber positioned at processing station 235 may use the ruthenium tetroxide-based process described above to deposit the catalytic layer. In another aspect, native oxide is removed from the substrate prior to pre-treatment with a barrier, reducing and/or catalytic layer in a dry etch chamber or supercritical clean chamber positioned in factory interface 230.

In step 1201, factory interface robot 232 places a substrate at the in-station 972 associated with processing stations 214 or 216.

In step 1202, mainframe robot 220 transfers the substrate to the first processing station of one of the electroless twin plating cells, i.e., processing station 202, 206, or 210. Hence, a substrate may undergo the deposition step 1202 in any one of the electroless twin cells and then continue on to step 1203. In this configuration, a substrate is not processed in more than one twin cell. As part of the process of electroless deposition, the substrate may be transferred as necessary between processing stations internally within an electroless twin cell via internal substrate transfer shuttle 605, i.e., between processing stations 202 and 204, 206 and 208, or 210 and 212. As described above, electroless deposition process steps may be divided between the two processing stations in an electroless twin chamber or all deposition process steps may be performed in each electroless processing station.

If the substrate is treated in step 1202 with interconnect gap fill, then the IBC process also is necessary. In one aspect, a dedicated IBC chamber may perform the IBC process on substrates. In another aspect, either the electroless plating cells or the SRD chambers may include the functionality of an IBC chamber, as described above in conjunction with FIGS. 3 and 4. The IBC process removes unwanted deposition from the substrate bevel and residual contamination from the substrate backside. Either the IBC process is performed on substrates in an electroless plating cell immediately after the electroless deposition of step 1202, or the IBC process is performed after the substrate is transferred to an external IBC chamber, i.e., with a dedicated IBC or a combined IBC/SRD chamber. Hence there are three possible processing sequences for this embodiment of the invention, depending on what IBC process is required. These sequences are illustrated in FIGS. 12A, 12B, and 12C. Process steps 1200, 1201, and 1202 are identical for all three of these sequences.

FIG. 12A illustrates a substrate processing sequence I which no IBC process is performed, for example the invention is used for deposition of an electroless capping layer, such as capping layer 105, depicted in FIG. 1B. After completing process steps 1200-1202, process step 1204 is performed. In step 1204, mainframe robot 220 transfers the substrate to SRD chamber positioned at processing station 214 or 216, wherein the final rinsing and drying of the substrate take place. In step 1205, after the SRD process is complete, factory interface robot 232 removes the substrate from the SRD and wet processing platform 213. This embodiment of the invention allows the high throughput deposition sequence either used to form an interconnect capping layer or an electroless seed layer on substrates by applying multiple electroless twin cells in parallel.

FIG. 12B illustrates the substrate processing sequence when the IBC process is desired and some or all of the electroless plating cells are configured to perform the IBC process described in conjunction with FIGS. 7 and 8. In step 1203b, after completing process steps 1200-1202, the substrate undergoes the IBC process prior to being transferred out of the twin cell. In step 1204, mainframe robot 220 transfers the substrate to SRD chamber positioned at processing stations 214 or 216, wherein the final rinsing and drying of the substrate take place. In step 1205, after the SRD process is complete, factory interface robot 232 removes the substrate from the SRD and wet processing platform 213. By using up to 3 electroless twin plating cells in parallel, this embodiment of the invention allows high throughput electroless gap fill of interconnect features on substrates and in situ substrate bevel clean prior to removal from the wet processing platform.

FIG. 12C illustrates the substrate processing sequence when the IBC process is desired and wet processing platform 213 is configured with combined IBC/SRD chambers. In step 1203c, after completing process steps 1200-1202, mainframe robot 220 transfers the substrate to IBC/SRD chamber positioned at processing station 214 or 216, wherein the IBC process is performed on the substrate. In step 1204, the substrate undergoes the final SRD process in the IBC/SRD chamber. In step 1205, after the SRD process is complete, factory interface robot 232 removes the substrate from the IBC/SRD and wet processing platform 213. By using up to 3 electroless twin plating cells in parallel, this this embodiment of the invention allows high throughput electroless gap fill of interconnect features on substrates and in situ substrate bevel clean prior to removal from the wet processing platform.

b) Multiple Layer Metal Deposition

In one embodiment of the cluster tool 200, it may be beneficial to have each substrate processed in two or more electroless plating cells. In this configuration, one or two of the electroless twin cells may be dedicated to seed layer deposition and/or repair and the remaining electroless twin cell or cells is/are dedicated to gap fill deposition. As an example, twin cells positioned at processing stations 202/204 and 206/208 may be configured for seed layer deposition and twin cell positioned at processing stations 210/212 may be configured for gap fill deposition (see FIG. 11). These configurations for the pairs of processing stations 202/204, 206/208, and 210/212 may be rearranged without affecting the functionality of the invention and are defined above only for purposes of description.

The processing sequence for this application of the invention is illustrated in FIG. 12D. Steps 1200, 1201, 1204, and 1205 are identical to the steps described above in FIGS. 12A, 12B, and 12C. In this processing sequence, however, the electroless deposition takes places in two steps, 1202a and 1202b. In step 1202a, the substrate is transferred from one of the in-stations to processing station 202 or 206 for seed layer deposition. In step 1202b, after seed layer deposition is completed in twin cell positioned in processing stations 202/204 or 206/208, the substrate is transferred to processing station 210/212 for gap fill deposition. In one aspect, each processing station in each electroless twin cell may then act as an independent electroless plating cell. In this case, in step 1202a seed layer deposition may take place in any one of four processing stations: 202, 204, 206, or 208 and in step 1202b, the electroless gap fill deposition may take place in either processing station 210 or 212. Further, if the substrate has been pre-treated with a catalytic layer in processing station 235 prior to wet processing, processing stations 202, 204, 206, or 208 may act as independent electroless plating cells.

Because the electroless gap fill process of step 1202b typically results in unwanted deposition on the substrate bevel, an IBC process (step 1203) may be performed on substrates prior to their removal from wet processing platform 213.

In the processing sequence shown in FIG. 12D, step 1203 may be performed as described above in either step 1203b or 1203c, depending on the configuration of wet processing platform 213. Either the electroless twin cells or the SRD chambers will need to have the capability of performing an IBC process incorporated into them.

In steps 1204 and 1205, the substrate is given a final rinse, dried, and transferred out of wet processing platform 213. This embodiment of the invention allows sequential deposition of an electroless seed layer on a substrate and electroless gap fill of the interconnect features on the substrate, followed by in situ bevel clean of the substrate prior to removal from the wet processing platform. In one aspect, a barrier layer may be deposited on the substrate immediately prior to wet processing, improving adhesion of the subsequent metal layers. The process of sequential deposition minimizes both the amount and variation of oxidation of the seed layer prior to gap fill over the prior art. Additionally, only a single processing platform is required to complete three deposition steps on a substrate structure, reducing system cost and fabrication facility cost.

c) Electroless Deposition with Intermediate Rinse

A third substrate processing sequence for this embodiment of the invention includes performing an intermediary spin-rinse-dry process on substrates after processing in the first processing station of an electroless twin cell and before processing in the second processing station. This processing sequence may be beneficial for electroless plating chemistries for which a completely clean and dry wafer is preferred for the second electroless plating process. This substrate processing sequence is illustrated in FIG. 12E. Steps 1200, 1201, 1203, and 1204 are identical to the steps described in FIGS. 12A, 12B, and 12C.

As shown in FIG. 12E, step 1202c follows step 1201 (i.e., the substrate is transferred into wet processing platform 213). In step 1202c, the substrate is transferred to the first processing station of an electroless twin cell, e.g. processing station 202, 206, or 210, and and an electroless process is performed therein. The process performed on the substrate may be a complete electroless deposition process or some combination of the initial steps thereof, e.g. preparatory clean, activation, and post-activation clean for selective deposition, or catalytic layer deposition for non-selective deposition.

In step 1202d, the substrate is transferred to an SRD chamber, such as SRD 400, wherein the substrate is rinsed and/or dried via the SRD process described in conjunction with FIG. 4.

In step 1202e, the substrate is transferred to the second processing station of the electroless twin cell, e.g., processing station 204, 208, or 212, and is processed therein. The process performed on the substrate may be the completion of the electroless deposition process already begun on the substrate, or, if a first metal layer was deposited in step 1202c, a second metal layer may be deposited via electroless plating. Alternately, in embodiments in which the IBC process is required and the electroless plating twin cells include the functionality of an IBC chamber, the final deposition step, i.e. 1202e, may also include performing the IBC process on the substrate via the IBC process described in conjunction with FIG. 3.

In steps 1204 and 1205, the substrate is given a final rinse, dried, and transferred out of wet processing platform 213. For embodiments of the invention in which processing stations 214 and 216 are combination IBC/SRD chambers, the step 1204 may include both the IBC and SRD processes.

4. Description of Process Chambers

Embodiments of the invention include the incorporation of multiple substrate processing chambers onto a single cluster tool, including electroless, SRD and ALD or CVD chambers. Examples of these chambers and the processes performed on substrates therein have been described previously.

C. Electroless Deposition System with Brush Box and SRD

1. Applications of Cluster Tool Configuration

In one embodiment, illustrated in FIGS. 11 and 11A by the cluster tool 200 includes an electroless plating chamber, a brush box substrate clean chamber and a spin-rinse drying chamber. This configuration allows deposition of capping layers on high density interconnect features with low defects, because it remove loose metallic particles formed on the substrate surface during electroless deposition. Other applications include deposition of an electroless seed layer deposition of electroless gap fill.

2. General Description of Cluster Tool Configuration

In one embodiment, processing station 214 acts as the interface between the wet processing platform 213 and the generally dry processing stations or factory interface 230 of the plating cluster tool 200. As such, the SRD chamber for wet processing platform 213 and an in-station 972 are located at processing station 214, as shown in FIG. 11A. The in-station 972 may be located either above or below the SRD chamber. In one aspect, processing station 216 is configured as a brush box 216a for post-deposition cleaning of substrates (see FIG. 11A). Brush box 216a may be configured to accept wafers that are oriented either horizontally or vertically. In this embodiment, processing stations 202 and 204 comprise an electroless plating twin cell, processing stations 206 and 208 comprise a second electroless plating twin cell, and processing stations 210 and 212 comprise a third electroless plating twin cell. These configurations for the pairs of processing stations 202/204, 206/208, and 210/212 may be rearranged without affecting the functionality of the invention and are defined above only for purposes of description. Each electroless twin cell is contained by a processing enclosure 302. Each twin cell also includes a substrate transfer shuttle (not shown for clarity) for substrate transfers between the first and second processing stations inside each processing enclosure 302. Alternately, each electroless plating twin cell may also includes the functionality of an IBC chamber, i.e. the post-deposition cleaning of unwanted material and contamination from the bevel portion and backside of a substrate. This configuration of wet processing platform 213 may be used to deposit an electroless capping layer on interconnect features, process substrate structures with electroless seed layer deposition, fill interconnect features with electroless gap fill deposition, or to deposit both seed layer and gap fill on a substrate sequentially.

For non-selective electroless deposition, dry side processing station 235 may be configured as an ALD or CVD chamber for the deposition of a barrier layer and/or catalytic layer prior to wet processing. Optionally, a pre-deposition dry etch chamber positioned at processing station 235a may also be included in factory interface 230 for the removal of native oxide from the substrate (see FIG. 11).

3. Process Sequence

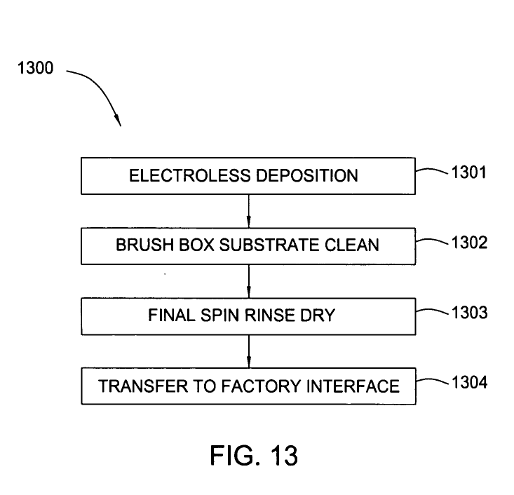

A typical substrate processing sequence 1300 for this embodiment of the invention is detailed in the flow chart illustrated in FIG. 13.

In step 1301, one or more electroless deposition steps may be completed on the substrate. Any of the substrate processing sequences detailed in FIGS. 12A, 12B, or 12C, 12D, or 12E may be used to complete electroless deposition for this embodiment of the invention, i.e., steps 1201 and 1202, or steps 1201, 1202a, and 1202b, or steps 1201, 1202c, 1202d, and 1202e. However, rather than transferring the substrate directly to an SRD chamber when electroless deposition is complete (as shown in FIGS. 12A, 12B, and 12C), a brush box substrate clean is first performed. Alternately, in embodiments in which the electroless plating twin cells include the functionality of an IBC chamber, the final deposition step, i.e., 1202, 1202b, or 1202e, may also include performing the IBC process on the substrate as described above.

In step 1302, main frame robot 220 transfers the substrate from an electroless plating cell to brush box 216a, wherein a substrate surface brush clean process, described below, is performed to remove any unwanted surface contamination, for example the enlarged metallic particles 104b depicted in FIG. 1B.

In step 1303, the substrate is transferred to the SRD chamber and the final rinse and dry process is performed via the SRD process described in conjunction with FIG. 4.

In step 1304, the substrate is transferred out of wet processing platform 213 from the SRD. The incorporation of a brush box chamber on wet processing platform 213 makes possible the formation of low-defect capping layers on interconnect features.

4. Description of Brush Box Chamber

In one configuration of cluster tool 200, a brush box chamber is used for post-deposition clean of substrates prior to their removal from the wet processing platform. Brush box chambers are generally used to remove residual contaminants from the surface of a substrate after the CMP process. Brush box chambers conventionally clean or scrub residue substrate surfaces via mechanical scrubbing devices, which may employ polyvinyl acetate (PVA) brushes, brushes made from other porous or sponge-like material, or brushes made with nylon bristles, etc. However, configurations of cluster tool 200 may also use brush box chambers for the removal of loosely bound metallic contamination that has formed on the surface of a substrate during the electroless deposition process, such as the enlarged metallic particles 104b (shown in FIG. 1B). This procedure can greatly reduce defects associated with the electroless deposition of capping layers on interconnect features.

Typically, brush box chambers clean a vertically-oriented substrate by lowering the substrate between cylindrical, rotating brushes. The substrate itself may also be rotated by means of powered rollers on which the substrate rests. Liquid cleaning solutions are applied to the substrate by spray nozzles and/or through the scrubber brushes. A detailed description of an exemplary brush box chamber that may be used in embodiments of the invention may be found in commonly assigned U.S. Pat. No. 6,558,471, entitled “Scrubber Operation,” filed on Jan. 26, 2001, which is hereby incorporated by reference in its entirety.

D. Electroless Deposition System with IBC and SRD Chambers

One embodiment of the wet processing platform 213, illustrated in FIGS. 2 and 2A, generally includes an electroless plating chamber, a wafer bevel clean chamber, and a spin-rinse drying chamber. Optionally, this embodiment may also include ALD barrier layer deposition prior to wet processing.

1. Applications of Cluster Tool Configuration

This configuration may be used to process substrate structures with barrier layer deposition and electroless seed layer deposition and/or seed layer repair, fill high aspect ratio interconnect features with electroless gap fill deposition, or deposit both seed layer and gap fill on a substrate sequentially. Advantages in substrate processing throughput may also be realized due to the use of dedicated SRD and IBC chambers. This is because the IBC chamber is typically a throughput bottleneck and this configuration provides two IBC chambers.

2. General Description of Cluster Tool Configuration

In this embodiment, processing stations 214 and 216 may be configured as an interface between the wet processing platform 213 and the generally dry processing stations or factory interface 230 of the cluster tool 200. As such, substrates are introduced into wet processing platform 213 by being placed in an in-station 972 while waiting for wet processing. The in-station 972 is typically located above or below processing stations 214 and 216, as shown in FIG. 2A. In addition to the in-stations, processing stations 214 and 216 each include an SRD chamber which performs the final wet processing steps on a substrate before the substrate leaves wet processing platform 213. In this embodiment, processing station 235 may be configured as an ALD or CVD chamber for the deposition of a barrier layer and/or catalytic layer prior to wet processing. In some embodiments, the catalytic layer so formed is a ruthenium-containing layer deposited without the use of carbon-containing precursors. Processing stations 202 and 204 comprise an electroless plating twin cell configured for seed layer deposition or repair, processing stations 210 and 212 comprise a electroless plating twin cell configured for gap fill deposition, and processing stations 206 and 208 are standard IBC chambers. These configurations for the pairs of processing stations 202/204, 206/208, and 210/212 may be rearranged without affecting the functionality of the invention and are defined above only for purposes of description. Each electroless twin cell is contained by a processing enclosure 302. Each twin cell may also include an internal substrate transfer shuttle 605 for transferring substrates between the first and second processing stations inside each processing enclosure 302. This configuration of wet processing platform 213 is typically used to sequentially process substrate structures with barrier layer and electroless seed layer deposition and/or seed layer repair followed by electroless gap fill. Sequential deposition minimizes both the amount and variation of oxidation of the seed layer prior to gap fill over the prior art. Electroless gap fill has the added benefit of being capable of filling high aspect ratio features. Additionally, only a single processing platform is required to complete three deposition steps on a substrate structure. Further, because the most time-consuming process, i.e., the IBC process, is performed by dedicated IBC chambers and is not incorporated into either the SRD chambers or the electroless plating twin cells, throughput may be increased for the deposition of some films.

3. Process Sequence

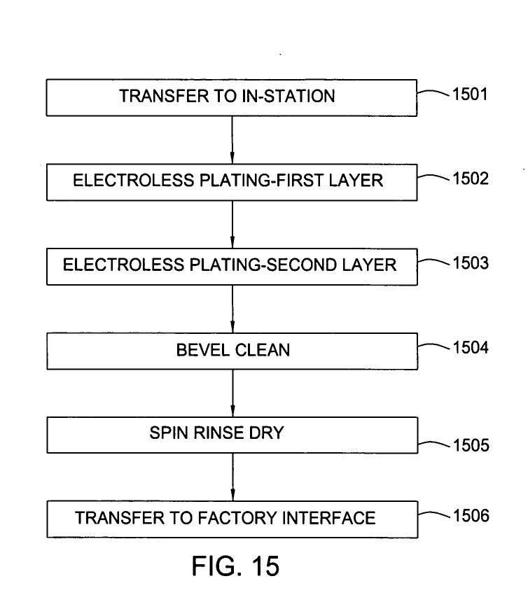

A processing sequence is illustrated in FIG. 15.

In step 1501, factory interface robot 232 places a substrate at the in-station 972 associated with processing stations 214 or 216.

In step 1502, mainframe robot 220 transfers the substrate to processing station 202 for seed layer deposition.

In step 1503, mainframe robot 220 transfers the substrate to processing station 210 for electroless gap fill of interconnect features. All electroless deposition processes necessary for seed layer deposition take place in the twin cell located at processing stations 202/204 and all electroless deposition processes necessary for gap fill take place in twin cell located at processing stations 210/212. The substrate is transferred between processing stations 202 and 204 or 210 and 212 via internal substrate transfer shuttle 605 as necessary. Typically, the reducing layer and catalytic layer formation steps are performed in the first processing station of the seed layer twin cell, i.e. processing station 202 via the reducing layer and catalytic layer formation processes described above in conjunction with FIG. 14. The electroless plating step is performed in the second processing station, i.e. processing station 204 using the electroless deposition process described above in conjunction with FIG. 7. Alternatively, when the substrate has been processed with a catalytic layer prior to wet processing, all electroless deposition can take place in a single processing station. Processing stations 202 and 204 then act as two independent seed layer plating cells. Processing stations 210 and 212 typically act as two independent gap fill plating cells in this configuration and generally do not require substrate transfers via internal substrate transfer shuttle 605. Hence, step 1502 includes transferring the substrate from one of the in-stations to either processing station 202 or 204 for seed layer deposition/repair and step 1503 includes transferring the substrate to either processing station 210 or 212 for gap fill deposition.

In step 1504, upon completion of gap fill deposition, the substrate is transferred to the IBC chamber positioned at processing stations 206 or 208 for removal of unwanted deposition on the wafer edge and bevel via the IBC process described in conjunction with FIG. 3. In step 1505, mainframe robot 220 transfers the substrate to SRD chamber positioned at processing station 214 or 216 for final rinsing and drying via the SRD process described in conjunction with FIG. 4.

In step 1506, after the SRD process is complete, factory interface robot 232 removes the substrate from the SRD and the wet processing platform 213.

E. Electroless Deposition Platform with Brush Box and Vapor Dryer

1. Applications of Cluster Tool Configuration

One embodiment of the invention is illustrated in FIGS. 11 and 11A by exemplary wet processing platform 213 and generally includes electroless plating, brush box substrate clean and vapor drying chambers. This configuration of cluster tool 200 may be used to deposit capping layers on interconnect features. This embodiment may also process substrate structures with electroless seed layer deposition, fill interconnect features with electroless gap fill deposition, or deposit both seed layer and gap fill sequentially. In this case, the dry side processing station 235 may be configured as an ALD/CVD pre-treatment chamber for deposition of a barrier layer and/or catalytic layer. In some embodiments, the catalytic layer so formed is a ruthenium-containing layer deposited without the use of carbon-containing precursors. In some aspects, a plasma-enhanced dry etch is performed on the substrate in a chamber positioned in processing station 235a inside factory interface 230 prior to deposition.

This embodiment of the invention allows the formation of capping layers over interconnect features without the defects caused by watermarks, which are created during a conventional spin-rinse-dry process. Also, capping layers formed with this embodiment of the invention are much less likely to include leakage paths between the capped interconnects due to the post-deposition brush box cleaning process. This configuration of cluster tool 200 may also be used to sequentially process substrate structures with electroless seed layer deposition followed by electroless gap fill. Sequential deposition minimizes both the amount and variation of oxidation of the seed layer prior to gap fill. Electroless gap fill has the added benefit of being capable of filling high aspect ratio features using the process method described above in Step 504 and in conjunction with FIGS. 7 and 8. Additionally, only a single processing platform is required to complete two deposition steps on a substrate structure. Further, this embodiment of the invention removes most surface particles from substrates and eliminates watermark-related defects caused by SRD chambers when rinsing hydrophobic substrates.

2. General Description of Cluster Tool Configuration

In this embodiment, processing station 214 may act as the interface between the wet processing platform 213 and the generally dry processing stations or factory interface 230 of the cluster tool 200. As such, the vapor dryer chamber for wet processing platform 213 and an in-station 972 are located at processing station 214. The in-station 972 (shown in FIG. 9A) may be located above the vapor dryer chamber and holds substrates for future wet processing (as shown in FIG. 11). The vapor dryer performs the final wet processing step on substrates processed by wet processing platform 213 and includes a substrate platform that serves as a holding location for clean, dry substrates which are subsequently removed from wet processing platform 213. Processing station 216 is configured as a brush box chamber for post-deposition cleaning of substrates. The brush box located at processing station 216 may be configured to accept wafers that are oriented either horizontally or vertically. In this embodiment, processing stations 202 and 204 comprise an electroless plating twin cell, processing stations 206 and 208 comprise a second electroless plating twin cell, and processing stations 210 and 212 comprise a third electroless plating twin cell.

In another configuration, the brush box 216a and vapor dryer 216b are configured together at processing station 216, as shown in FIG. 11A. In-station 972 is still located in processing station 214. After the final vapor dry process step is completed on a substrate, the substrate is transferred to the vapor dryer substrate platform located in factory interface 230, as shown in FIG. 11A.

One embodiment of the invention may be used wherein the vapor dryer and brush box are not located at processing stations 214 and 216 respectively, but are both located at processing stations 202/204 or 210/212. The vapor dryer and brush box are more serviceable in this embodiment due to the improved access from the side of wet processing platform 213.

3. Process Sequences

a) Capping Layer Deposition

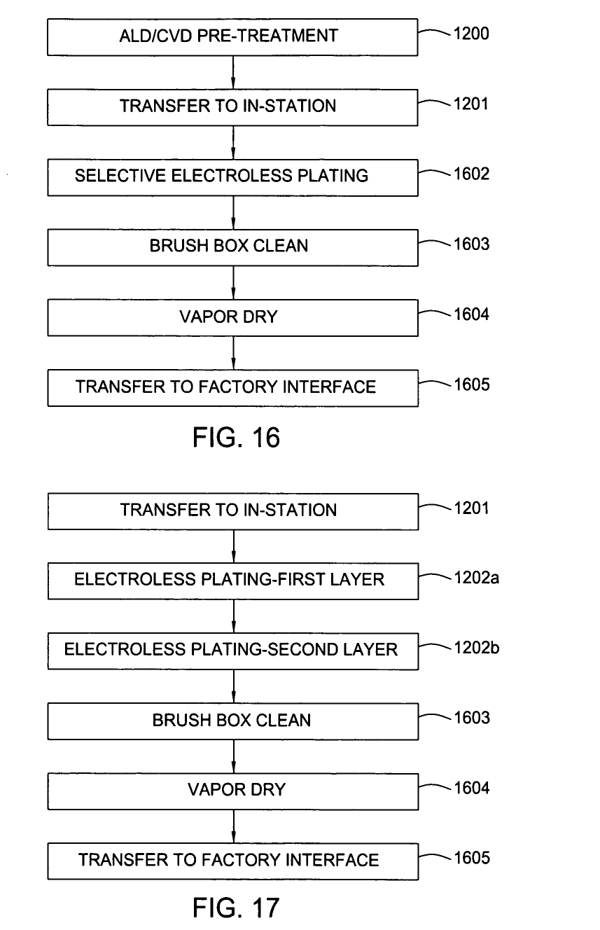

When this configuration is used for depositing a capping layer on a substrate, then all electroless deposition processes may take place in a single electroless plating twin cell. The second and third electroless twin cells may operate in parallel with the first twin cell and perform the same deposition process on other substrates. A typical substrate processing sequence for depositing a capping layer with this embodiment of the invention is detailed in the flow chart illustrated in FIG. 16. Steps 1200 and 1201 in FIG. 16 are identical to steps 1200 and 1201 in FIG. 12 and are described above.

Step 1602 is similar to step 1202 described above in conjunction with FIGS. 12A-C, except that selective electroless deposition is performed on the substrate, i.e., the formation of a capping layer on exposed interconnect features. Alternately, the selective electroless plating step 1602 may also include additional vapor drying steps, wherein the substrate is removed from the electroless plating cell by mainframe robot 220, transferred to vapor dryer positioned at processing station 214 and processed therein, and returned via mainframe robot 220 to the appropriate electroless cell for completion of the electroless plating process. These additional vapor drying steps may occur prior to the preparatory clean step, as described above in Step 501, of the electroless plating process.

In step 1603, upon completion of capping layer deposition, the substrate is transferred to the brush box 216a or to a brush box chamber located at processing station 216 to remove any unwanted contamination from the surface of the substrate. The brush box process is described above in conjunction with the brush box chamber description.

In step 1604, after the brush box substrate clean is complete, the substrate is transferred to vapor dryer 214a or to a vapor dryer positioned at processing station 214 for the final vapor dry process, which is described below in conjunction with the vapor dryer chamber description.

In step 1605, after the vapor dry process is complete, factory interface robot 232 removes the substrate from the vapor dryer substrate platform and the wet processing platform 213.

b) Multiple Metal Layer Deposition

When this embodiment of the invention is used for depositing multiple layers of metal on substrates, e.g., a seed layer followed sequentially by other electroless deposition processes, then each substrate is processed by more than one twin electroless cell. In this application of the invention, one or two of the electroless twin cells are dedicated to seed layer deposition and the remaining electroless twin cell or cells is/are dedicated to gap fill deposition. As an example, twin cells positioned at processing stations 202/204 and 206/208 may be configured for seed layer deposition and twin cell positioned at processing stations 210/212 may be configured for gap fill deposition. These configurations for the pairs of processing stations 202/204, 206/208, and 210/212 may be rearranged without affecting the functionality of the invention and are defined above only for purposes of description. The processing sequence for this application of the invention is illustrated in FIG. 17. Steps 1200, 1201, 1202a, and 1202b are identical to steps 1200, 1201, 1202a, and 1202b in FIG. 12B and described above. Alternately, the electroless plating step 1202 may also include additional vapor drying steps, wherein the substrate is removed from the electroless plating cell by mainframe robot 220, transferred to vapor dryer positioned at processing station 214 and processed therein, and returned via mainframe robot 220 to the appropriate electroless cell for completion of the electroless plating process. These additional vapor drying steps may occur prior to the dielectric clean and/or prior to the metal clean steps, which are included in the preparatory clean step. The preparatory clean step is part of the electroless plating process and is described above in Step 501 in conjunction with FIGS. 7 and 8. Steps 1603, 1604, and 1605 in FIG. 17 are identical to steps 1603, 1604, and 1605 in FIG. 16 and described above. In instances when this embodiment is used either for interconnect gap fill or for forming a seed layer that will be followed by electroless gap fill, it should be noted that the cluster tool must also be configured with IBC capability incorporated into the electroless plating twin cells, allowing the necessary post-deposition cleaning of substrates prior to removal from the wet processing platform.

4. Description of Process Chambers

Embodiments of the invention include the incorporation of multiple substrate processing chambers onto a single cluster tool, including electroless, brush box, vapor dryer and ALD or CVD chambers. Examples of most of these chambers and the processes performed on substrates therein have been described previously. A general description of vapor dryer chambers and vertical wafer handling is provided below.

a) Vapor Dryer Chamber

The vapor drying process is typically performed after completing a metal deposition process, e.g., the electroless capping layer process, to prevent watermarks and to remove any residue on the substrate from prior processes. Vapor drying may also be used in lieu of a final spin-rinse-dry prior to removing a substrate from a wet processing platform. Vapor drying includes introducing a surface tension-reducing volatile compound, such as a volatile organic compound (VOC), to the substrate structure. For example, a VOC may be introduced with a carrier gas (e.g., nitrogen gas) in the vicinity of the liquid adhering to a substrate structure. The introduction of the VOC results in surface tension gradients which cause the liquid to flow off of the substrate, leaving it dry. In one embodiment, the VOC is isopropyl alcohol (IPA). In other embodiments, the VOC may be other alcohols, ketones, ethers, or other suitable compounds. Examples of exemplary vapor drying processes are further described in the commonly assigned U.S. Pat. No. 6,328,814, filed Mar. 26, 1999 and U.S. patent application Ser. No. 10/737,732, entitled “Scrubber With Integrated Vertical Marangoni Drying”, filed Dec. 16, 2003, which is incorporated by reference in its entirety to the extent not inconsistent with the present disclosure.

It is believed that vapor drying the substrate structure before and/or after depositing a capping layer by selective electroless deposition assists in the removal of contaminants and other residue from prior processing steps. Such contaminants may cause, for example, watermarks and other surface defects. The residual compounds are difficult to remove with aqueous solutions from the low-k dielectric portion of the substrate structure since the low-k dielectric portion is a hydrophobic surface. Vapor drying with a volatile organic compound aids in removing contaminants from these surfaces along with any residual water—an important step in preventing electroless deposition of capping material on unwanted regions of substrate structures. Additionally, vapor drying may be used in conjunction with other deposition processes unrelated to capping layers in order to minimize watermarks and other residues and to speed drying time. A detailed description of embodiments of an apparatus and method of vapor drying is disclosed in U.S. Patent Application Publication No. 2003/0121170, entitled “Single Wafer Dryer and Drying Methods,” which is incorporated in its entirety to the extent not inconsistent with the present disclosure.

b) Vertical Wafer Handling

Substrates cleaned vertically in brush box chambers and vapor dryers benefit from the assistance of gravity in removing particles and other contaminants from the substrate. Hence, the most effective configuration for brush box chambers and vapor dryer chambers is for vertically oriented substrates. Some embodiments of the invention include brush box chambers and vapor dryers configured for vertically oriented substrates. The 90 degree difference in substrate orientation between plating cells and brush box and vapor dryer chambers requires more than the traditional horizontally orientated substrate transfer mechanisms. Exemplary methods of combined vertical/horizontal substrate transfer as they are incorporated into embodiments of the invention are described below.

Embodiments of the invention require transfer of substrates from a conventional, horizontal substrate transfer robot, i.e., mainframe robot 220, to processing chambers that typically require vertical orientation of the substrate, such as a brush box chamber and/or a vapor dryer chamber.

FIG. 9A illustrates the apparatus required for substrate transfer into a brush box chamber, from a brush box chamber into a vapor dryer chamber, and from a vapor dryer out of wet processing platform 213. Brush box chamber 975 and vapor dryer 974 are shown in processing stations 216 and 214, respectively, on wet processing platform 213. In-station 972 is shown configured above vapor dryer 974. Running beam 250 and flipper robot 251 are shown in FIG. 9A and also in FIG. 11.

Transfer of a substrate from horizontal transfer robot, such as mainframe robot 220, into a brush box chamber requires rotation of the substrate to a vertical orientation and a downward vertical motion into the brush box. One method is to use a conventional horizontal transfer robot (not shown in FIG. 9A) that is also configured for rotating substrates to vertical orientation in conjunction with a brush box chamber that includes the added capability of transferring substrates downward into the brush box. This requires a brush box with a dedicated robot (not shown) for inserting substrates into brush box chamber 975. More typically, the substrate is rotated to vertical either by the horizontal transfer robot or by flipper robot 251. When the vertical orientation is performed by the horizontal transfer robot, the substrate may be placed in a vertical substrate holding station, also known as a crescent (not shown). When the vertical orientation is performed by flipper robot 251, the horizontal transfer robot hands off a horizontal substrate to flipper robot 251, which then rotates the substrate into vertical orientation. Running beam 250, which is disposed directly over flipper robot 251, brush box chamber 975, and vapor dryer 974, is used for vertical transfers of the substrate into and out of brush box chamber 975 and into vapor dryer 974 (See FIG. 9A). After vertical orientation, the substrate may be located on flipper robot 251 or in a vertical holding station (not shown). Vertical beam 970 moves along running beam rail 976 until directly over the substrate. The substrate 973b is removed by substrate edge gripper device 971, which may move vertically along vertical beam 970. Vertical beam 970 then moves along running beam rail 976 until directly over brush box chamber 975 and substrate edge gripper device 971 transfers the substrate 973c vertically downward into brush box chamber 975. After cleaning in brush box chamber 975 is complete, substrate edge gripper device 971 removes substrate 973b vertically from brush box chamber 975. Vertical beam 970 then moves along running beam rail 976 until directly over vapor dryer 974. Substrate edge gripper device 971 transfers the substrate vertically downward into vapor dryer 974. After cleaning in vapor dryer 974 is complete, substrate 973d is held on substrate platform 958 (shown more clearly in FIG. 9A and in FIG. 2A) where it awaits transfer out of wet processing platform 213 by factory interface robot 232 (see FIG. 11).

The wafer transfer sequence above is summarized in the flow chart in FIG. 9B. In step 9001, electroless deposition is complete and the mainframe robot 220 holds a substrate horizontally. In 9002 the mainframe robot rotates the substrate to vertical and transfers the substrate to a brush box robot, which then lowers the substrate into brush box chamber 975. Alternately, in step 9003, mainframe robot 220 rotates the substrate and transfers it to a vertical holding station. Alternately, in step 9004, mainframe robot 220 does not rotate the substrate to vertical and instead hands off the substrate to flipper robot 251, which rotates the substrate to vertical. In step 9005, running beam 250 transfers the substrate to brush box chamber 975. In step 9006, running beam 250 transfers the substrate to vapor dryer 974. In step 9007, the substrate is transferred from vapor dryer 974 out of the wet processing platform 213.

While the foregoing is directed to embodiments of the present invention, other and further embodiments of the invention may be devised without departing from the basic scope thereof, and the scope thereof is determined by the claims that follow.

1. An electroless deposition cluster tool, comprising:
a mainframe;
at least one electroless plating cell in an environmentally controlled enclosure, wherein the at least one electroless plating cell is on the mainframe; and
at least one electroplating cell on the mainframe.

2. The cluster tool of claim 1, wherein the electroless plating cell comprises:
a first fluid processing chamber;
a second fluid processing chamber; and
a substrate transfer shuttle adapted to transfer substrates inside the processing enclosure between the first chamber and the second chamber.

3. The cluster tool of claim 1, further comprising:
at least one IBC chamber; and
at least one SRD chamber.

4. The cluster tool of claim 1, further comprising:
at least one brush box chamber; and
at least one vapor dryer chamber.

5. The cluster tool of claim 1, further comprising a plasma-enhanced dry etch chamber, comprising:
a temperature-controlled substrate support;
a temperature-controlled chamber body;
a lid assembly containing a first and second electrode, wherein plasma is struck between the first and second electrode and the second electrode is adapted to heat the substrate; and
a processing zone between the second electrode and the substrate support, wherein process gases flow from the lid assembly to the surface of the substrate.

6. An electroless deposition cluster tool, comprising:
at least one electroless plating cell on a mainframe;
at least one electroplating cell on the mainframe;
at least one IBC chamber on the mainframe; and
at least one SRD chamber on the mainframe.

7. The cluster tool of claim 6, further comprising at least one plasma processing chamber.

8. The cluster tool of claim 6, further comprising at least one plasma-enhanced dry etch chamber.

9. An electroless deposition cluster tool, comprising:
at least one electroless plating cell in an environmentally controlled enclosure, wherein the at least one electroless plating cell is on a mainframe; and
at least one SRD chamber on the mainframe.

10. The cluster tool of claim 9, wherein the electroless plating cell comprises:
a first fluid processing chamber;
a second fluid processing chamber; and
a substrate transfer shuttle adapted to transfer substrates inside the processing enclosure between the first chamber and the second chamber.

11. The cluster tool of claim 9, further comprising at least one brush box chamber.

12. The cluster tool of claim 9, further comprising at least one IBC chamber.

13. The cluster tool of claim 12, wherein the IBC and SRD chambers are combined into a hybrid IBC/SRD chamber.

14. The cluster tool of claim 9, further comprising at least one plasma-enhanced dry etch chamber.

15. The cluster tool of claim 9, further comprising at least one supercritical clean chamber.

16. An electroless deposition cluster tool, comprising:
at least one electroless plating cell in an environmentally controlled enclosure, wherein the at least one electroless plating cell is on a mainframe;
at least one brush box chamber on the mainframe; and
at least one vapor dryer chamber on the mainframe.

17. The cluster tool of claim 16, wherein the electroless plating cell comprises:
a first fluid processing chamber;
a second fluid processing chamber; and
a substrate transfer shuttle adapted to transfer substrates inside the processing enclosure between the first chamber and the second chamber.

18. The cluster tool of claim 16, further comprising at least one plasma-enhanced dry etch chamber.

19. The cluster tool of claim 1, wherein the electroless plating cell comprises:
a substrate support assembly having a substrate supporting surface, wherein the substrate support assembly is adapted to center and rotate a substrate, and;
a fluid dispense arm that is adapted to dispense multiple processing fluids onto a surface of a substrate on the substrate supporting surface, wherein the fluid dispense arm further comprises:
a plurality of fluid conduits configured to supply a fluid to a surface of a substrate, wherein the fluid is selected from a list consisting of an electroless deposition fluid, a rinsing fluid and a substrate bevel cleaning fluid; and
a fluid nozzle that is in fluid communication with one of the fluid conduits and is adapted to deliver a fluid to an edge of the substrate.

20. The electroless deposition system of claim 3, further comprising a plasma processing chamber adapted to form a reducing layer and/or a catalytic layer on a substrate, comprising:
one or more walls forming a processing region;
a temperature-controlled substrate support on one of the one or more walls, wherein the temperature-controlled substrate support is adapted to support the substrate during processing;
a gas supply adapted to provide appropriate process gases to the process region for forming a reducing layer and/or a catalytic layer on the substrate;
a gas distribution showerhead on the one of the one or more walls and is in fluid communication with the gas supply, wherein the gas distribution showerhead is adapted to distribute process gases uniformly into the process region; and
an RF power supply connect to the gas distribution showerhead so that the gas distribution showerhead can be adapted to control a plasma generated in the processing region.

21. The electroless deposition system of claim 20, further comprising a plasma-enhanced dry etch chamber, comprising:
a temperature-controlled chamber body having one or more walls that form a processing region;
a temperature-controlled substrate support in the processing region;
a lid assembly containing a first and second electrode, wherein plasma is struck between the first and second electrode and the second electrode is adapted to heat the substrate; and
a fluid source in fluid communication with the lid assembly, wherein the fluid source is adapted to deliver a process gases from the lid assembly to the surface of the substrate.

22. The electroless deposition system of claim 20, wherein the gas supply is further adapted to provide appropriate process gases to the processing region for forming a barrier layer on the substrate.

23. An electroless deposition cluster tool, comprising:
at least one plasma processing chamber that is on a mainframe and is adapted to form a reducing layer and/or a catalytic layer on a substrate, wherein the at least one plasma processing chamber comprises;
one or more walls forming a processing region;
a temperature-controlled substrate support on one of the one or more walls, wherein the temperature-controlled substrate support is adapted to support the substrate during processing;
a gas supply adapted to provide appropriate process gases to the process region for forming a reducing layer and/or a catalytic layer on the substrate;
a gas distribution showerhead on the one of the one or more walls and in fluid communication with the gas supply, wherein the gas distribution showerhead is adapted to distribute process gases uniformly into the process region; and
an RF power supply connect to the gas distribution showerhead so that the gas distribution showerhead can be adapted to control a plasma generated in the processing region; and
at least one fluid processing chamber on the mainframe, wherein the at least one fluid processing chamber comprises:
a substrate support assembly adapted to support and rotate the substrate;
one or more fluid dispense arms adapted to dispense multiple processing fluids onto a surface of a substrate on the substrate support assembly; and
a substrate processing platen assembly adapted to dispense a temperature controlled fluid to the backside of the substrate during processing.

24. The cluster tool of claim 23, wherein the gas supply is adapted to provide a process gas to the processing region, wherein the process gas is adapted to form a barrier layer on a surface of a substrate on the temperature-controlled substrate support.

25. The cluster tool of claim 23, wherein the gas supply is further adapted to provide appropriate process gases to the process region for forming a barrier layer on the substrate.

26. The cluster tool of claim 23, wherein the plasma processing chamber further comprises:
a ruthenium tetroxide generation system comprising:
a vessel that is adapted to retain an amount of ruthenium metal;
an oxidizing source that is adapted to deliver an ozone containing gas to the vessel to form a ruthenium tetroxide containing gas in the vessel; and
a source vessel assembly that is in fluid communication with the vessel and is adapted to collect the ruthenium tetroxide containing gas formed in the vessel, wherein the source vessel assembly comprises:
a source vessel; and
a heat exchanging device that is in thermal communication with the source vessel and is adapted to control the temperature of the source vessel; and
a processing chamber in fluid communication with the source vessel.

27. The cluster tool of claim 23, further comprising:
an IBC process chamber on the mainframe and having one or more fluid dispense arms are adapted to deliver a fluid to a surface of a substrate on a substrate support, wherein the IBC process chamber further comprises:
a plurality of fluid conduits configured to supply a fluid to a surface of a substrate, wherein the fluid is selected from a list consisting of an electroless deposition fluid, a rinsing fluid and a substrate bevel cleaning fluid; and
a fluid nozzle that is in fluid communication with one of the fluid conduits and is adapted to deliver a fluid to an edge of the substrate; and
a SRD chamber on the mainframe.

28. The cluster tool of claim 23, further comprising:
at least one processing chamber adapted to perform the IBC process on the substrate;
at least one brush box chamber; and
at least one vapor dryer chamber.

29. The cluster tool of claim 23, further comprising a plasma-enhanced dry etch chamber, comprising:
a temperature-controlled chamber body having one or more walls that form a processing region;
a temperature-controlled substrate support in the processing region;
a lid assembly containing a first and second electrode, wherein plasma is struck between the first and second electrode and the second electrode is adapted to heat the substrate; and
a fluid source in fluid communication with the lid assembly, wherein the fluid source is adapted to deliver a process gases from the lid assembly to the surface of the substrate.

30. The cluster tool of claim 23, further comprising at least one supercritical clean chamber on the mainframe.

31. An electroless cluster tool, comprising:
at least one plasma processing chamber on a mainframe that is adapted to form a reducing layer on a substrate, comprising:
one or more walls forming a processing region;
a temperature-controlled substrate support on one of the one or more walls, wherein the temperature-controlled substrate support is adapted to support the substrate during processing;
a gas supply adapted to provide a process gas to the process region to forming a reducing layer on a surface of a substrate on the temperature-controlled substrate support;
a gas distribution showerhead on one of the one or more walls and is in fluid communication with the gas supply, wherein the gas distribution showerhead is adapted to distribute process gases uniformly into the process region; and
an RF power supply connect to the gas distribution showerhead so that the gas distribution showerhead can be adapted to control a plasma generated in the processing region; and
at least one fluid processing chamber that is on the mainframe and is adapted to form a metal-containing catalytic and/or conductive layer on a surface of a substrate via an electroless plating process, comprising:
a substrate support assembly adapted to support and rotate the substrate;
one or more fluid dispense arms adapted to dispense multiple processing fluids onto a surface of the substrate on the substrate support assembly; and
a substrate processing platen assembly adapted to dispense a temperature controlled fluid to the backside of a substrate on the substrate support assembly.

32. The cluster tool of claim 31, further comprising at least one plasma processing chamber adapted to form a barrier layer on a substrate, comprising:
one or more walls forming a processing region;
a temperature-controlled substrate support on one of the one or more walls, wherein the temperature-controlled substrate support is adapted to support the substrate during processing;
a gas supply adapted to provide appropriate process gases to the process region for forming a barrier layer on the substrate;
a gas distribution showerhead on the one of the one or more walls and is in fluid communication with the gas supply, wherein the gas distribution showerhead is adapted to distribute process gases uniformly into the process region; and
an RF power supply connect to the gas distribution showerhead so that the gas distribution showerhead can be adapted to control a plasma generated in the processing region.

33. The cluster tool of claim 31, wherein the gas supply is further adapted to deliver a process gas that can form a barrier layer on a surface of a substrate.

34. The cluster tool of claim 31, further comprising:
at least one processing chamber adapted to perform the IBC process on the substrate; and
at least one SRD chamber.

35. The cluster tool of claim 31, further comprising:
at least one processing chamber adapted to perform the IBC process on the substrate;
at least one brush box chamber; and
at least one vapor dryer chamber.

36. The electroless deposition system of claim 31, further comprising a plasma-enhanced dry etch chamber, comprising:
a temperature-controlled chamber body having one or more walls that form a processing region;
a temperature-controlled substrate support in the processing region;
a lid assembly containing a first and second electrode, wherein plasma is struck between the first and second electrode and the second electrode is adapted to heat the substrate; and
a fluid source in fluid communication with the lid assembly, wherein the fluid source is adapted to deliver a process gas from the lid assembly to the surface of the substrate.

37. An electroless cluster tool, comprising:
at least one plasma processing chamber adapted to form a reducing and/or a barrier layer on a substrate, comprising:
one or more walls forming a processing region;
a temperature-controlled substrate support on one of the one or more walls, wherein the temperature-controlled substrate support is adapted to support the substrate during processing;
a gas supply adapted to provide appropriate process gases to the process region for forming a reducing layer and/or a barrier layer on the substrate;
a gas distribution showerhead on one of the one or more walls and is in fluid communication with the gas supply, wherein the gas distribution showerhead is adapted to distribute process gases uniformly into the process region; and
an RF power supply connect to the gas distribution showerhead so that the gas distribution showerhead can be adapted to control a plasma generated in the processing region;
a first fluid processing chamber, adapted to form a metal-containing catalytic and/or conductive layer on the substrate via an electroless plating process; and
a second fluid processing chamber, adapted to form a conductive layer on the substrate via an electroplating process.

38. The electroless deposition system of claim 37, further comprising a plasma-enhanced dry etch chamber, comprising:
a temperature-controlled chamber body having one or more walls that form a processing region;
a temperature-controlled substrate support in the processing region;
a lid assembly containing a first and second electrode, wherein plasma is struck between the first and second electrode and the second electrode is adapted to heat the substrate; and
a fluid source in fluid communication with the lid assembly, wherein the fluid source is adapted to deliver a process gas from the lid assembly to the surface of the substrate.

39. A substrate plating cluster tool, comprising:
a plasma chamber adapted to deposit a ruthenium-containing catalytic layer on a substrate, comprising:
a ruthenium tetroxide generation system comprising:
a vessel that is adapted to retain an amount of ruthenium metal;
an oxidizing source that is adapted to deliver an ozone containing gas to the vessel to form a ruthenium tetroxide-containing gas in the vessel; and
a source vessel assembly that is in fluid communication with the vessel and is adapted to collect the ruthenium tetroxide containing gas formed in the vessel, wherein the source vessel assembly comprises:
a source vessel; and
a heat exchanging device that is in thermal communication with the source vessel and is adapted to control the temperature of the source vessel; and
a processing chamber in fluid communication with the source vessel; and
a processing chamber adapted to form a conductive layer on the substrate.

40. The cluster tool of claim 39, wherein the processing chamber adapted to form a conductive layer is an electroless plating chamber.

41. The cluster tool of claim 40, further comprising a plasma processing chamber adapted to form a reducing layer and/or a barrier layer on the substrate, comprising:
one or more walls forming a processing region;
a temperature-controlled substrate support on one of the one or more walls, wherein the temperature-controlled substrate support is adapted to support the substrate during processing;
a gas supply adapted to provide appropriate process gases to the process region for forming a reducing layer and/or a barrier layer on a surface of a substrate on the temperature-controlled substrate support;
a gas distribution showerhead on the one of the one or more walls and is in fluid communication with the gas supply, wherein the gas distribution showerhead is adapted to distribute process gases uniformly into the process region; and
an RF power supply connect to the gas distribution showerhead so that the gas distribution showerhead can be adapted to control a plasma generated in the processing region.

42. The cluster tool of claim 39, wherein the processing chamber adapted to form a conductive layer is an electroplating chamber.

43. The cluster tool of claim 42, further comprising a plasma processing chamber adapted to form a reducing layer and/or a barrier layer on the substrate, comprising:
one or more walls forming a processing region;
a temperature-controlled substrate support on one of the one or more walls, wherein the temperature-controlled substrate support is adapted to support the substrate during processing;
a gas supply adapted to provide appropriate process gases to the process region for forming a reducing layer and/or a barrier layer on a surface of a substrate on the temperature-controlled substrate support;
a gas distribution showerhead on the one of the one or more walls and is in fluid communication with the gas supply, wherein the gas distribution showerhead is adapted to distribute process gases uniformly into the process region; and
an RF power supply connect to the gas distribution showerhead so that the gas distribution showerhead can be adapted to control a plasma generated in the processing region.
